(19) United States
(12) Patent Application Publication
(10) Pub. No.: US 2026/0051715 A1
(43) Pub. Date: Feb. 19, 2026

(54) SEMICONDUCTOR LIGHT EMITTING DEVICE

(71) Applicant: HAMAMATSU PHOTONICS K.K., Hamamatsu-shi, Shizuoka (JP)

(72) Inventors: Seiichiro MIZUNO, Hamamatsu-shi, Shizuoka (JP); Kazuyoshi HIROSE, Hamamatsu-shi, Shizuoka (JP); Hiroki KAMEI, Hamamatsu-shi, Shizuoka (JP); Takahiro SUGIYAMA, Hamamatsu-shi, Shizuoka (JP)

(73) Assignee: HAMAMATSU PHOTONICS K.K., Hamamatsu-shi, Shizuoka (JP)

(21) Appl. No.: 19/101,052

(22) PCT Filed: Aug. 7, 2023
(86) PCT No.: PCT/JP2023/028797

§ 371 Date: Feb. 4, 2025

(30) Foreign Application Priority Data
Sep. 5, 2022 (JP) 2022-140642

(51) Int. Cl. H01S 5/042; H01S 5/062

(52) U.S. Cl. CPC H01S 5/042; H01S 5/06246

(57) ABSTRACT

A semiconductor light emitting device includes: a plurality of iPM lasers each having a first surface and a second surface opposite to the first surface and outputting light from the first surface; and a drive circuit that supplies a drive current to cause each of the plurality of iPM lasers to emit light. The drive circuit includes: a current source circuit common to the plurality of iPM lasers; a plurality of switch sections provided corresponding to the plurality of iPM lasers, respectively, for ON/OFF switching of the drive current; and a switch operating section that individually operates each of the plurality of switch sections.

### TECHNICAL FIELD

One aspect of the present disclosure relates to a semiconductor light emitting device.

### BACKGROUND ART

In a semiconductor light emitting device including a plurality of photonic crystal lasers, a drive circuit for driving each photonic crystal laser is known (see, for example, Non Patent Literature 1). Non Patent Literature 1 describes a drive circuit having a plurality of digital-to-analog converters, a plurality of operational amplifiers, and a plurality of transistors so as to correspond to each of a plurality of photonic crystal lasers. In the drive circuit described in Non Patent Literature 1, a 12-bit digital control signal from a microcontroller is digital-to-analog converted to drive a transistor and control the current flowing through the laser.

Patent Literature 1 discloses a shape measuring device. The shape measuring device includes three or more light sources arranged in a line to project a grid pattern. Non Patent Literature 3 discloses a three-dimensional shape measurement method using structured illumination. Non Patent Literature 1 further discloses a phase shift method using a stripe pattern.

### CITATION LIST

### Patent Literature

Patent Literature 1: Japanese Unexamined Patent Publication No. 2011-242178

### Non Patent Literature

Non Patent Literature 1: “Study on beam shape control based on in-plane mutual entrainment phenomenon of photonic crystal lasers”, Menaka De Zoysa et al., Proceedings of the 81st Autumn Meeting of the Japan Society of Applied Physics, 10p-Z18-8, 2020
Non Patent Literature 2: Y Kurosaka et al., “Effects of non-lasing band in two-dimensional photonic-crystal lasers clarified using omnidirectional band structure”, Opt. Express 20, 21773-21783 (2012)
Non Patent Literature 3: Jason Geng, “Structured-light 3D surface imaging: a tutorial”, Advances in Optics and Photonics 3, pp. 128-160 (2011)

### SUMMARY OF INVENTION

### Technical Problem

An integrable phase modulating (iPM) laser is known that outputs a desired optical image by phase modulation in a phase modulation layer. A semiconductor light emitting device including a plurality of iPM lasers can be applied to a variety of applications. For example, it can be applied to three-dimensional measurement by sequentially outputting optical images of periodic stripe patterns from the respective iPM lasers and shifting the phases of the stripe patterns output from the respective iPM lasers. However, when the drive circuit described in Non Patent Literature 1 is applied to the semiconductor light emitting device including a plurality of iPM lasers, the following problems occur. That is, a plurality of signal lines are required between the microcontroller and the digital-to-analog converter, and a plurality of digital-to-analog converters are provided so as to correspond to the plurality of iPM lasers. Therefore, the total number of signal lines is huge. In addition, since a plurality of operational amplifiers and a plurality of transistors are provided, the area of the entire drive circuit can become large. In addition, a plurality of digital-to-analog converters, a plurality of operational amplifiers, and a plurality of transistors are provided so as to correspond to the plurality of iPM lasers. For this reason, power consumption (standby power) also occurs in the plurality of digital-to-analog converters, the plurality of operational amplifiers, and the plurality of transistors corresponding to the iPM lasers that are not in operation. Therefore, there is concern about heat generation due to standby power. Depending on the application of the semiconductor light emitting device (for example, acquisition of a stereoscopic image of the oral cavity in dentistry), it is required to reduce the amount of heat generated and to make the device smaller.

An object of one aspect of the present disclosure is to provide a semiconductor light emitting device that can reduce the amount of heat generated and can be made smaller.

### Solution to Problem

A semiconductor light emitting device according to one aspect of the present disclosure is [1]“a semiconductor light emitting device, including: a plurality of iPM lasers each having a first surface and a second surface opposite to the first surface and outputting light from the first surface; and a drive circuit that supplies a drive current to cause each of the plurality of iPM lasers to emit light, wherein the drive circuit includes: a common current source circuit for the plurality of iPM lasers; a plurality of switch sections provided corresponding to the plurality of iPM lasers, respectively, for ON/OFF switching of the drive current; and a switch operating section that individually operates each of the plurality of switch sections”.

In the semiconductor light emitting device described in [1] above, the drive current can be supplied to each iPM laser corresponding to each of the plurality of switch sections by individually operating each of the plurality of switch sections using the switch operating section. When a plurality of current source circuits corresponding to the respective iPM lasers are provided, even in the current source circuit corresponding to the iPM laser that is not in operation, power consumption (standby power) occurs because the current source circuit itself is in operation. In the semiconductor light emitting device described in [1] above, since the drive current is supplied based on the current generated by the common current source circuit, the amount of heat generated due to standby power can be reduced. In addition, since the current source circuit is common, fewer current source circuits is needed. Therefore, the semiconductor light emitting device can be made smaller.

The semiconductor light emitting device according to one aspect of the present disclosure may be [2]“the semiconductor light emitting device described in [1] above, wherein each of the plurality of switch sections includes a first switch and a second switch connected in series to the first switch, and the switch operating section includes a first shift register to operate the first switch and a second shift register to operate the second switch”. According to the semiconductor light emitting device described in [2], the drive current can be individually supplied only to the iPM laser for which both the first switch and the second switch are turned on. Then, the first shift register can specify the iPM lasers to be driven, for example, in units of rows, and the second shift register can specify the iPM lasers to be driven, for example, in units of columns. Therefore, it becomes easy to individually supply the drive current to the plurality of iPM lasers arranged across a plurality of rows and a plurality of columns.

The semiconductor light emitting device according to one aspect of the present disclosure may be [3]“the semiconductor light emitting device described in [1] or [2] above, wherein the drive circuit further includes a plurality of current mirror circuits respectively corresponding to the plurality of iPM lasers, each of the plurality of current mirror circuits has a first current path and a second current path through which current having a magnitude proportional to a magnitude of current flowing through the first current path flows, the first current path is connected to the common current source circuit, and each of the plurality of switch sections is provided on the first current path, and the second current path is connected to the iPM laser corresponding to the current mirror circuit to which the second current path belongs, among the plurality of iPM lasers”. According to the semiconductor light emitting device described in [3], the drive current based on the current generated in the common current source circuit can be supplied to the iPM laser through the second current path.

The semiconductor light emitting device according to one aspect of the present disclosure may be [4]“the semiconductor light emitting device described in any one of [1] to [3] above, wherein the drive circuit further includes a plurality of oscillation prevention circuits respectively corresponding to the plurality of iPM lasers, each of the plurality of oscillation prevention circuits includes: an NMOS-FET including a source terminal connected to an anode terminal of each of the plurality of iPM lasers and a drain terminal connected to a first constant potential line; a first PMOS-FET including a gate terminal connected to the source terminal of the NMOS-FET and a drain terminal connected to a second constant potential line having a lower potential than the first constant potential line; and a second PMOS-FET that includes a drain terminal connected to a source terminal of the first PMOS-FET, a source terminal connected to a third constant potential line having a higher potential than the second constant potential line, and a gate terminal and supplies current to the first PMOS-FET according to an input voltage to the gate terminal, and a potential between the first PMOS-FET and the second PMOS-FET is supplied to a gate terminal of the NMOS-FET”. According to the semiconductor light emitting device described in [4], the resonance constant (Q value) can be reduced by providing the oscillation prevention circuit. Therefore, since ringing or peaking is suppressed, it is possible to drive the iPM laser stably.

The semiconductor light emitting device according to one aspect of the present disclosure may be [5]“the semiconductor light emitting device described in any one of [1] to [4] above, wherein a value of current generated by the common current source circuit is variable”. According to the semiconductor light emitting device described in [5], since the magnitude of the drive current is variable, the light amount of each iPM laser is changed, and as a result, the brightness of the optical image output from the plurality of iPM lasers can be changed.

The semiconductor light emitting device according to one aspect of the present disclosure may be [6]“the semiconductor light emitting device described in [5] above, wherein the common current source circuit further includes: an operational amplifier having a pair of input terminals, an input voltage being supplied to one of the pair of input terminals; a transistor having a control terminal connected to an output terminal of the operational amplifier; and a resistor section having one end connected to a current terminal of the transistor and to the other input terminal of the operational amplifier and the other end connected to a fourth constant potential line, a resistance value of the resistor section is variable, and switching operations of the plurality of switch sections are synchronized with an operation of changing the resistance value of the resistor section”. According to the semiconductor light emitting device described in [6], since the resistance value of the resistor section is variable, the value of the current generated in the current source circuit varies. In addition, since the switching operations of the plurality of switch sections are synchronized with the operation of changing the resistance value of the resistor section, the value of the drive current supplied to each iPM laser can be set for each iPM laser.

The semiconductor light emitting device according to one aspect of the present disclosure may be [7]“the semiconductor light emitting device described in [6] above, wherein the resistor section includes a plurality of partial circuits connected in parallel to each other between the one end and the other end of the resistor section, each of the plurality of partial circuits includes a resistor and a third switch connected in series to each other between the one end and the other end of the resistor section, and the switching operations of the plurality of switch sections are synchronized with a switching operation of the third switch”. According to the semiconductor light emitting device described in [7], the resistance value of the resistor section can be made variable, and the switching operations of the plurality of switch sections can be synchronized with the operation of changing the resistance value of the resistor section.

The semiconductor light emitting device according to one aspect of the present disclosure may be [8]“the semiconductor light emitting device described in [5] above, wherein the common current source circuit further includes: an operational amplifier having a pair of input terminals, an input voltage being supplied to one of the pair of input terminals; a transistor having a control terminal connected to an output terminal of the operational amplifier; and a resistor section having one end connected to a current terminal of the transistor and the other input terminal of the operational amplifier and the other end connected to a fourth constant potential line, and switching operations of the plurality of switch sections are synchronized with an operation of switching a value of the input voltage”. According to the semiconductor light emitting device described in [8], the value of the current generated in the current source circuit is changed by switching the value of the input voltage. In addition, since the switching operations of the plurality of switch sections are synchronized with the operation of switching the value of the input voltage, the value of the drive current supplied to each iPM laser can be set for each iPM laser.

The semiconductor light emitting device according to one aspect of the present disclosure may be [9]“the semiconductor light emitting device described in [5] above, wherein the drive circuit further includes: a serial-to-parallel converter for converting a serial signal including digital data indicating an instruction value of current for the common current source circuit into a parallel signal; and a digital-to-analog converter for converting the digital data converted into the parallel signal into an analog signal, and the common current source circuit generates current having a magnitude corresponding to the instruction value based on the analog signal”. According to the semiconductor light emitting device described in [9], since digital data indicating the instruction value of the current for the common current source circuit can be received as a serial signal from the outside, it is possible to reduce the number of wirings.

The semiconductor light emitting device according to one aspect of the present disclosure may be [10]“the semiconductor light emitting device described in any one of [1] to [9] above, wherein each of the plurality of iPM lasers includes: an active layer that is a light emitting section; a phase modulation layer optically coupled to the active layer; a first cladding layer located on the first surface side of the active layer and the phase modulation layer; a second cladding layer located on the second surface side of the active layer and the phase modulation layer; a second electrode located on the second surface side of the second cladding layer; and a first electrode located on the first surface side of the first cladding layer, the phase modulation layer includes: a base layer; and a plurality of different refractive index regions that are provided in the base layer so as to be two-dimensionally distributed on a plane perpendicular to a normal direction of the first surface and have a refractive index different from a refractive index of the base layer, in a state in which a virtual square lattice is set on the plane, the plurality of different refractive index regions are arranged so that a centroid of each of the plurality of different refractive index regions is away from a corresponding lattice point by a predetermined distance, and an angle of a line segment connecting the centroid of each of the plurality of different refractive index regions to the corresponding lattice point with respect to the virtual square lattice, which is an angle around each lattice point in the virtual square lattice, is set according to a phase distribution for forming an optical image, and at least two angles among the angles in the plurality of different refractive index regions are different from each other”. According to the semiconductor light emitting device described in [10], an iPM laser can be suitably realized.

The semiconductor light emitting device according to one aspect of the present disclosure may be [11]“the semiconductor light emitting device described in any one of [1] to [9] above, wherein each of the plurality of iPM lasers includes: an active layer that is a light emitting section; a phase modulation layer optically coupled to the active layer; a first cladding layer located on the first surface side of the active layer and the phase modulation layer; a second cladding layer located on the second surface side of the active layer and the phase modulation layer; a second electrode located on the second surface side of the second cladding layer; and a first electrode located on the first surface side of the first cladding layer, the phase modulation layer includes: a base layer; and a plurality of different refractive index regions that are provided in the base layer so as to be two-dimensionally distributed on a plane perpendicular to a normal direction of the first surface and have a refractive index different from that of the base layer, in a state in which a virtual square lattice is set on the plane, the plurality of different refractive index regions are arranged so that a centroid of each of the plurality of different refractive index regions is located on a straight line passing through a corresponding lattice point and inclined with respect to the virtual square lattice, and a distance along the straight line between the centroid of each of the plurality of different refractive index regions and the corresponding lattice point is set according to a phase distribution for forming an optical image, and an inclination of the straight line is uniform in the plurality of different refractive index regions”. According to the semiconductor light emitting device described in [11], an iPM laser can be suitably realized.

The semiconductor light emitting device according to one aspect of the present disclosure may be [12]“the semiconductor light emitting device described in any one of [1] to [11] above, wherein each of the plurality of iPM lasers is monolithically formed”. According to the semiconductor light emitting device described in [12], the assembly of the semiconductor light emitting device can be simplified by forming the plurality of iPM lasers within a single element.

The semiconductor light emitting device according to one aspect of the present disclosure may be [13]“the semiconductor light emitting device described in [12] above, wherein the plurality of iPM lasers and the drive circuit are provided on a common substrate”. According to the semiconductor light emitting device described in [13], since the drive circuit and the plurality of iPM lasers formed monolithically can be integrated on the common substrate, it is possible to make the device smaller.

The semiconductor light emitting device according to one aspect of the present disclosure may be [14]“the semiconductor light emitting device described in any one of [1] to [11] above, further including: a support substrate having a third surface and a fourth surface opposite to the third surface, wherein the plurality of iPM lasers are individually mounted on the third surface so that the second surface faces the third surface”. According to the semiconductor light emitting device described in [14], a plurality of iPM lasers can be formed discretely on the support substrate.

The semiconductor light emitting device according to one aspect of the present disclosure may be [15]“the semiconductor light emitting device described in [14] above, wherein the drive circuit is provided on the third surface or the fourth surface of the support substrate”. According to the semiconductor light emitting device described in [15], since the drive circuit and the plurality of iPM lasers formed discretely can be integrated on the support substrate, it is possible to make the device smaller.

The semiconductor light emitting device according to one aspect of the present disclosure may be [16]“the semiconductor light emitting device described in any one of [1] to [12] above, wherein the drive circuit is connected to the plurality of iPM lasers by bump bonding”. According to the semiconductor light emitting device described in [16], since the drive circuit and the plurality of iPM lasers can be integrated by connecting the drive circuit and the plurality of iPM lasers to each other by bump bonding, it is possible to make the device smaller.

### Advantageous Effects of Invention

According to one aspect of the present disclosure, it is possible to provide a semiconductor light emitting device that can reduce the amount of heat generated and can be made smaller.

### BRIEF DESCRIPTION OF DRAWINGS

FIG. 1 is a configuration drawing of a semiconductor light emitting device according to an embodiment.

FIG. 2 is a plan view of the semiconductor light emitting device shown in FIG. 1.

FIG. 3 is a schematic drawing showing a cross section of each iPM laser along the line III-III shown in FIG. 2.

FIG. 4 is a plan view of a phase modulation layer shown in FIG. 3.

FIG. 5 is an enlarged view of a part (unit constituent region) of the phase modulation layer shown in FIG. 4.

FIG. 6 is a drawing for explaining coordinate transformation from spherical coordinates to coordinates in an XYZ Cartesian coordinate system.

FIG. 7 is a plan view showing a reciprocal lattice space for a phase modulation layer of each iPM laser with M-point oscillation.

FIG. 8 is a conceptual drawing for explaining a state in which a diffraction vector is added to an in-plane wave number vector.

FIG. 9 is a drawing for schematically explaining a peripheral structure of a light line.

FIG. 10 is a drawing conceptually showing an example of a rotation angle distribution.

FIG. 11 is a conceptual drawing for explaining a state in which a diffraction vector is added to an in-plane wave number vector in a direction from which a wave number spread is excluded.

FIG. 12 is a plan view of a phase modulation layer according to a first modification.

FIG. 13 is an enlarged view of a part (unit constituent region) of the phase modulation layer shown in FIG. 12.

FIG. 14 is an overall block diagram of a drive circuit shown in FIG. 1.

FIG. 15 is a circuit diagram of the drive circuit shown in FIG. 1.

FIG. 16 is a detailed circuit diagram of a current source circuit shown in FIG. 15.

FIG. 17 is a drawing showing the configuration of a switch operating section shown in FIG. 14.

FIG. 18 is a schematic drawing showing the configuration of a three-dimensional measuring device.

FIG. 19 is a drawing showing a sinusoidal wave stripe pattern formed by the three-dimensional measuring device shown in FIG. 18.

(a) and (b) in FIG. 20 are drawings showing a first stripe element and a second stripe element.

(a) and (b) in FIG. 21 are drawings showing a third stripe element and a fourth stripe element.

FIG. 22 is a drawing showing a stripe pattern generated by combining first to fourth stripe elements.

(a) and (b) in FIG. 23 are drawings showing a first stripe pattern and a second stripe pattern.

(a) and (b) in FIG. 24 are drawings showing a third stripe pattern and a fourth stripe pattern.

(a) and (b) in FIG. 25 are drawings showing current source circuits according to the first modification example and a second modification example.

FIG. 26 is a side view of a semiconductor light emitting device according to a third modification example.

FIG. 27 is a side view of a semiconductor light emitting device according to a fourth modification example.

FIG. 28 is a part of a cross-sectional view of a semiconductor light emitting device according to a fifth modification example.

FIG. 29 is a part of a cross-sectional view of a semiconductor light emitting device according to a sixth modification example.

FIG. 30 is an exploded perspective view showing the configuration of a light source device according to a second embodiment of the present disclosure.

(a) and (b) in FIG. 31 are drawings schematically showing how light including stripe elements is projected from each of four iPM lasers onto a common projection region.

(a) and (b) in FIG. 32 are drawings schematically showing how light including stripe elements is projected from each of four iPM lasers onto a common projection region.

(a) and (b) in FIG. 33 are drawings schematically showing how light including stripe elements is projected from each of four iPM lasers onto a common projection region in a comparative example.

(a) and (b) in FIG. 34 are drawings schematically showing how light including stripe elements is projected from four iPM lasers onto a common projection region in a comparative example.

FIG. 35 is a drawing for explaining a problem caused by the positional deviation of a bright line in the above comparative example.

FIG. 36 is a graph showing a relationship between the distance and the deviation of the central angle when the arrangement pitch is 0.25 mm in Expression (35).

(a) and (b) in FIG. 37 are drawings for explaining one modification example of the second embodiment.

(a) and (b) in FIG. 38 are drawings for explaining one modification example of the second embodiment.

(a) and (b) in FIG. 39 are drawings for explaining a comparative example of one modification example of the second embodiment.

(a) and (b) in FIG. 40 are drawings for explaining a comparative example of one modification example of the second embodiment.

(a) and (b) in FIG. 41 are drawings for explaining another modification example of the second embodiment.

(a) and (b) in FIG. 42 are drawings for explaining another modification example of the second embodiment.

FIG. 43 is a chart showing conversion among decimal numbers, binary code that is another way of expressing binary numbers, and gray code.

FIG. 44 is a drawing showing an example of a combination of stripe patterns including a gray code.

FIG. 45 is a perspective view showing the configuration of a light source device according to a third embodiment of the present disclosure.

FIG. 46 is a perspective view showing the configuration of a light source device according to the third embodiment of the present disclosure.

FIG. 47 is a perspective view showing the configuration of a light source device according to one modification example of the third embodiment.

FIG. 48 is a perspective view showing the configuration of a light receiving and emitting module according to a fourth embodiment of the present disclosure.

FIG. 49 is a perspective view showing the configuration of a light receiving and emitting module according to one modification example of the fourth embodiment.

FIG. 50 is a perspective view showing the configuration of a light receiving and emitting module according to another modification example of the fourth embodiment.

### DESCRIPTION OF EMBODIMENTS

Hereinafter, embodiments of the present disclosure will be described in detail with reference to the drawings. The same or equivalent portions in the drawings are denoted by the same reference numerals, and repeated description thereof will be omitted.

### First Embodiment

### [Configuration of Semiconductor Light Emitting Device]

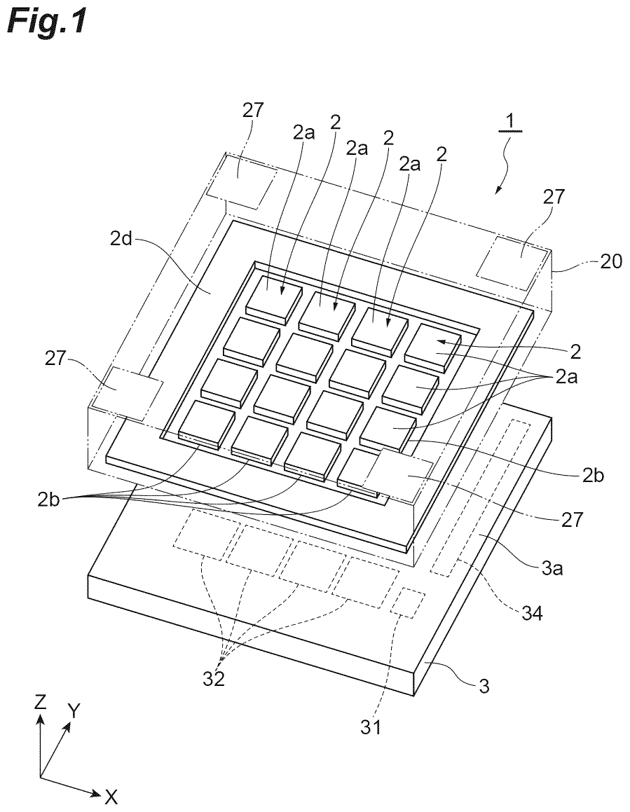

FIG. 1 is a configuration drawing of a semiconductor light emitting device 1 according to a first embodiment. As shown in FIG. 1, a semiconductor light emitting device 1 includes a plurality of iPM lasers 2 and a drive circuit 3. Each of the plurality of iPM lasers 2 has a first surface 2a and a second surface 2b on a side opposite to the first surface 2a. The drive circuit 3 has a surface 3a facing the second surface 2b. The drive circuit 3 includes a current source circuit 31, a plurality of current mirror circuits 32, and a switch operating section 34. Each of the plurality of current mirror circuits 32 is electrically connected to each of the plurality of iPM lasers 2. The switch operating section 34 is electrically connected to the plurality of iPM lasers 2. For example, electrical contacts corresponding to each of the plurality of current mirror circuits 32 and the switch operating section 34 are formed on the surface 3a, and the plurality of current mirror circuits 32 and the switch operating section 34 are connected to the plurality of iPM lasers 2 by bump bonding through the electrical contacts. The semiconductor light emitting device 1 further includes a semiconductor region 2d and a semiconductor substrate 20. The semiconductor region 2d surrounds the plurality of iPM lasers 2 in an annular shape. The plurality of iPM lasers 2 are formed on the semiconductor substrate 20, and the semiconductor substrate 20 is formed of a semiconductor such as GaAs, for example. The planar shape of the semiconductor substrate 20 is a square or a rectangle, and a first electrode 27 that forms an ohmic contact with the back surface of the semiconductor substrate 20 and defines a reference potential is formed at each of the four corners of the back surface of the semiconductor substrate 20. In this manner, the plurality of iPM lasers 2 are formed on the common semiconductor substrate 20. In other words, the plurality of iPM lasers 2 are monolithically formed. The iPM lasers 2 adjacent to each other are formed at predetermined distances. Each of the plurality of iPM lasers 2 outputs a laser beam including a desired optical image from the first surface 2a. The drive circuit 3 supplies a drive current for causing each of the plurality of iPM lasers 2 to emit light. The semiconductor region 2d distributes the load applied to each iPM laser 2 when the iPM laser 2 is mounted on the drive circuit 3, thereby improving flatness. In the following description, a direction perpendicular to the first surface 2a is referred to as a Z-axis direction, a direction parallel to the first surface 2a is referred to as an X-axis direction, and a direction perpendicular to both the Z-axis direction and the X-axis direction is referred to as a Y-axis direction.

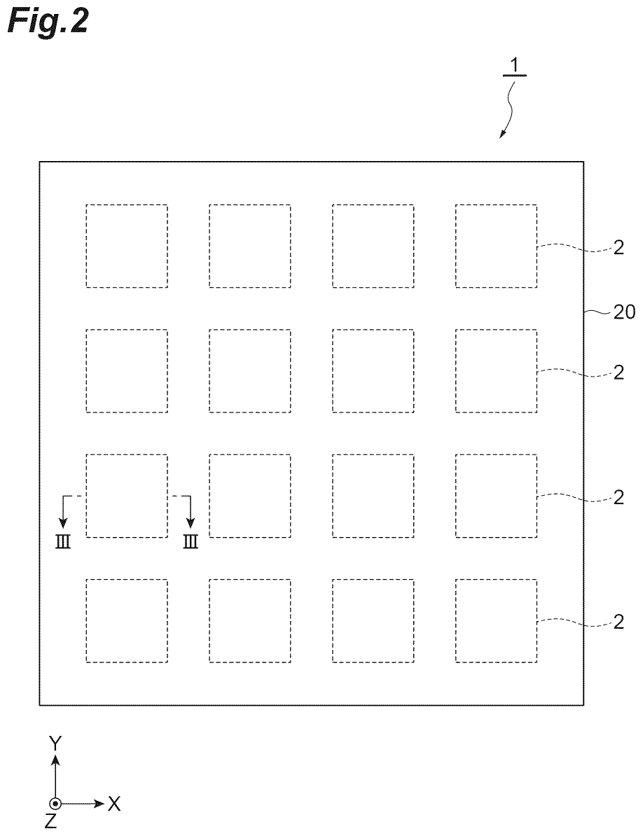

FIG. 2 is a plan view of the semiconductor light emitting device 1 shown in FIG. 1. In FIG. 2, the semiconductor region 2d is omitted. A plurality of iPM lasers 2 are arranged in a two-dimensional matrix with the X-axis direction and the Y-axis direction as a row direction and a column direction, respectively. In the present embodiment, a total of 16 iPM lasers 2 are arranged, four in the X-axis direction (row direction) and four in the Y-axis direction (column direction).

### [Configuration of iPM Laser]

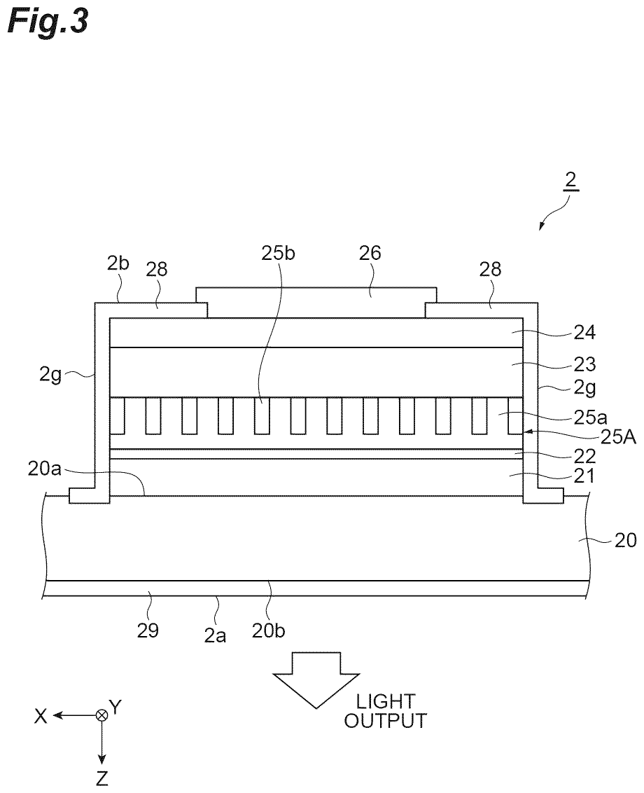

FIG. 3 is a schematic drawing showing a cross section of each iPM laser 2 taken along the line III-III shown in FIG. 2. Each iPM laser 2 forms a standing wave in an in-plane direction parallel to a virtual plane defined by the X-axis direction and the Y-axis direction, and outputs a phase-controlled plane wave in the Z-axis direction. As will be described later, light that forms an optical image with a two-dimensional arbitrary shape is output along the normal direction (that is, Z-axis direction) of the main surface 20a of the semiconductor substrate 20, an inclined direction crossing the normal direction, or both the normal direction and the inclined direction.

Each iPM laser 2 includes an active layer 22 serving as a light emitting section provided on the semiconductor substrate 20, a phase modulation layer 25A optically coupled to the active layer 22, a first cladding layer 21 located on the first surface 2a side with respect to the active layer 22 and the phase modulation layer 25A, a second cladding layer 23 located on the second surface 2b side with respect to the active layer 22 and the phase modulation layer 25A, and a contact layer 24 provided on the second cladding layer 23. The semiconductor substrate 20, the first cladding layer 21, the active layer 22, the second cladding layer 23, and the contact layer 24 are formed of a compound semiconductor such as a GaAs-based semiconductor, an InP-based semiconductor, or a nitride-based semiconductor, for example. The energy band gaps of the first cladding layer 21 and the second cladding layer 23 are larger than the energy band gap of the active layer 22. The thickness directions of the semiconductor substrate 20, the first cladding layer 21, the active layer 22, the second cladding layer 23, and the contact layer 24 match the Z-axis direction.

In the present embodiment, the phase modulation layer 25A is provided between the active layer 22 and the second cladding layer 23. The phase modulation layer 25A may be provided between the first cladding layer 21 and the active layer 22. If necessary, an optical guide layer may be provided between the active layer 22 and the second cladding layer 23 and/or between the active layer 22 and the first cladding layer 21. The thickness direction of the phase modulation layer 25A matches the Z-axis direction. The optical guide layer may include a carrier barrier layer for efficiently confining carriers in the active layer 22.

Between the iPM lasers 2 adjacent to each other, a separation region 2g is formed. The separation region 2g is a slit (gap) formed by either dry etching or wet etching. The separation region 2g is insulated by forming an insulating film 28 such as SiN on the side walls of the slit, thereby suppressing current leakage due to solder during assembly. The separation region 2g can also be formed by insulating a semiconductor layer modified by high-intensity light (electric field) or by using either impurity diffusion or ion implantation.

The phase modulation layer 25A includes a base layer 25a and a plurality of different refractive index regions 25b. The base layer 25a is formed of a first refractive index medium. Each different refractive index region 25b is formed of a second refractive index medium having a refractive index different from the refractive index of the first refractive index medium, and is present within the base layer 25a. The two-dimensional arrangement of the plurality of different refractive index regions 25b includes an approximately periodic structure. Assuming that the equivalent refractive index of the mode is n, the wavelength λ₀ (=√2)×a×n, a is the lattice spacing) selected by the phase modulation layer 25A is included in the emission wavelength range of the active layer 22. The phase modulation layer 25A can selectively output light having a band edge wavelength near the wavelength λ₀, among the emission wavelengths of the active layer 22, to the outside. The laser light incident on the phase modulation layer 25A forms a predetermined mode corresponding to the arrangement of the different refractive index regions 25b within the phase modulation layer 25A, and is emitted to the outside from the first surface 2a as a laser beam having a desired pattern.

Each iPM laser 2 further includes a second electrode 26 provided on the contact layer 24 and the first electrode 27 provided on a back surface 20b of the semiconductor substrate 20 (see FIG. 1). The second electrode 26 is located on the second surface 2b side with respect to the second cladding layer 23, and forms an ohmic contact with the contact layer 24. The first electrode 27 is located on the first surface 2a side of the first cladding layer 21, and forms an ohmic contact with the semiconductor substrate 20. The second electrode 26 is provided in the central region of the contact layer 24. A portion of the contact layer 24 other than the second electrode 26 is covered with the insulating film 28. The contact layer 24 that is not in contact with the second electrode 26 may be removed. A portion of the back surface 20b of the semiconductor substrate 20 other than the first electrode 27 is covered with an anti-reflection film 29.

When a drive current is supplied between the second electrode 26 and the first electrode 27, recombination of electrons and holes occurs in the active layer 22, and light is emitted within the active layer 22. The electrons and holes that contribute to light emission in the active layer 22 and the generated light are efficiently confined between the first cladding layer 21 and the second cladding layer 23.

The light output from the active layer 22 enters the phase modulation layer 25A to form a predetermined mode corresponding to the lattice structure inside the phase modulation layer 25A. The laser light output from the phase modulation layer 25A is directly output from the back surface 20b to the outside of each iPM laser 2, or is reflected by the second electrode 26 and then output from the back surface 20b to the outside of each iPM laser 2. At this time, signal light included in the laser light is output along the normal direction of the main surface 20a, an inclined direction crossing the normal direction, or both the normal direction and the inclined direction. Of the output light, the signal light forms a desired optical image. The signal light is mainly 1st-order light and −1st-order light.

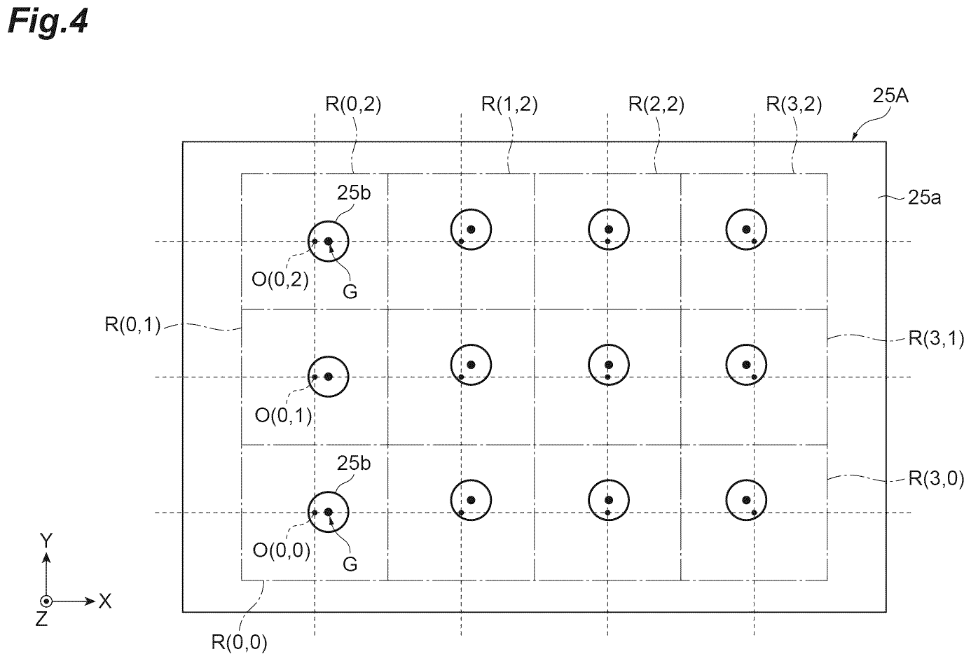

FIG. 4 is a plan view of the phase modulation layer 25A shown in FIG. 3. The phase modulation layer 25A includes the base layer 25a and the plurality of different refractive index regions 25b. The base layer 25a is formed of a first refractive index medium. The plurality of different refractive index regions 25b are formed of a second refractive index medium having a refractive index different from the refractive index of the first refractive index medium. Here, a virtual square lattice is set on one surface of the phase modulation layer 25A that matches a plane parallel to the plane formed by the X-axis direction and the Y-axis direction. One side of the square lattice is parallel to the X axis, and the other side is parallel to the Y axis. At this time, a square-shaped unit constituent region R(x, y) centered on a lattice point O of the square lattice can be set two-dimensionally over a plurality of columns (x=0, 1, 2, 3, . . . ) along the X axis and a plurality of rows (y=0, 1, 2, . . . ) along the Y axis. Assuming that the XY coordinates of each unit constituent region R are given by the centroid position of each unit constituent region R, this centroid position matches the lattice point O of the virtual square lattice. The plurality of different refractive index regions 25b are provided, for example, one by one in each unit constituent region R. The planar shape of the different refractive index region 25b is, for example, a circular shape. The lattice point O may be located outside the different refractive index region 25b, or may be included inside the different refractive index region 25b.

The ratio of the area S of the different refractive index region 25b to one unit constituent region R is called a filling factor (FF). Assuming that the lattice spacing of the square lattice is a, the filling factor FF of the different refractive index region 25b is given as S/a². S is the area of the different refractive index region 25b in the X-Y plane. For example, when the shape of the different refractive index region 25b is a perfect circle, S is given as S=π(d/2)² using the diameter d of the perfect circle. When the different refractive index region 25b has a square shape, S is given as S=LA² using the length LA of one side of the square.

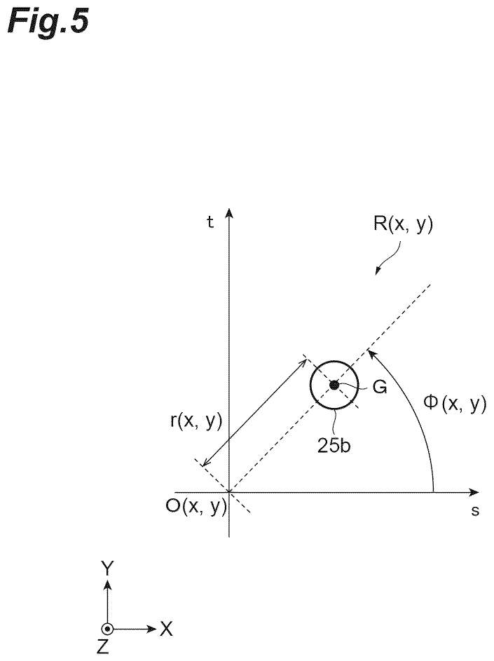

FIG. 5 is an enlarged view of a part (unit constituent region R) of the phase modulation layer 25A shown in FIG. 4. As shown in FIG. 5, each of the different refractive index regions 25b has a centroid G, and the position of the centroid G in the unit constituent region R is given by an s axis and a t axis perpendicular to each other at the lattice point O. Here, in the unit constituent region R(x, y) defined by the s axis and the t axis perpendicular to each other, the angle between a vector from the lattice point O(x, y) toward the centroid G and the s axis is defined as ϕ(x, y). x indicates the position of an x-th lattice point along the X axis, and y indicates the position of a y-th lattice point along the Y axis. When the angle ϕ is 0°, the direction of a vector connecting the lattice point O(x, y) and the centroid G to each other matches the positive direction of the X axis. The length of the vector connecting the lattice point O(x, y) and the centroid G to each other is defined as r(x, y). In one example, r(x, y) is constant regardless of x and y (throughout the phase modulation layer 25A).

As shown in FIG. 4, the direction of the vector connecting the lattice point O(x, y) and the centroid G (the centroid of the corresponding different refractive index region 25b), that is, the angle ϕ of the centroid G of the different refractive index region 25b around the lattice point, is set individually for each lattice point O(x, y) according to the phase pattern corresponding to the desired optical image. The phase pattern, that is, the angle ϕ(x, y), has a specific value for each position determined by the values of x and y, but is not necessarily expressed by a specific function. That is, the angle ϕ(x, y) is determined from the phase distribution extracted from the complex amplitude distribution obtained by inverse Fourier transform on the desired optical image. Of the angles ϕ in the plurality of different refractive index regions 25b, at least two angles ϕ are different from each other. When calculating the complex amplitude distribution from the desired optical image, the reproducibility of the beam pattern is improved by applying an iterative algorithm such as a Gerchberg-Saxton (GS) method, which is commonly used in the calculation for hologram generation.

The beam pattern output from phase modulation layer 25A includes, for example, a stripe pattern. In order to obtain a desired beam pattern, the distribution of the angles ϕ(x, y) of the different refractive index regions 25b in the phase modulation layer 25A is determined by the following procedure.

As a first prerequisite, in the XYZ Cartesian coordinate system defined by the Z axis that matches the normal direction and the X-Y plane that matches one surface of the phase modulation layer 25A including a plurality of different refractive index regions 25b, a virtual square lattice formed by M1 (an integer of 1 or more)×N1 (an integer of 1 or more) unit constituent regions R, each of which has a square shape, is set on the X-Y plane.

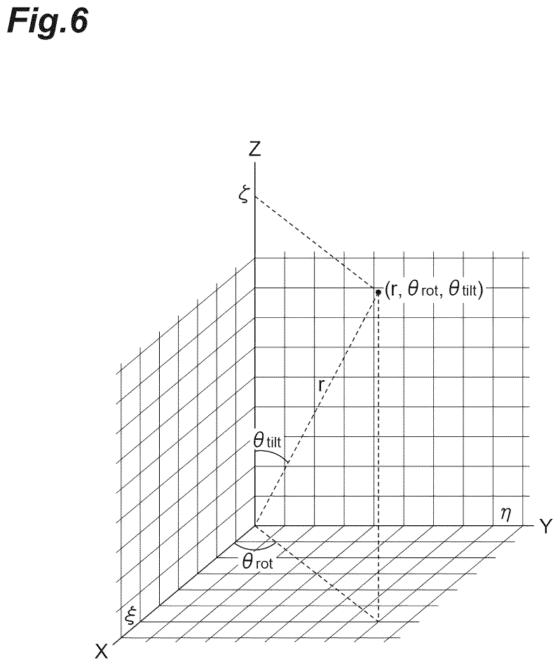

As a second prerequisite, it is assumed that the coordinates (ξ, η, ζ) in the XYZ Cartesian coordinate system satisfy the relationship shown in the following Expressions (1) to (3) with respect to the spherical coordinates (r, θᵣₒₜ, θₜᵢₗₜ) defined by the length r of the radius, a tilt angle θₜᵢₗₜ from the Z axis, and a rotation angle θᵣₒₜ from the X axis specified on the X-Y plane, as shown in FIG. 6. FIG. 6 is a drawing for explaining coordinate transformation from the spherical coordinates (r, θᵣₒₜ, θₜᵢₗₜ) to the coordinates (ξ, η, ζ) in the XYZ Cartesian coordinate system. By the coordinates (ξ, η, ζ), a designed optical image on a predetermined plane set in the XYZ Cartesian coordinate system, which is the real space, is expressed.

Assuming that the beam pattern corresponding to the optical image output from each iPM laser 2 is a group of bright spots directed in a direction defined by the angles θₜᵢₗₜ and θᵣₒₜ, it is assumed that the angles Nₜᵢₗₜ and θᵣₒₜ are converted into a coordinate value kₓ on the Kₓ axis and a coordinate value k_{y} on the K_{y} axis. The coordinate value kₓ is a normalized wave number defined by the following Expression (4) and corresponds to the X axis. The coordinate value k_{y} is a normalized wave number defined by the following Expression (5), corresponds to the Y axis, and is perpendicular to the Kₓ axis. The normalized wave number means a wave number normalized by setting the wave number 2π/a corresponding to the lattice spacing of the virtual square lattice to 1.0. At this time, in the wave number space defined by the Kₓ axis and the K_{y} axis, a specific wave number range including a beam pattern corresponding to an optical image is M2 (an integer of 1 or more)×N2 (an integer of 1 or more) image regions FR each having a square shape. The integer M2 does not have to be equal to the integer M1. Similarly, integer N2 does not have to be equal to the integer N1. Expressions (4) and (5) are disclosed in, for example, Non Patent Literature 2.

$$\begin{matrix}[ Expression 1 ] & \\ ξ = r sin {θ}_{tilt} cos {θ}_{rot} & ( 1 )\end{matrix}$$

$$\begin{matrix}[ Expression 2 ] & \\ η = r sin {θ}_{tilt} sin {θ}_{rot} & ( 2 )\end{matrix}$$

$$\begin{matrix}[ Expression 3 ] & \\ ζ = r cos {θ}_{tilt} & ( 3 )\end{matrix}$$

$$\begin{matrix}[ Expression 4 ] & \\ {k}_{x} = \frac{a}{λ} sin {θ}_{tilt} cos {θ}_{rot} & ( 4 )\end{matrix}$$

$$\begin{matrix}[ Expression 5 ] & \\ {k}_{y} = \frac{a}{λ} sin {θ}_{tilt} sin {θ}_{rot} & ( 5 )\end{matrix}$$

In Expressions (4) and (5), a indicates a lattice constant of a virtual square lattice, and λ indicates an oscillation wavelength of each iPM laser 2.

As a third prerequisite, in the wave number space, a complex amplitude F(x, y) obtained by two-dimensional inverse discrete Fourier transforming an image region FR(kₓ, k_{y}), which is specified by a coordinate component kₓ (an integer of 0 or more and M2−1 or less) in a Kₓ-axis direction and a coordinate component k_{y} (an integer of 0 or more and N2−1 or less) in a K_{y}-axis direction, into the unit constituent region R(x, y) on the X-Y plane, which is specified by a coordinate component x (an integer of 0 or more and M1−1 or less) in the x-axis direction and a coordinate component y (an integer of 0 or more and N1−1 or less) in the y-axis direction, is given by the following Expression (6), where j is an imaginary unit. The complex amplitude F(x, y) is defined by the following Expression (7) where A(x, y) is the amplitude term and P(x, y) is the phase term. As a fourth prerequisite, the unit constituent region R(x, y) is defined by the s axis and the t axis that are parallel to the X axis and the Y axis, respectively, and perpendicular to each other at the lattice point O(x, y) that is the center of the unit constituent region R(x, y).

$$\begin{matrix}[ Expression 6 ] & \\ F ( x , y ) = {\sum }_{{k}_{x} = 0}^{M 2 - 1} {\sum }_{{k}_{y} = 0}^{N 2 - 1} F R ( {k}_{x} , {k}_{y} ) exp [ j 2 π ( \frac{{k}_{x}}{M 2} x + \frac{{k}_{y}}{N 2} y ) ] & ( 6 )\end{matrix}$$

$$\begin{matrix}[ Expression 7 ] & \\ F ( x , y ) = A ( x , y ) \times exp [ jP ( x , y ) ] & ( 7 )\end{matrix}$$

Under the above first to fourth prerequisites, the phase modulation layer 25A is formed to satisfy the following fifth and sixth conditions. That is, the fifth condition is satisfied when, within the unit constituent region R(x, y), the centroid G is located away from the lattice point O(x, y). The sixth condition is satisfied when, with a line segment length r(x, y) from the lattice point O(x, y) to the corresponding centroid G being set to a common value in each of the M1×N1 unit constituent regions R, the corresponding different refractive index region 25b is located within the unit constituent region R(x, y) so that the angle ϕ(x, y) between the s axis and the line segment connecting the lattice point O(x, y) and the corresponding centroid G to each other satisfies the relationship ϕ(x, y)=C×P(x, y)+B, where C is a proportional constant, for example, 180°/π, and B is any constant, for example, 0.

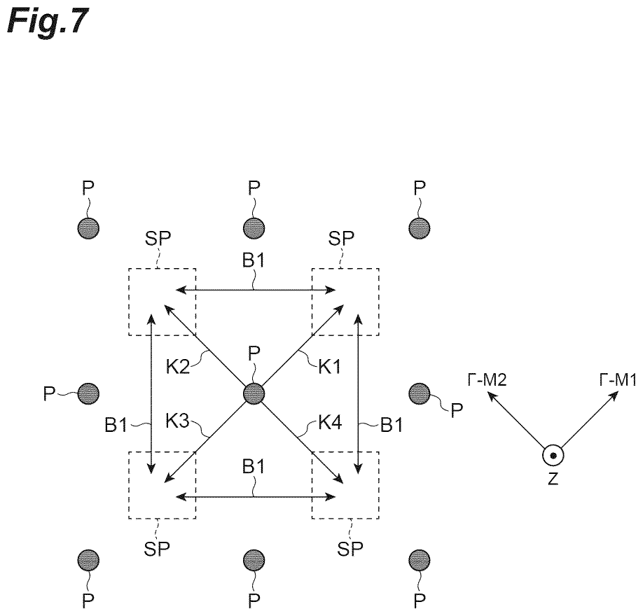

Each iPM laser 2 may oscillate at the F point or at the M point. Next, M-point oscillation of each iPM laser 2 will be described. For M-point oscillation of each iPM laser 2, it is preferable that the lattice spacing a of the virtual square lattice, the emission wavelength λ of the active layer 22, and the equivalent refractive index n of the mode satisfy the condition λ=(√2)n×a. FIG. 7 is a plan view showing a reciprocal lattice space related to the phase modulation layer of each iPM laser 2 with M-point oscillation. A point P in the drawing indicates a reciprocal lattice point. In the drawing, an arrow B1 indicates a primitive reciprocal lattice vector, and arrows K1, K2, K3, and K4 indicate four in-plane wave number vectors. Each of the in-plane wave number vectors K1 to K4 has a wave number spread SP due to the rotation angle distribution ϕ(x, y).

The shape and size of the wave number spread SP are the same as those in the case of the above-described F-point oscillation. In each of the iPM lasers 2 with M-point oscillation, the magnitudes of the in-plane wave number vectors K1 to K4 (that is, the magnitude of the standing wave in the in-plane direction) are smaller than the magnitude of the primitive reciprocal lattice vector B1. Therefore, the sum of the in-plane wave number vectors K1 to K4 and the primitive reciprocal lattice vector B1 is not 0, and the wave number in the in-plane direction cannot become 0 due to diffraction. For this reason, diffraction in a direction perpendicular to the plane (Z-axis direction) does not occur. In this state, each iPM laser 2 with M-point oscillation does not output the 0th-order light in the direction perpendicular to the plane (Z-axis direction) and the 1st-order light and the −1st-order light in a direction inclined with respect to the Z-axis direction.

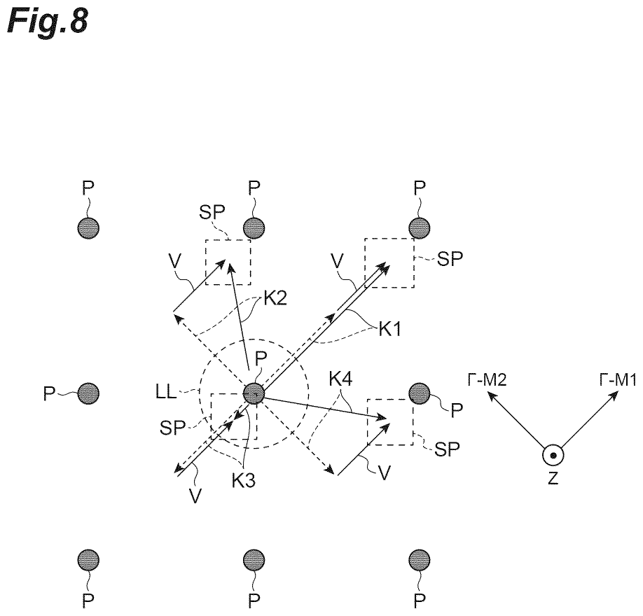

In the present embodiment, by applying the following measures to the phase modulation layer 25A in each iPM laser 2 with M-point oscillation, it is possible to output a part of the 1st-order light and the −1st-order light without outputting the 0th-order light. Specifically, as shown in FIG. 8, a diffraction vector V having a predetermined magnitude and direction is added to the in-plane wave number vectors K1 to K4, so that the magnitude of at least one of the in-plane wave number vectors K1 to K4 (in-plane wave number vector K3 in the drawing) is made smaller than 2π/λ. In other words, at least one (in-plane wave number vector K3) of the in-plane wave number vectors K1 to K4 after the diffraction vector V is added falls within a circular region (light line) LL with a radius of 2π/λ.

The in-plane wave number vectors K1 to K4 shown by the broken lines in FIG. 8 indicate vectors before the diffraction vector V is added, and the in-plane wave number vectors K1 to K4 shown by the solid lines indicate vectors after the diffraction vector V is added. The light line LL corresponds to the total reflection condition, and a wave number vector having a magnitude that falls within the light line LL has a component in the direction perpendicular to the surface (Z-axis direction). In one example, the direction of the diffraction vector V is along the Γ-M1 axis or the Γ-M2 axis. The magnitude of the diffraction vector V is within the range of 2π/(√2)a−2π/λ to 2π/(√2)a+2π/λ, and is, for example, 2π/(√2)a.

Subsequently, the magnitude and direction of the diffraction vector V for making at least one of the in-plane wave number vectors K1 to K4 fall within the light line LL are examined. The following Expressions (8) to (11) indicate the in-plane wave number vectors K1 to K4 before the diffraction vector V is added.

$$\begin{matrix}[ Expression 8 ] & \\ K 1 = ( \frac{π}{a} + Δ kx , \frac{π}{a} + Δ ky ) & ( 8 )\end{matrix}$$

$$\begin{matrix}[ Expression 9 ] & \\ K 2 = ( - \frac{π}{a} + Δ kx , \frac{π}{a} + Δ ky ) & ( 9 )\end{matrix}$$

$$\begin{matrix}[ Expression 10 ] & \\ K 3 = ( - \frac{π}{a} + Δ kx , - \frac{π}{a} + Δ ky ) & ( 10 )\end{matrix}$$

$$\begin{matrix}[ Expression 11 ] & \\ K 4 = ( \frac{π}{a} + Δ kx , - \frac{π}{a} + Δ ky ) & ( 11 )\end{matrix}$$

The spreads Δkx and Δky of the wave number vector satisfy the following Expressions (12) and (13), respectively. The maximum value Δkxₘₐₓ of the spread in the x-axis direction and the maximum value Δkyₘₐₓ of the spread in the y-axis direction of the in-plane wave number vector are defined by the angular spread of the designed optical image.

$$\begin{matrix}[ Expression 12 ] & \\ - Δ {kx}_{max} \leq Δ kx \leq Δ {kx}_{max} & ( 12 )\end{matrix}$$

$$\begin{matrix}[ Expression 13 ] & \\ - Δ {ky}_{max} \leq Δ ky \leq Δ {ky}_{max} & ( 13 )\end{matrix}$$

When the diffraction vector V is expressed as in the following Expression (14), the in-plane wave number vectors K1 to K4 after the diffraction vector V is added become the following Expressions (15) to (18).

$$\begin{matrix}[ Expression 14 ] & \\ V = ( Vx , Vy ) & ( 14 )\end{matrix}$$

$$\begin{matrix}[ Expression 15 ] & \\ K 1 = ( \frac{π}{a} + Δ kx + Vx , \frac{π}{a} + Δ ky + Vy ) & ( 15 )\end{matrix}$$

$$\begin{matrix}[ Expression 16 ] & \\ K 2 = ( - \frac{π}{a} + Δ kx + Vx , \frac{π}{a} + Δ ky + Vy ) & ( 16 )\end{matrix}$$

$$\begin{matrix}[ Expression 17 ] & \\ K 3 = ( - \frac{π}{a} + Δ kx + Vx , - \frac{π}{a} + Δ ky + Vy ) & ( 17 )\end{matrix}$$

$$\begin{matrix}[ Expression 18 ] & \\ K 4 = ( \frac{π}{a} + Δ kx + Vx , - \frac{π}{a} + Δ ky + Vy ) & ( 18 )\end{matrix}$$

Considering that in Expressions (15) to (18), any of the wave number vectors K1 to K4 falls within the light line LL, the relationship of the following Expression (19) is satisfied.

$$\begin{matrix}[ Expression 19 ] & \\ {( \pm \frac{π}{a} + Δ kx + Vx )}^{2} + {( \pm \frac{π}{a} + Δ ky + Vy )}^{2} < {( \frac{2 π}{λ} )}^{2} & ( 19 )\end{matrix}$$

That is, by adding the diffraction vector V satisfying Expression (19), any of the wave number vectors K1 to K4 falls within the light line LL, and a part of the 1st-order light and −1st-order light is output.

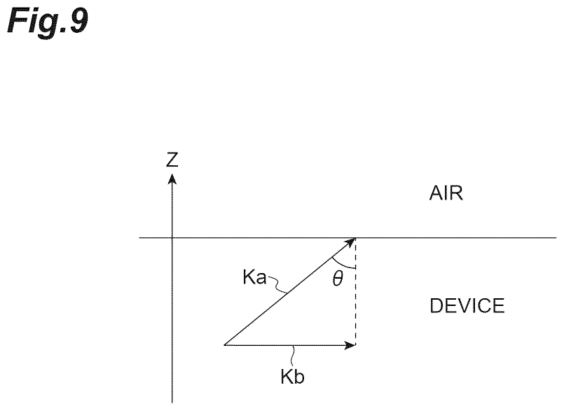

The magnitude (radius) of the light line LL is set to 2π/λ, for the following reasons. FIG. 9 is a drawing for schematically explaining a peripheral structure of the light line LL. In this drawing, a boundary between the device and air is shown as viewed from a direction perpendicular to the Z-axis direction. The magnitude of the wave number vector of light in vacuum is 2π/λ. However, when light propagates in a device medium as shown in FIG. 9, the magnitude of a wave number vector Ka in a medium with a refractive index n is 2πn/λ. At this time, in order for light to propagate through the boundary between the device and air, the wave number components parallel to the boundary need to be continuous (law of conservation of wave number).

In FIG. 9, when an angle θ is formed by the wave number vector Ka and the Z axis, the length of a wave number vector Kb (that is, an in-plane wave number vector) projected onto the plane is (2πn/λ)sin θ. On the other hand, generally, due to the relationship of the refractive index n>1 of the medium, the law of conservation of wave number does not hold at angles where the in-plane wave number vector Kb in the medium is larger than 2π/λ. At this time, the light is totally reflected and cannot be extracted to the air side. The magnitude of the wave number vector corresponding to this total reflection condition is the magnitude of the light line LL, that is, 2π/λ.

As an example of a specific method for adding the diffraction vector V to the in-plane wave number vectors K1 to K4, a method can be considered in which a rotation angle distribution ϕ2(x, y) (second phase distribution) that is not related to the optical image is superimposed on a rotation angle distribution ϕ1(x, y) (first phase distribution), which is a phase distribution according to the optical image. In this case, the rotation angle distribution ϕ (x, y) of the phase modulation layer 25A is expressed as ϕ(x, y)=ϕ1(x, y)+ϕ2(x, y). ϕ1(x, y) corresponds to the phase of the complex amplitude when the optical image is Fourier transformed as described above. ϕ2(x, y) is a rotation angle distribution for adding the diffraction vector V that satisfies the above-described Expression (19).

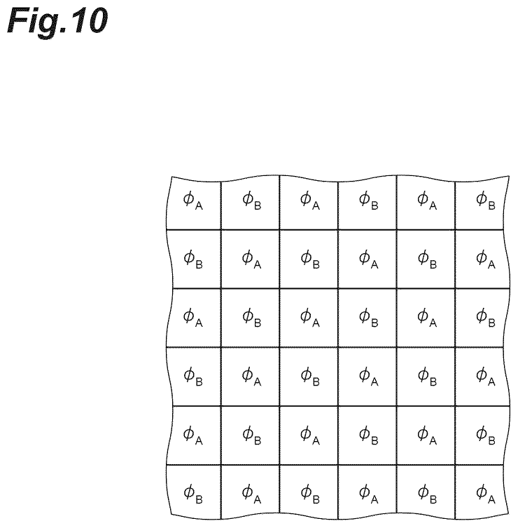

FIG. 10 is a drawing conceptually showing an example of the rotation angle distribution ϕ2(x, y). In the example shown in the drawing, a first phase value ϕ_{A} and a second phase value ϕ_{B}, which is a different value from the first phase value ϕ_{A}, are arranged in a checkerboard pattern. In one example, the phase value ϕ_{A} is 0 (rad) and the phase value ϕ_{B} is π (rad). In this case, the first phase value ϕ_{A} and the second phase value ϕ_{B} change in steps of π. By such an arrangement of phase values, the diffraction vector V along the Γ-M1 axis or the Γ-M2 axis can be suitably realized. In the case of a checkerboard pattern arrangement, V=(±π/a, ±π/a), and the diffraction vector V and the wave number vectors K1 to K4 in FIG. 7 are exactly offset. The angle distribution ϕ2(x, y) of the diffraction vector V is expressed as an inner product of a diffraction vector V(Vx, Vy) and a position vector r(x, y). That is, the angle distribution ϕ2(x, y) of the diffraction vector V is expressed as ϕ2(x, y)=V·r=Vxx+Vyy.

In the above-described embodiment, when the wave number spread based on the angular spread of the optical image is included in a circle with a radius Ak centered on a certain point in the wave number space, this can be simply thought as follows. By adding the diffraction vector V to the in-plane wave number vectors K1 to K4 in the four directions, the magnitude of at least one of the in-plane wave number vectors K1 to K4 in the four directions is made smaller than 2π/λ (light line LL). This may also be thought as making the magnitude of at least one of the in-plane wave number vectors K1 to K4 in the four directions smaller than a value {(2π/λ)−Δk}, which is obtained by subtracting the wave number spread Δk from 2π/λ, by adding the diffraction vector V to vectors obtained by removing the wave number spread Δk from the in-plane wave number vectors K1 to K4 in the four directions.

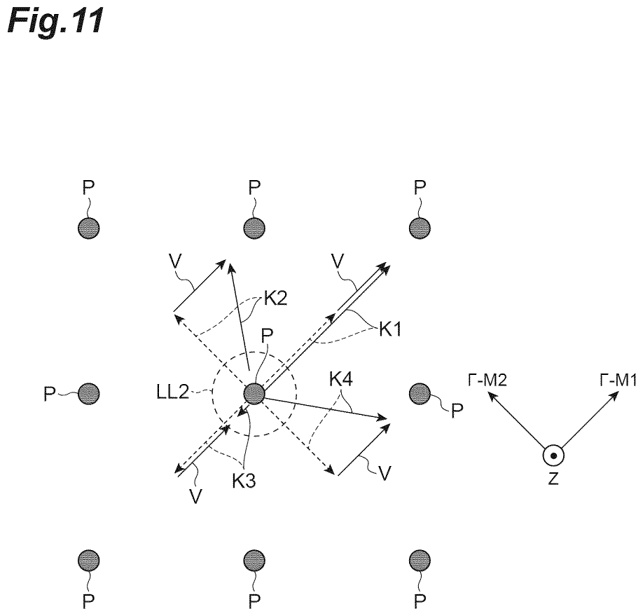

FIG. 11 is a drawing conceptually showing the above state. As shown in the drawing, when the diffraction vector V is added to the in-plane wave number vectors K1 to K4 excluding the wave number spread Δk, the magnitude of at least one of the in-plane wave number vectors K1 to K4 becomes smaller than {(2π/λ)−Δk}. In FIG. 11, a region LL2 is a circular region with a radius of {(2π/λ)−Δk}. In FIG. 11, the in-plane wave number vectors K1 to K4 shown by the broken lines indicate vectors before the diffraction vector V is added, and the in-plane wave number vectors K1 to K4 shown by the solid lines indicate vectors after the diffraction vector V is added. The region LL2 corresponds to the total reflection condition considering the wave number spread Δk, and the wave number vector whose magnitude falls within the region LL2 also propagates in the direction perpendicular to the surface (Z-axis direction).

In this form, the magnitude and direction of the diffraction vector V for making at least one of the in-plane wave number vectors K1 to K4 fall within the region LL2 will be described. The following Expressions (20) to (23) indicate the in-plane wave number vectors K1 to K4 before the diffraction vector V is added.

$$\begin{matrix}[ Expression 20 ] & \\ K 1 = ( \frac{π}{a} , \frac{π}{a} ) & ( 20 )\end{matrix}$$

$$\begin{matrix}[ Expression 21 ] & \\ K 2 = ( - \frac{π}{a} , \frac{π}{a} ) & ( 21 )\end{matrix}$$

$$\begin{matrix}[ Expression 22 ] & \\ K 3 = ( - \frac{π}{a} , - \frac{π}{a} ) & ( 22 )\end{matrix}$$

$$\begin{matrix}[ Expression 23 ] & \\ K 4 = ( \frac{π}{a} , - \frac{π}{a} ) & ( 23 )\end{matrix}$$

Here, when the diffraction vector V is expressed as in the above Expression (14), the in-plane wave number vectors K1 to K4 after the diffraction vector V is added become the following Expressions (24) to (27), respectively.

$$\begin{matrix}[ Expression 24 ] & \\ K 1 = ( \frac{π}{a} + Vx , \frac{π}{a} + Vy ) & ( 24 )\end{matrix}$$

$$\begin{matrix}[ Expression 25 ] & \\ K 2 = ( - \frac{π}{a} + Vx , \frac{π}{a} + Vy ) & ( 25 )\end{matrix}$$

$$\begin{matrix}[ Expression 26 ] & \\ K 3 = ( - \frac{π}{a} + Vx , - \frac{π}{a} + Vy ) & ( 26 )\end{matrix}$$

$$\begin{matrix}[ Expression 27 ] & \\ K 4 = ( \frac{π}{a} + Vx , - \frac{π}{a} + Vy ) & ( 27 )\end{matrix}$$

Considering that any of the in-plane wave number vectors K1 to K4 falls within the region LL2 in Expressions (24) to (27), the relationship of the following Expression (28) is satisfied. That is, by adding the diffraction vector V satisfying Expression (28), any of the in-plane wave number vectors K1 to K4 excluding the wave number spread Δk falls within the region LL2. Even in such a case, it is possible to output a part of the 1st-order light and a part of the −1st-order light without outputting the 0th-order light.

$$\begin{matrix}[ Expression 28 ] & \\ {( \pm \frac{π}{a} + V x )}^{2} + {( \pm \frac{π}{a} + Vy )}^{2} < {( \frac{2 π}{λ} - Δ k )}^{2} & ( 28 )\end{matrix}$$

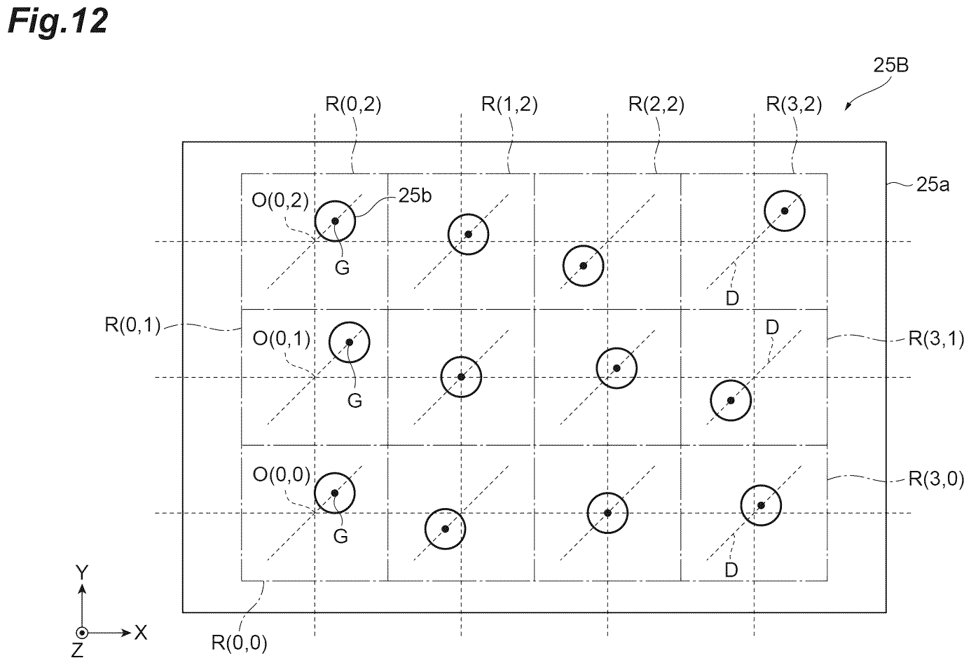

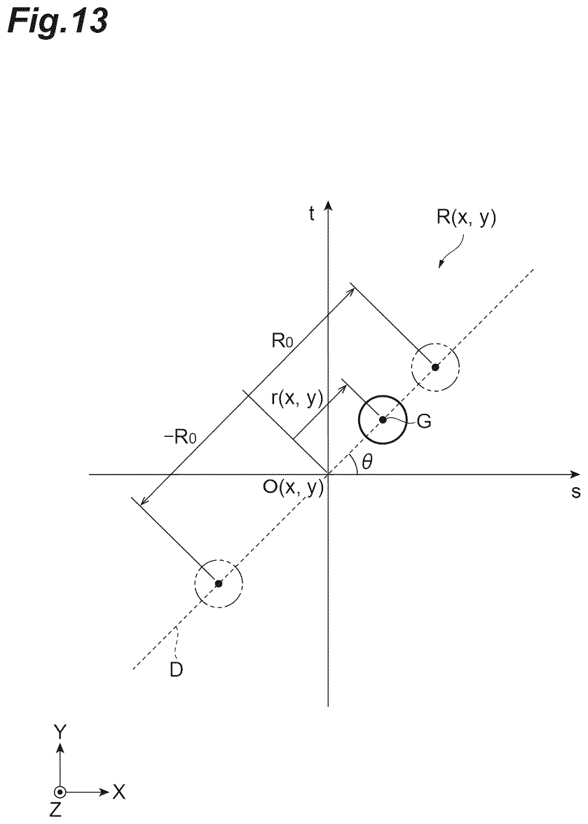

FIG. 12 is a plan view of a phase modulation layer 25B according to a modification example. FIG. 13 is a drawing showing the positional relationship of different refractive index regions in the phase modulation layer 25B according to the modification example. The phase modulation layer 25A may be replaced with the phase modulation layer 25B. As shown in FIGS. 12 and 13, the centroid G of each different refractive index region 25b of the phase modulation layer 25B according to the modification example is located on a straight line D. The straight line D is a straight line that passes through the lattice point O corresponding to each unit constituent region R and is inclined with respect to each side of the square lattice. That is, the straight line D is a straight line inclined with respect to both the X axis and the Y axis. The inclination angle of the straight line D with respect to one side (X axis) of the square lattice is θ.

The inclination angle θ is constant within the phase modulation layer 25B. The inclination angle θ satisfies 0°<θ<90°, and is θ=45° in one example. Alternatively, the inclination angle θ satisfies 180°<θ<270°, and is θ=225° in one example. When the inclination angle θ satisfies 0°<θ<90° or 180°<θ<270°, the straight line D extends from the first quadrant to the third quadrant of the coordinate plane defined by the X axis and the Y axis. The inclination angle θ satisfies 90°<θ<180°, and is θ=135° in one example. Alternatively, the inclination angle θ satisfies 270°<θ<360°, and is θ=315° in one example. When the inclination angle θ satisfies 90°<θ<180° or 270°<θ<360°, the straight line D extends from the second quadrant to the fourth quadrant of the coordinate plane defined by the X axis and the Y axis. Thus, the inclination angle θ is an angle excluding 0°, 90°, 180°, and 270°.

Here, the distance between the lattice point O and the centroid G is defined as r(x, y). x is the position of the x-th lattice point on the X axis, and y is the position of the y-th lattice point on the Y axis. When the distance r(x, y) is a positive value, the centroid G is located in the first quadrant (or the second quadrant). When the distance r(x, y) is a negative value, the centroid G is located in the third quadrant (or the fourth quadrant). When the distance r(x, y) is 0, the lattice point O and the centroid G match each other. The inclination angles are preferably 45°, 135°, 225°, and 275°. At these inclination angles, only two of the four wave number vectors (for example, in-plane wave number vectors (±π/a, ±π/a)) that form a standing wave at point M are phase-modulated and the other two are not phase-modulated, so that a stable standing wave can be formed.

The distance r(x, y) between the centroid G of each different refractive index region and the lattice point O corresponding to each unit constituent region R is set individually for each different refractive index region 15b according to a phase pattern corresponding to a desired optical image. The phase pattern, that is, the distribution of the distance r(x, y), has a specific value for each position determined by the values of x and y, but is not necessarily expressed by a specific function. The distribution of the distance r(x, y) is determined from the phase distribution extracted from the complex amplitude distribution obtained by inverse Fourier transform on the desired optical image.

That is, as shown in FIG. 13, the distance r(x, y) is set to 0 when the phase P(x, y) at certain coordinates (x, y) is P₀, the distance r(x, y) is set to the maximum value R₀ when the phase P(x, y) is π+P₀, and the distance r(x, y) is set to the minimum value −R₀ when the phase P(x, y) is −π+P₀. Then, for the intermediate phase P(x, y), the distance r(x, y) is taken so that r(x, y)={P(x, y)−P₀}×R₀/π. The initial phase P₀ can be set arbitrarily.

Assuming that the lattice spacing of a virtual square lattice is a, the maximum value R₀ of r(x, y) falls within the range of, for example, the following Expression (29). When calculating the complex amplitude distribution from the desired optical image, it is possible to improve the reproducibility of the beam pattern by applying an iterative algorithm such as a Gerchberg-Saxton (GS) method, which is commonly used in the calculation for hologram generation.

$$\begin{matrix}[ Expression 29 ] & \\ 0 \leq {R}_{0} \leq \frac{a}{\sqrt{2}} & ( 29 )\end{matrix}$$

In the present embodiment, a desired optical image can be obtained by determining the distribution of the distance r(x, y) of the different refractive index region 25b of the phase modulation layer 25B. Under the first to fourth prerequisites as in the above-described embodiment, the phase modulation layer 25B is formed to satisfy the following conditions. That is, the corresponding different refractive index region 25b is located within the unit constituent region R(x, y) so that the distance r(x, y) from the lattice point O(x, y) to the centroid G of the corresponding different refractive index region 25b satisfies the relationship r(x, y)=C×(P(x, y)−P₀), where C is a proportional constant, for example, R₀/n, and P₀ is any constant, for example, 0.

That is, the distance r(x, y) is set to 0 when the phase P(x, y) at certain coordinates (x, y) is P₀, set to the maximum value R₀ when the phase P(x, y) is π+P₀, and set to the minimum value −R₀ when the phase P(x, y) is −π+P₀. In order to obtain a desired light image, inverse Fourier transform may be performed on the optical image to apply the distribution of the distance r(x, y) according to the phase P(x, y) of the complex amplitude to a plurality of different refractive index regions 25b. The phase P(x, y) and the distance r(x, y) may be proportional to each other.

In the present embodiment, similarly to the above-described embodiment, the lattice spacing a of the virtual square lattice and the emission wavelength λ of the active layer 12 satisfy the condition for M-point oscillation. In addition, when considering the reciprocal lattice space in the phase modulation layer 25B, the magnitude of at least one of the in-plane wave number vectors in four directions each including the wave number spread due to the distribution of the distance r(x, y) can be made smaller than 2π/λ (light line).

In this form, by applying the following measures to the phase modulation layer 25B in each iPM laser 2 with M-point oscillation, a part of the 1st-order light and the −1st-order light is output without outputting the 0th-order light into the light line. Specifically, as shown in FIG. 8, the diffraction vector V having a certain magnitude and direction is added to the in-plane wave number vectors K1 to K4, so that the magnitude of at least one of the in-plane wave number vectors K1 to K4 is made smaller than 2π/λ. That is, at least one of the in-plane wave number vectors K1 to K4 after the diffraction vector V is added falls within the circular region (light line) LL with a radius of 2π/λ. By adding the diffraction vector V that satisfies the above-described Expression (19), any of the in-plane wave number vectors K1 to K4 falls within the light line LL, and a part of the 1st-order light and a part of the −1st-order light is output.

Alternatively, as shown in FIG. 11, the magnitude of at least one of the in-plane wave number vectors K1 to K4 in the four directions may be made smaller than a value {(2π/λ)−Δk}, which is obtained by subtracting the wave number spread Δk from 2π/λ, by adding the diffraction vector V to vectors obtained by removing the wave number spread Δk from the in-plane wave number vectors K1 to K4 in the four directions (that is, in-plane wave number vectors in the four directions in the square lattice PCSEL with M-point oscillation). That is, by adding the diffraction vector V that satisfies the above-described Expression (28), any of the in-plane wave number vectors K1 to K4 falls within the region LL2, and a part of the 1st-order light and −1st-order light is output.

As an example of a specific method for adding the diffraction vector V to the in-plane wave number vectors K1 to K4, a method can be considered in which a distance distribution r2(x, y) (second phase distribution) that is not related to the optical image is superimposed on a distance distribution r1(x, y) (first phase distribution), which is a phase distribution according to the optical image. In this case, the distance distribution r(x, y) of the phase modulation layer 25B is expressed as r(x, y)=r1(x, y)+r2(x, y). r1(x, y) corresponds to the phase of the complex amplitude when the optical image is Fourier transformed as described above. r2(x, y) is a distance distribution for adding the diffraction vector V that satisfies the above-described Expression (19) or Expression (28). A specific example of the distance distribution r2(x, y) is the same as that shown in FIG. 10.

### [Configuration of Drive Circuit]

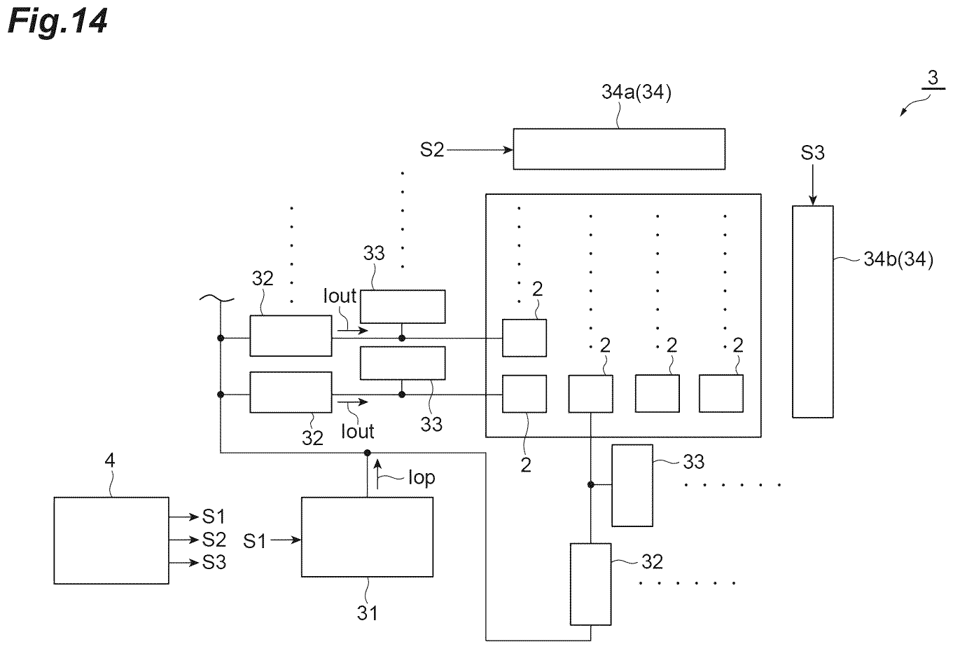

FIG. 14 is an overall block diagram of the drive circuit 3 shown in FIG. 1. As shown in FIG. 14, the drive circuit 3 includes a current source circuit 31, a plurality of current mirror circuits 32, a plurality of oscillation prevention circuits 33, and a switch operating section 34. The drive circuit 3 is electrically connected to an external control circuit 4 provided outside the semiconductor light emitting device 1, and is driven in response to instruction signals S1 to S3 from the external control circuit 4. The current source circuit 31 generates an operating current Iop that is the basis of a drive current Iout for causing each iPM laser 2 to emit light. The current source circuit 31 receives the instruction signal S1 from the external control circuit 4, and generates the operating current Iop having a current value based on the instruction signal S1. The current source circuit 31 is common to a plurality of iPM lasers 2. A wiring that extends from an output terminal of the current source circuit 31 branches into a plurality of wirings, and the plurality of branched wirings are connected to input terminals of the plurality of current mirror circuits 32, respectively. Each of the plurality of current mirror circuits 32 amplifies the operating current Iop generated by the current source circuit 31 to produce the drive current Iout, and then the drive current Iout is supplied to each iPM laser 2. The output terminal of each of the plurality of current mirror circuits 32 is connected to each iPM laser 2. The number of the plurality of current mirror circuits 32 is the same as the number of the plurality of iPM lasers 2. The output terminal of each of the plurality of current mirror circuits 32 is further connected to each of the plurality of oscillation prevention circuits 33.

Each of the plurality of oscillation prevention circuits 33 suppresses ringing caused by parasitic components (inductance components) of the wiring between each current mirror circuit 32 and each iPM laser 2. The number of the plurality of oscillation prevention circuits 33 is the same as the number of the plurality of iPM lasers 2 and the number of the plurality of current mirror circuits 32. The switch operating section 34 includes a first shift register 34a and a second shift register 34b. The first shift register 34a receives the instruction signal S2 from the external control circuit 4. Then, the first shift register 34a performs ON/OFF switching of the supply of the drive current Iout to each of the plurality of iPM lasers 2 for each column based on the instruction signal S2. The second shift register 34b receives the instruction signal S3 from the external control circuit 4. Then, the second shift register 34b performs ON/OFF switching of the supply of the drive current Iout to the plurality of iPM lasers 2 for each row based on the instruction signal S3. ON/OFF switching of the drive current Iout is performed for each individual iPM laser 2 by both the first shift register 34a and the second shift register 34b. When the drive current Iout is turned on, the drive current Iout is supplied to each iPM laser 2.

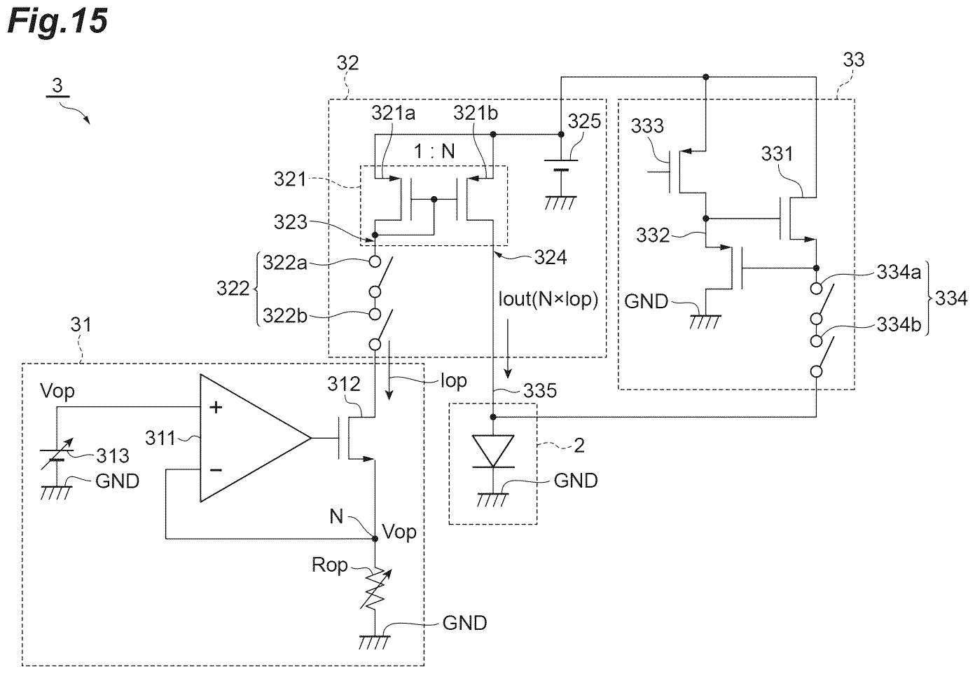

FIG. 15 is a circuit diagram of the drive circuit 3 shown in FIG. 1. As shown in FIG. 15, the current source circuit 31 includes an operational amplifier 311, an NMOS-FET (transistor) 312, a voltage source 313, and a resistor section Rop. The current source circuit 31 in the present embodiment is a sink type constant current circuit because the current source circuit 31 uses the NMOS-FET 312. The drain terminal of the NMOS-FET 312 is connected to the input terminal of the current mirror circuit 32. The gate terminal (control terminal) of the NMOS-FET 312 is connected to the output terminal of the operational amplifier 311. The operational amplifier 311 has an inverting input terminal and a non-inverting input terminal as a pair of input terminals. The voltage source 313 is connected to the non-inverting input terminal (one of the pair of input terminals) of the operational amplifier 311, and an input voltage Vop is supplied thereto. The source terminal (current terminal) of the NMOS-FET 312 is connected to the inverting input terminal (the other of the pair of input terminals) of the operational amplifier 311, and is also connected to a reference potential line GND (fourth constant potential line) through the resistor section Rop. Due to the imaginary short of the operational amplifier 311, a voltage equal to the input voltage Vop (for convenience, illustrated as Vop) is applied to a node N between the source terminal of the NMOS-FET 312 and the resistor section Rop. For this reason, the operating current Iop has a current value calculated by dividing the voltage value of the input voltage Vop by the resistance value of the resistor section Rop. One or both of the resistance value of the resistor section Rop and the voltage value of the input voltage Vop output from the voltage source 313 are variable. The current value of the operating current Iop changes as the voltage value of the input voltage Vop or the resistance value of the resistor section Rop changes. Therefore, the operating current Iop is variable. The current source circuit 31 may function as a source type constant current circuit by providing a PMOS-FET instead of the NMOS-FET 312. In this case, the resistor section Rop is connected between the source terminal of the PMOS-FET and the input terminal of each current mirror circuit 32. A bipolar transistor may be provided instead of the NMOS-FET or the PMOS-FET.

Each current mirror circuit 32 has a transistor circuit 321 and a switch section 322. In the example shown in FIG. 15, the transistor circuit 321 includes a PMOS-FET 321a and a PMOS-FET 321b. The gate terminal of the PMOS-FET 321a and the gate terminal of the PMOS-FET 321b are common. The source terminal of the PMOS-FET 321a and the source terminal of the PMOS-FET 321b are common. A voltage source 325 is connected to the common source terminal. The switch section 322 includes a first switch 322a and a second switch 322b. The first switch 322a and the second switch 322b are connected in series to each other. ON/OFF switching of the switch section 322 is performed individually for each current mirror circuit 32 in response to an instruction signal from the switch operating section 34. The first switch 322a is electrically connected to the first shift register 34a (see FIG. 14). ON/OFF switching of the first switch 322a is performed in response to the instruction signal S2 from the first shift register 34a. The second switch 322b is electrically connected to the second shift register 34b (see FIG. 14). ON/OFF switching of the second switch 322b is performed in response to the instruction signal S3 from the second shift register 34b. The operating current Iop is supplied to each current mirror circuit 32 by turning on both the first switch 322a and the second switch 322b.

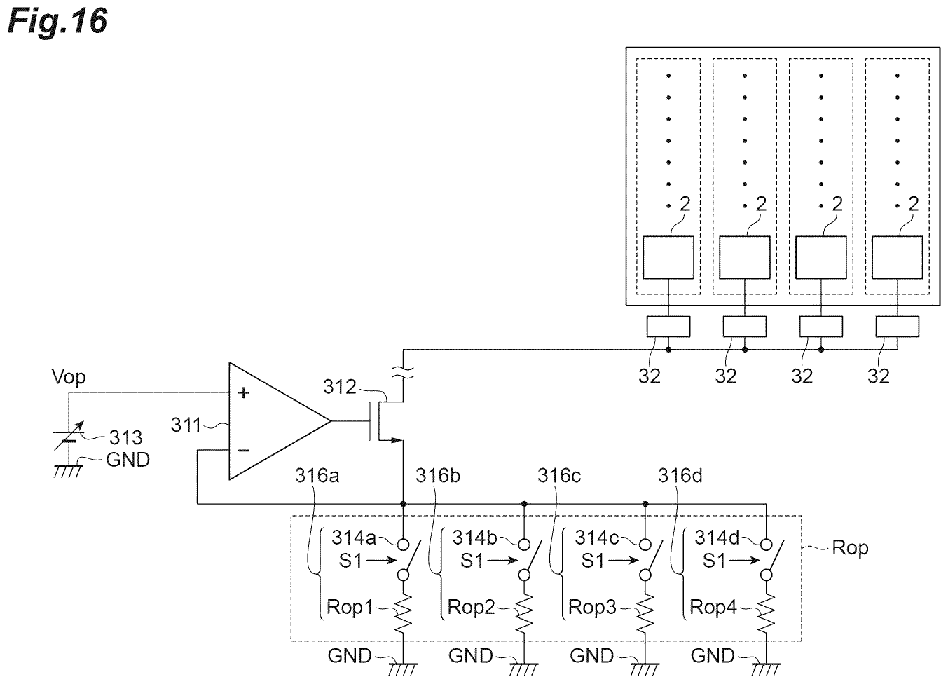

FIG. 16 is a detailed circuit diagram of the current source circuit 31 shown in FIG. 15. As shown in FIG. 16, the resistor section Rop includes a number of partial circuits 316a to 316d. One end of the resistor section Rop is connected to the source terminal of the NMOS-FET 312 and the inverting input terminal of the operational amplifier 311, and the other end of the resistor section Rop is connected to the reference potential line GND. The partial circuits 316a to 316d are connected in parallel to one another between one end and the other end of the resistor section Rop. The partial circuit 316a includes a resistor Rop1 and a third switch 314a connected in series to each other. The partial circuit 316b includes a resistor Rop2 and a third switch 314b connected in series to each other. The partial circuit 316c includes a resistor Rop3 and a third switch 314c connected in series to each other. The partial circuit 316d includes a resistor Rop4 and a third switch 314d connected in series to each other. In the example shown in FIG. 16, the four third switches 314a to 314d and the four resistors Rop1 to Rop4 are provided. Each of the plurality of third switches 314a to 314d and each of the plurality of resistors Rop1 to Rop4 are directly connected to each other through wiring only. The plurality of third switches 314a to 314d receive the instruction signal S1 for ON/OFF switching of at least one of the third switches 314a to 314d from the external control circuit 4 (see FIG. 14). At least one of the plurality of resistors Rop1 to Rop4 is connected to the source terminal of the NMOS-FET 312 in response to a third switch that is turned on among the plurality of third switches 314a to 314d. This changes the value of the operating current Iop. For example, when only the third switch 314a is turned on, the operating current Iop has a constant current value calculated by dividing the voltage value of the input voltage Vop by the resistance value of the resistor Rop1. On the other hand, when the third switches 314a and 314c are turned on, the operating current Iop has a constant current value calculated by dividing the voltage value of the input voltage Vop by the combined resistance value of the resistors Rop1 and Rop3.

The external control circuit 4 sequentially performs ON/OFF switching of at least one of the plurality of third switches 314a to 314d at a predetermined cycle (for example, several kHz to several GHz). The switching order may be a predetermined order or a random order. For example, the external control circuit 4 performs ON/OFF switching of at least one of the plurality of third switches 314a to 314d for each column of the plurality of iPM lasers 2, thereby switching the value of the drive current Iout. The external control circuit 4 may switch the value of the drive current Iout for each iPM laser 2. The external control circuit 4 switches the plurality of third switches 314a to 314d in synchronization with the timing at which the first switch 322a and the second switch 322b of each current mirror circuit 32 are switched. As a result, the plurality of iPM lasers 2 are driven individually, and at the same time, the value of the drive current Iout supplied to each of the plurality of iPM lasers 2 is switched. In other words, the switching operations of the first switch 322a and the second switch 322b are synchronized with the operation of changing the resistance value of the resistor section Rop (switching operations of the third switches 314a to 314d).

FIG. 15 is referred to again. Each current mirror circuit 32 has a first current path 323 including the PMOS-FET 321a and a plurality of switch sections 322 and a second current path 324 including the PMOS-FET 321b. The first current path 323 is connected to the drain terminal of the NMOS-FET 312 of the current source circuit 31. The second current path 324 is connected to each iPM laser 2. When both the first switch 322a and the second switch 322b are turned on, the operating current Iop flows through the first current path 323. Since a voltage Vgs between the gate terminal and the source terminal is common to the PMOS-FET 321a and the PMOS-FET 321b, the operating current Iop also flows through the second current path 324. However, the drive current Iout that is N times (N is a real number) the operating current Iop flows through the PMOS-FET 321b. That is, the drive current Iout is proportional to the magnitude of the operating current Iop.

As shown in FIG. 15, each oscillation prevention circuit 33 includes an NMOS-FET 331, a first PMOS-FET 332, a second PMOS-FET 333, and an oscillation prevention switch section 334. The anode of each iPM laser 2 is connected to the source terminal of the NMOS-FET 331. The source terminal of the NMOS-FET 331 is also connected to the gate terminal of the first PMOS-FET 332. The source terminal of the first PMOS-FET 332 is connected to the drain terminal of the second PMOS-FET 333. The second PMOS-FET 333 supplies current to the first PMOS-FET 332 according to an input voltage to the gate terminal of the second PMOS-FET 333. The potential between the first PMOS-FET 332 and the second PMOS-FET 333 is supplied to the gate terminal of the NMOS-FET 331. The first PMOS-FET 332 and the second PMOS-FET 333 form a feedback circuit. The drain terminal of the NMOS-FET 331 is connected to the voltage source 325 (first constant potential line). The drain terminal of the first PMOS-FET 332 is connected to the reference potential line GND (second constant potential line). The source terminal of the second PMOS-FET 333 is connected to the voltage source 325 (third constant potential line). The oscillation prevention switch section 334 is connected between the anode of each iPM laser 2 and the source terminal of the NMOS-FET 331. The oscillation prevention switch section 334 includes a first oscillation prevention switch 334a and a second oscillation prevention switch 334b. The first oscillation prevention switch 334a and the second oscillation prevention switch 334b are connected in series to each other. The first oscillation prevention switch 334a is electrically connected to the first shift register 34a (see FIG. 14). The first oscillation prevention switch 334a is switched on/off in response to the instruction signal S2 from the first shift register 34a. That is, the operation of the first oscillation prevention switch 334a is completely synchronized with the operation of the first switch 322a. The second oscillation prevention switch 334b is electrically connected to the second shift register 34b (see FIG. 14). The second oscillation prevention switch 334b is switched on/off in response to the instruction signal S3 from the second shift register 34b. That is, the operation of the second oscillation prevention switch 334b is completely synchronized with the operation of the second switch 322b.

Each iPM laser 2 and the drain terminal of the PMOS-FET 321b are connected to each other by a wiring 335 having an inductance. The first switch 322a, the second switch 322b, and the plurality of third switches 314a to 314d are switched at a frequency of, for example, several kHz to several GHz by the external control circuit 4. Therefore, when each switch is turned on/off, peaking or ringing can occur due to the resonance phenomenon associated with the inductance of the wiring 335.

In each oscillation prevention circuit 33, the impedance of the NMOS-FET 331 has an effect of lowering a resonance constant Q due to the effect of the feedback loop. That is, since the impedance component of the NMOS-FET 331 is included in the denominator of the resonance constant Q, the resonance constant Q is reduced. Thus, since each oscillation prevention circuit 33 can reduce the resonance constant Q, ringing and peaking in the path through which the drive current Iout flows is suppressed. This suppresses the occurrence of overcurrent or overshoot of current in each iPM laser 2, making it possible to drive each iPM laser 2 stably. Since the operation of the first oscillation prevention switch 334a is completely synchronized with the operation of the first switch 322a and the operation of the second oscillation prevention switch 334b is completely synchronized with the operation of the second switch 322b, a drain current can be made to flow through the NMOS-FET 331 at the timing at which the operating current Iop is supplied to each current mirror circuit 32. Therefore, it is possible to suppress heat generation compared to a case where the drain current constantly flows through the NMOS-FET 331.

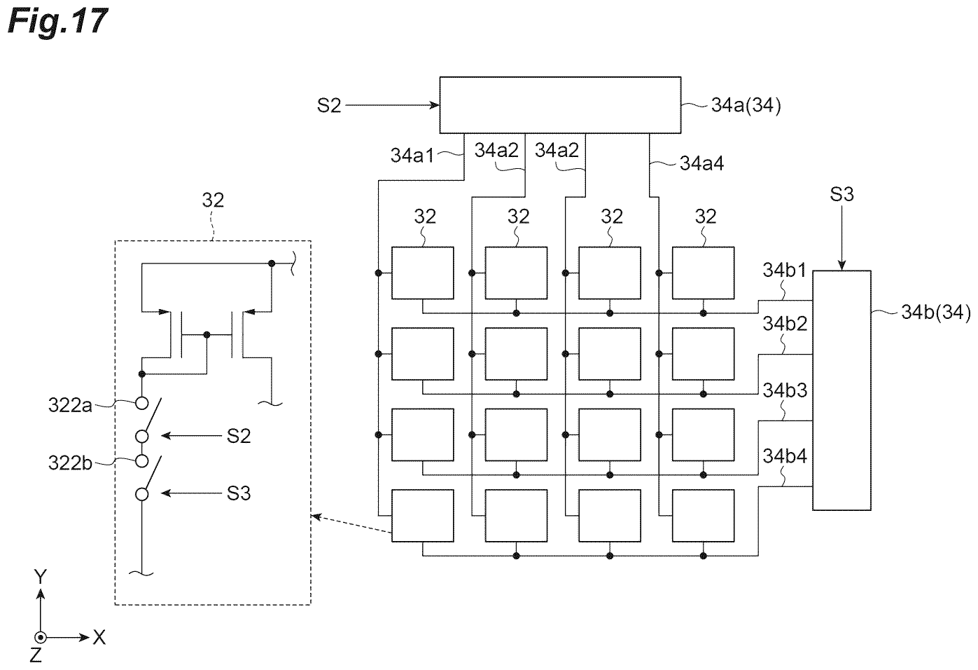

FIG. 17 is a drawing showing the configuration of the switch operating section 34 shown in FIG. 14. For ease of explanation, it is assumed that a plurality of current mirror circuits 32 are arranged in a matrix with the X-axis direction and the Y-axis direction as a row direction and a column direction, respectively. Each current mirror circuit 32 is connected to each iPM laser 2, but a plurality of iPM lasers 2 are not shown in FIG. 17. The first shift register 34a has parallel outputs. In the example shown in FIG. 17, the first shift register 34a has four terminal outputs of output terminals 34a1 to 34a4, and each of the output terminals 34a1 to 34a4 is connected to each column of the plurality of current mirror circuits 32. The first shift register 34a drives each column of the plurality of current mirror circuits 32 in response to the instruction signal S2 from the external control circuit 4. Similarly, in the example shown in FIG. 17, the second shift register 34b has four terminal outputs of output terminals 34b1 to 34b4, and each of the output terminals 34a1 to 34a4 is connected to each row of the plurality of current mirror circuits 32. The second shift register 34b drives each row of the plurality of current mirror circuits 32 in response to the instruction signal S3 from the external control circuit 4.

### [Measurement Method Using Three-Dimensional Measuring Device]

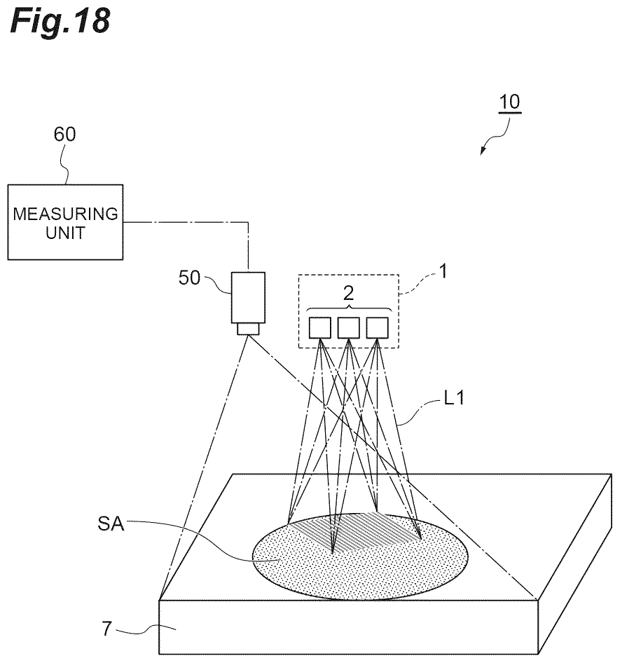

FIG. 18 is a schematic drawing showing the configuration of a three-dimensional measuring device 10. As shown in FIG. 18, the three-dimensional measuring device 10 includes the semiconductor light emitting device 1 including a plurality of iPM lasers 2, a single imaging unit 50, and a measuring unit 60. Light L1 emitted from the plurality of iPM lasers 2 is emitted to a certain region on the surface of an object to be measured SA placed on a stage 7. The stage 7 may be a scanning stage that is capable of scanning in a two-dimensional direction or a three-dimensional direction. When the emission range of the light L1 is sufficiently wide relative to the measurement range of the object to be measured SA, the stage 7 may be omitted.

The imaging unit 50 is a device having sensitivity to the light L1 emitted from the plurality of iPM lasers 2. As the imaging unit 50, for example, a CCD (Charge Coupled Device) camera, a CMOS (Complementary MOS) camera, and other two-dimensional image sensors can be used. The imaging unit 50 captures an image of the object to be measured SA to which the light L1 is emitted, and outputs an output signal indicating the imaging result to the measuring unit 60.

The measuring unit 60 is a computer system including, for example, a processor, a memory, and the like. The measuring unit 60 executes various control functions using a processor. Examples of the computer system include a personal computer, a microcomputer, a cloud server, and a smart device (a smartphone, a tablet terminal, and the like). The measuring unit 60 may be configured by a PLC (Programmable logic controller), or may be configured by an integrated circuit such as an FPGA (Field-programmable gate array).

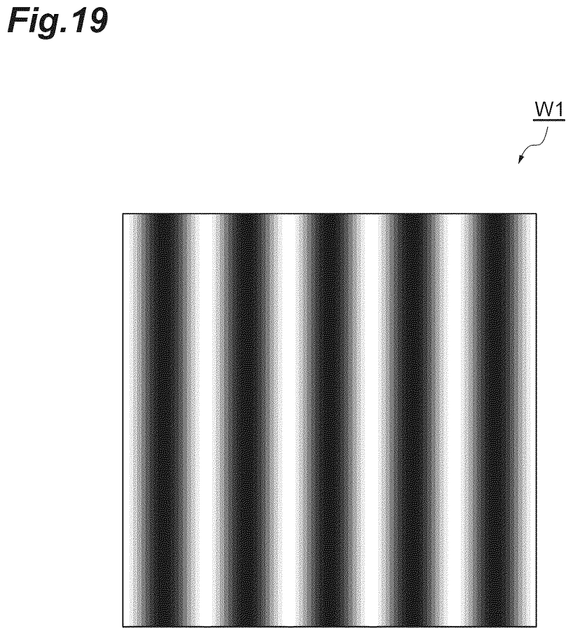

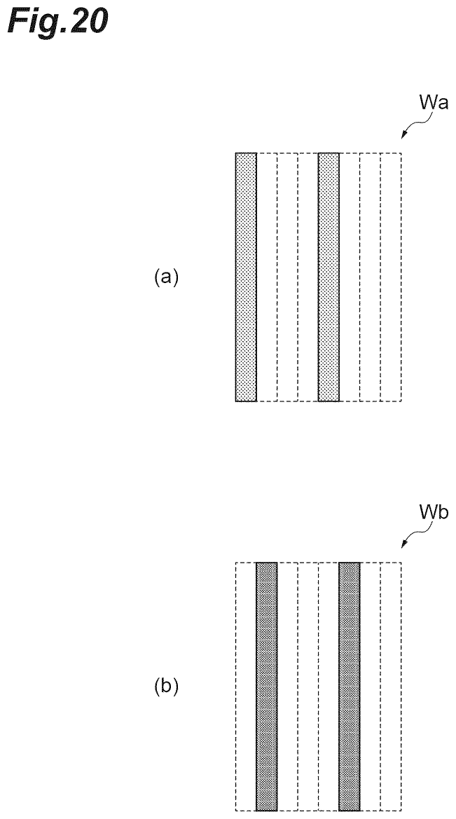

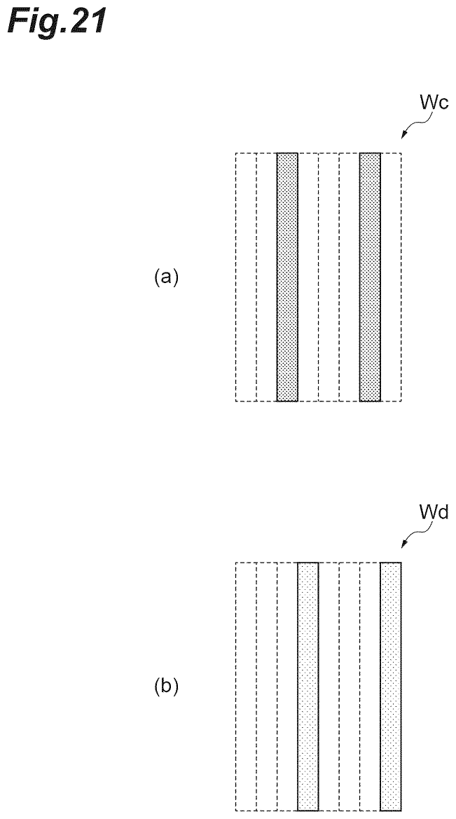

The light L1 forms, for example, a sinusoidal wave stripe pattern W1 as shown in FIG. 19. In FIG. 19, the light intensity in the stripe pattern W1 is expressed by the shade of color, with a darker (closer to black) portion having higher light intensity and a lighter (closer to white) portion having lower light intensity. The stripe pattern W1 is a periodic stripe pattern shown in an image region of, for example, 100×100 pixels. The period of the stripe pattern W1 is, for example, a 20-pixel period. The brightness of the stripe pattern W1 changes with the intensity of the light L1. A bright portion (black portion) of the stripe pattern W1 is a portion where the intensity of the light L1 is high, and a dark portion (white portion) of the stripe pattern W1 is a portion where the intensity of the light L1 is low.

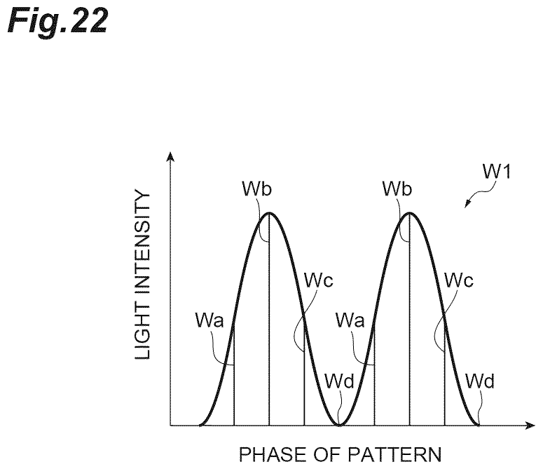

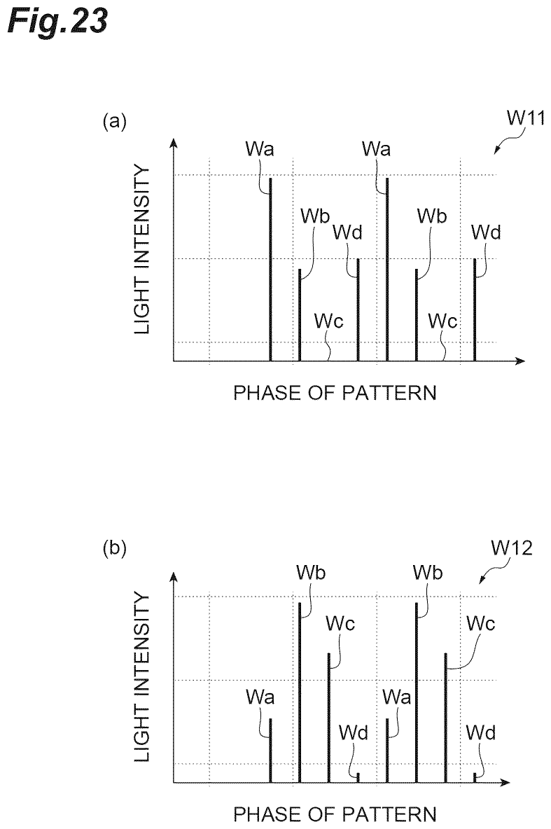

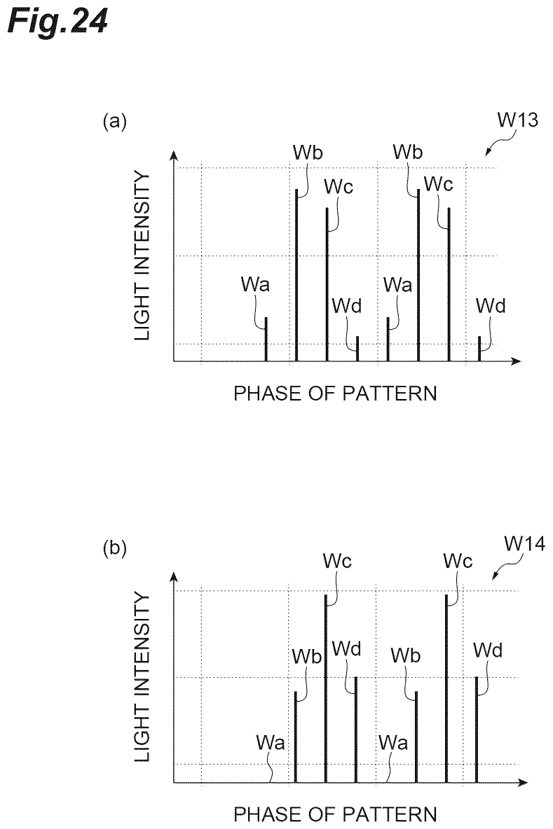

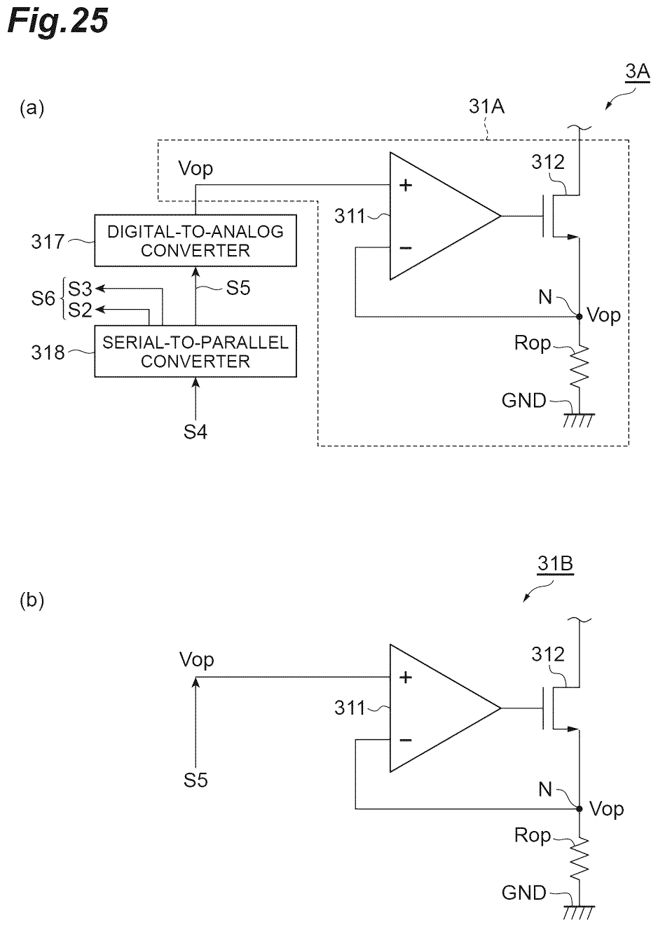

The stripe pattern W1 is formed by combining a plurality of stripe elements formed by light components output from each of the plurality of iPM lasers 2. Here, for ease of explanation, a case where the stripe pattern W1 with a four-pixel period is formed using four iPM lasers 2 will be described as an example. FIG. 20(a) is a drawing showing a first stripe element Wa formed by light output from a certain iPM laser 2 (hereinafter, referred to as a first iPM laser). FIG. 20(a) shows only the pattern output from the first iPM laser. A portion where the pattern is formed is shown by halftone dots, and the larger the density of halftone dots, the larger the light intensity. FIG. 20(b) is a drawing showing a second stripe element Wb formed by light output from another iPM laser 2 (hereinafter, referred to as a second iPM laser). FIG. 20(b) shows only the pattern output from the second iPM laser. FIG. 21(a) is a drawing showing a third stripe element We formed by light output from yet another iPM laser 2 (hereinafter, referred to as a third iPM laser). FIG. 21(a) shows only the pattern output from the third iPM laser. FIG. 21(b) is a drawing showing a fourth stripe element Wd formed by light output from still another iPM laser 2 (hereinafter, referred to as a fourth iPM laser). FIG. 21(b) shows only the pattern output from the fourth iPM laser. The light output from these iPM lasers 2 is included in the light L1. Comparing FIG. 20(a) with FIG. 20(b), the phase of the second stripe element Wb is shifted by π/2 (rad), that is, ¼ period, from the phase of the first stripe element Wa. In this example, the light intensity of the second stripe element Wb is larger than the light intensity of the first stripe element Wa. Comparing FIG. 20(b) with FIG. 21(a), the phase of the third stripe element We is shifted by π/2 (rad), that is, ¼ period, from the phase of the second stripe element Wb. In addition, in this example, the light intensity of the third stripe element We is smaller than the light intensity of the second stripe element Wb. Comparing FIG. 21(a) with FIG. 21(b), the phase of the fourth stripe element Wd is shifted by π/2, that is, ¼ period, from the phase of the third stripe element Wc. In this example, the light intensity of the fourth stripe element Wd is smaller than the light intensity of the third stripe element Wc. FIG. 22 is a graph showing the light intensity distribution of the stripe pattern W1 generated by combining the first stripe element Wa to the fourth stripe element Wd. In FIG. 22, the horizontal axis indicates a position in a direction (the periodic direction of a sinusoidal wave) crossing the stripes (in other words, the phase of the stripe pattern W1), and the vertical axis indicates light intensity. As shown in FIG. 22, in the stripe pattern W1, a pattern having a sinusoidal wave light intensity distribution is realized by appropriately adjusting the light intensities of the first stripe element Wa to the fourth stripe element Wd. Then, the more iPM lasers 2 there are (the more stripe elements there are), the closer the waveform approaches an exact sinusoidal wave. FIG. 22 shows two sinusoidal waves included in the stripe pattern W1.

When generating the stripe pattern W1 with a four-pixel period, both of the first switch 322a and the second switch 322b of each current mirror circuit 32 connected to each of the first iPM laser to the fourth iPM laser are turned on in the order of the first iPM laser, the second iPM laser, the third iPM laser, and the fourth iPM laser during the exposure period of one frame of the imaging unit 50. In synchronization with the switching timing of the first switch 322a and the second switch 322b, the plurality of third switches 314a to 314d of the current source circuit 31 are switched in any order. That is, the first to fourth iPM lasers are driven individually in sequence, and at the same time, the value of the drive current Iout supplied to each of the first to fourth iPM lasers is increased or decreased. As a result, the first stripe element Wa, the second stripe element Wb, the third stripe element Wc, and the fourth stripe element Wd output respectively from the first iPM laser, the second iPM laser, the third iPM laser, and the fourth iPM laser are combined in the imaging of one frame by the imaging unit 50, and are recognized as the stripe pattern W1 in the imaging unit 50.

The measuring unit 60 measures a three-dimensional shape of the object to be measured SA based on a phase shift method using the stripe pattern W1. In this form, a plurality of sinusoidal wave stripe patterns W1 are used, each of which is given a phase shift (positional deviation) that is an equal division of one period of the lattice pitch, for example. The phase shift pattern may be prepared such that the phase is shifted by 2π/N (N is an integer).

Here, an example is shown in which four sinusoidal wave stripe patterns W1 having different phase shifts are used. Assuming that the light intensities of the four light components L1 having four sinusoidal wave stripe patterns W1 are I0 to I3, respectively, and the pixel of the imaging unit 50 is (x, y), the light intensities I0 to I3 on the surface of the object to be measured SA are expressed by the following Expressions (30) to (33). Ia(x, y) is the amplitude of the lattice pattern, Ib(x, y) is the background intensity, and O(x, y) is the initial phase.

$$\begin{matrix}[ Expression 30 ] & \\ I 0 = I a ( x , y ) cos \{ θ ( x , y ) \} + I b ( x , y ) & ( 30 )\end{matrix}$$

$$\begin{matrix}[ Expression 31 ] & \\ I 1 = Ia ( x , y ) cos \{ θ ( x , y ) + π / 2 \} + I b ( x , y ) & ( 31 )\end{matrix}$$

$$\begin{matrix}[ Expression 32 ] & \\ I 2 = Ia ( x , y ) cos \{ θ ( x , y ) + π \} + I b ( x , y ) & ( 32 )\end{matrix}$$

$$\begin{matrix}[ Expression 33 ] & \\ I 3 = Ia ( x , y ) cos \{ θ ( x , y ) + 3 π / 2 \} + I b ( x , y ) & ( 33 )\end{matrix}$$

The initial phase θ can be calculated by tan θ=−(I3−I1)/(I2−I0). When the number of phase shifts of the sinusoidal wave stripe pattern W1 is N, the initial phase θ can be calculated by the following Expression (34).

$$\begin{matrix}[ Expression 34 ] & \\ tan θ = - {\sum }_{n = 0}^{N - 1} \frac{In sin ( n \frac{2 π}{N} )}{In cos ( n \frac{2 π}{N} )} & ( 34 )\end{matrix}$$

When such a phase shift method is used, the height of the object to be measured SA can be measured at intervals smaller than the pitch of the sinusoidal wave stripe pattern W1 by converting the measured phase into height. In the configuration of the three-dimensional measuring device 10, the plurality of iPM lasers 2 may be arranged in a direction parallel to the stripes in the sinusoidal wave stripe pattern W1. In this case, since it is possible to eliminate the phase shift caused by the positional deviation of the plurality of iPM lasers 2, it is possible to eliminate the shift of the initial phase in each of the plurality of sinusoidal wave stripe patterns W1.

Here, a case will be described in which four sinusoidal wave stripe patterns having different phases are used. FIG. 23(a) is a drawing showing a first stripe pattern W11, FIG. 23(b) is a drawing showing a second stripe pattern W12, FIG. 24(a) is a drawing showing a third stripe pattern W13, and FIG. 24(b) is a drawing showing a fourth stripe pattern W14. As shown in FIG. 23(a), the first stripe pattern W11 is a sinusoidal wave stripe pattern in which the first stripe element Wa has the highest light intensity and the third stripe element We has the lowest light intensity. Then, as shown in FIG. 23(b), the second stripe pattern W12 is a sinusoidal wave stripe pattern in which the second stripe element Wb has the highest light intensity and the fourth stripe element Wd has the lowest light intensity. That is, from the first stripe pattern W11 to the second stripe pattern W12, a phase shift occurs in which the peak of the light intensity moves along a direction in which the phase advances. Then, as shown in FIG. 24(a), in the third stripe pattern W13, the light intensity of the third stripe element We is approximately equal to the light intensity of the second stripe element Wb. In addition, the light intensity of the fourth stripe element Wd is larger than the light intensity of the fourth stripe element Wd in the second stripe pattern W12. That is, from the second stripe pattern W12 to the third stripe pattern W13, a phase shift occurs. Then, as shown in FIG. 24(b), the fourth stripe pattern W14 is a sinusoidal wave stripe pattern in which the third stripe element We has the highest light intensity and the first stripe element Wa has the lowest light intensity. That is, from the third stripe pattern W13 to the fourth stripe pattern W14, a phase shift occurs. As described above, the phase is continuously shifted from the first stripe pattern W11 to the fourth stripe pattern W14. In this manner, it is possible to measure the three-dimensional shape of the object to be measured SA. Here, four sinusoidal wave stripe patterns are shown as an example of phase shift, but equally spaced phase shifts are preferred when performing measurement using a phase shift method.

### [Function and Effect]

In the semiconductor light emitting device 1, the drive current Iout can be supplied to each iPM laser 2 corresponding to each of the plurality of switch sections 322 by individually operating each of the plurality of switch sections 322 using the switch operating section 34. When a plurality of current source circuits 31 corresponding to the respective iPM lasers 2 are provided, even in the current source circuit 31 corresponding to the iPM laser 2 that is not in operation, power consumption (standby power) occurs because the current source circuit 31 itself is in operation. In the semiconductor light emitting device 1, since the drive current Iout is supplied based on the operating current Iop generated by the common current source circuit 31, the amount of heat generated due to standby power can be reduced and power consumption can be reduced. In addition, since the current source circuit 31 is common, the number of current source circuits 31 is reduced. Therefore, the semiconductor light emitting device 1 can be made smaller.

In the semiconductor light emitting device 1, each of the plurality of switch sections 322 has the first switch 322a and the second switch 322b connected in series to the first switch 322a. The switch operating section 34 has the first shift register 34a that operates the first switch 322a and the second shift register 34b that operates the second switch 322b. According to this, the drive current Iout can be individually supplied only to the iPM laser 2 for which both the first switch 322a and the second switch 322b are turned on. Then, the first shift register 34a can specify the iPM lasers 2 to be driven, for example, in units of rows, and the second shift register 34b can specify the iPM lasers 2 to be driven, for example, in units of columns. Therefore, it becomes easy to individually supply the drive current Iout to the plurality of iPM lasers 2 arranged across a plurality of rows and a plurality of columns.

In the semiconductor light emitting device 1, the drive circuit 3 further includes a plurality of current mirror circuits 32 corresponding to the plurality of iPM lasers 2, respectively. Each of the plurality of current mirror circuits 32 has the first current path 323 and the second current path 324 through which current with a magnitude proportional to the magnitude of the current flowing through the first current path 323 flows. The first current path 323 is connected to the common current source circuit 31, the switch section 322 is provided on the first current path 323, and the second current path 324 is connected to the iPM laser 2 corresponding to the current mirror circuit 32 among the plurality of iPM lasers 2. According to this, the drive current Iout based on the operating current Iop generated in the common current source circuit 31 can be supplied to the iPM laser 2 through the second current path 324.

In the semiconductor light emitting device 1, the drive circuit 3 further includes a plurality of oscillation prevention circuits 33 corresponding to the plurality of iPM lasers 2, respectively. Each of the plurality of oscillation prevention circuits 33 has the NMOS-FET 331 including a source terminal connected to the anode terminal of each of the plurality of iPM lasers 2 and a drain terminal connected to the voltage source 325. Each of the plurality of oscillation prevention circuits 33 has the first PMOS-FET 332 including a gate terminal connected to the source terminal of the NMOS-FET 331 and a drain terminal connected to the reference potential line GND having a lower potential than the voltage source 325. Each of the plurality of oscillation prevention circuits 33 has the second PMOS-FET 333 that includes a drain terminal connected to the source terminal of the first PMOS-FET 332, a source terminal connected to the voltage source 325 having a higher potential than the reference potential line GND, and a gate terminal and that supplies current to the first PMOS-FET 332 in response to an input voltage to the gate terminal. The potential between the first PMOS-FET 332 and the second PMOS-FET 333 is supplied to the gate terminal of the NMOS-FET 331. According to this, the resonance constant (Q value) can be reduced by providing the oscillation prevention circuit 33. Therefore, since ringing or peaking is suppressed, it is possible to drive the iPM laser 2 stably.

In the semiconductor light emitting device 1, the value of the operating current Iop generated by the common current source circuit 31 is variable. According to this, since the magnitude of the drive current Iout is variable, the light amount of each iPM laser 2 is changed, and as a result, the brightness of the optical image output from the plurality of iPM lasers 2 can be changed.

In the semiconductor light emitting device 1, the common current source circuit 31 further includes: the operational amplifier 311 having a pair of input terminals, the input voltage Vop being supplied to one of the pair of input terminals; the NMOS-FET 312 having a control terminal connected to the output terminal of the operational amplifier 311; and the resistor section Rop having one end connected to the current terminal of the NMOS-FET 312 and the other input terminal of the operational amplifier 311 and the other end connected to the reference potential line GND. The resistance value of the resistor section Rop is variable, and the switching operations of the plurality of switch sections 322 are synchronized with the operation of changing the resistance value of the resistor section Rop. According to this, since the resistance value of the resistor section Rop is variable, the value of the operating current Iop generated by the current source circuit 31 changes. In addition, since the switching operations of the plurality of switch sections 322 and the operation of changing the resistance value of the resistor section Rop are synchronized with each other, the value of the drive current Iout supplied to each iPM laser 2 can be set for each iPM laser 2.

In the semiconductor light emitting device 1, the resistor section Rop includes a plurality of partial circuits 316a to 316d connected in parallel to each other between one end and the other end of the resistor section Rop. Each of the plurality of partial circuits 316a to 316d include the resistors Rop1 to Rop4 and the third switches 314a to 314d connected in series to each other between one end and the other end of the resistor section Rop. The switching operations of the plurality of switch sections 322 and the switching operations of the third switches 314a to 314d are synchronized with each other. According to this, the resistance value of the resistor section Rop can be made variable, and the switching operations of the plurality of switch sections 322 can be synchronized with the operation of changing the resistance value of the resistor section Rop.

In the semiconductor light emitting device 1, each of the plurality of iPM lasers 2 has the active layer 22 that is a light emitting section, the phase modulation layer 25A optically coupled to the active layer 22, the first cladding layer 21 located on the first surface 2a side of the active layer 22 and the phase modulation layer 25A, the second cladding layer 23 located on the second surface 2b side of the active layer 22 and the phase modulation layer 25A, the second electrode 26 located on the second surface 2b side of the second cladding layer 23, and the first electrode 27 located on the first surface 2a side of the first cladding layer 21. The phase modulation layer 25A includes the base layer 25a and a plurality of different refractive index regions 25b that are provided in the base layer 25a so as to be two-dimensionally distributed on a plane perpendicular to the normal direction of the first surface 2a and have a refractive index different from that of the base layer 25a. In a state where a virtual square lattice set on the plane, the plurality of different refractive index regions 25b are arranged so that the centroid G of each of the plurality of different refractive index regions 25b is away from the corresponding lattice point by the distance r(x, y) (predetermined distance). In addition, the angle ϕ(x, y) around each lattice point in the virtual square lattice, that is, the angle ϕ(x, y) of the line segment connecting the centroid G of each of the plurality of different refractive index regions 25b and the corresponding lattice point to each other with respect to the virtual square lattice, is set according to the phase distribution for forming an optical image, and at least two angles ϕ(x, y) among the angles ϕ(x, y) in the plurality of different refractive index regions 25b are different from each other. According to this, it is possible to suitably realize the iPM laser 2.

In the semiconductor light emitting device 1, the phase modulation layer 25B according to the modification example includes the base layer 25a and a plurality of different refractive index regions 25b that are provided in the base layer 25a so as to be two-dimensionally distributed on a plane perpendicular to the normal direction of the first surface 2a and have a refractive index different from that of the base layer 25a. Then, in a state where a virtual square lattice set on the plane, the plurality of different refractive index regions 25b are arranged so that the centroid G of each of the plurality of different refractive index regions 25b passes through the corresponding lattice point and is located on the straight line D inclined with respect to the virtual square lattice, and the distance r(x, y) along the straight line D between the centroid G of each of the plurality of different refractive index regions 25b and the corresponding lattice point is set according to the phase distribution for forming an optical image. Then, the inclination angle θ, which is the inclination of the straight line D, is uniform in the plurality of different refractive index regions 25b. According to this, it is possible to suitably realize the iPM laser.

In the semiconductor light emitting device 1, the drive circuit 3 is connected to the plurality of iPM lasers 2 by bump bonding. According to this, since the drive circuit 3 and the plurality of iPM lasers 2 can be integrated, the device can be made even smaller.

In the semiconductor light emitting device 1, each of the plurality of iPM lasers 2 is monolithically formed. According to this, the assembly of the semiconductor light emitting device 1 can be simplified by forming the plurality of iPM lasers 2 within a single element.

### Modification Examples

The present disclosure is not limited to the embodiment described above. FIG. 25(a) is a drawing showing a part of a drive circuit 3A according to a first modification example. Hereinafter, only the differences between the drive circuit 3A and the drive circuit 3 according to the embodiment will be described. The drive circuit 3A includes a current source circuit 31A, a digital-to-analog converter 317, and a serial-to-parallel converter 318. In the current source circuit 31A, the source terminal of the NMOS-FET 312 is connected to the resistor section Rop. One end of the resistor section Rop is connected to the source terminal of the NMOS-FET 312 and the inverting input terminal of the operational amplifier 311, and the other end of the resistor section Rop is connected to the reference potential line GND. The digital-to-analog converter 317 is connected to the non-inverting input terminal of the operational amplifier 311, and the serial-to-parallel converter 318 is further connected to the digital-to-analog converter 317. In the current source circuit 31A, the resistance value of the resistor section Rop may be variable as in the above-described embodiment, or may be fixed.

The serial-to-parallel converter 318 receives a serial signal S4 from an external control circuit provided outside the semiconductor light emitting device 1. The serial signal S4 includes an instruction signal S2 to the first shift register 34a, an instruction signal S3 to the second shift register 34b, and an instruction signal S5 for setting the input voltage Vop. In other words, the instruction signal S5 is a signal indicating an instruction value of the amount of current for the common current source circuit 31. The instruction signals S2 and S3 are, for example, digital data expressed in 4-bit binary notation, and the instruction signal S5 is, for example, digital data expressed in 8-bit to 12-bit binary notation. In this case, the serial signal S4 includes 16 to 20 bits of digital data. The number of wirings between the external control circuit and the serial-to-parallel converter 318 is, for example, about three. In addition to the wiring used for transmitting the serial signal S4, wirings for transmitting, for example, a clock signal and a synchronization signal are required. The serial-to-parallel converter 318 converts the serial signal S4 into a parallel signal S6 including the instruction signals S2, S3, and S5. The serial-to-parallel converter 316 outputs the instruction signal S2 of the parallel signal S6 to the first shift register 34a, and outputs the instruction signal S3 of the parallel signal S6 to the second shift register 34b.

The serial-to-parallel converter 318 outputs the instruction signal S5 among the parallel signals S6 to the digital-to-analog converter 317. The number of wirings between the serial-to-parallel converter 318 and the digital-to-analog converter 317 is determined according to the number of bits of the instruction signal S5, and is, for example, 8 to 12. The digital-to-analog converter 317 converts the instruction signal S5 from digital data into an analog signal, that is, the input voltage Vop, and then outputs the input voltage Vop to the non-inverting input terminal of the operational amplifier 311. The current source circuit 31A generates the operating current Iop having a magnitude according to the instruction signal S5, based on the input voltage Vop. In the current source circuit 31A, the instruction signal S5 changes in synchronization with the switching timing of the first switch 322a and the second switch 322b. In other words, the switching operation of the first switch 322a and the second switch 322b is synchronized with the operation of switching the value of the input voltage Vop. In this manner, the value of the drive current Iout is set for each iPM laser 2.

As described above, the drive circuit 3A according to the first modification example has the serial-to-parallel converter 318 for converting the serial signal S4, which includes digital data indicating a current instruction value for the current source circuit 31A, into the parallel signal S6 and the digital-to-analog converter 317 for converting the digital data converted into the parallel signal S6 into an analog signal. The current source circuit 31A generates the operating current Iop having a magnitude according to the instruction value, based on the analog signal (input voltage Vop). According to this, since digital data indicating the current instruction value for the current source circuit 31A can be received as the serial signal S4 from the external control circuit, the number of wirings connecting the semiconductor light emitting device 1 and the external control circuit to each other can be reduced, making the wiring thinner. As a result, for example, workability in three-dimensional measurement is improved.

FIG. 25(b) is a drawing showing a current source circuit 31B according to a second modification example. Hereinafter, only the differences between the current source circuit 31B and the current source circuit 31 according to the embodiment will be described. The current source circuit 31B does not have the voltage source 313 shown in FIG. 15. Instead, the input voltage Vop is supplied to the non-inverting input terminal of the operational amplifier 311 from an external control circuit provided outside the semiconductor light emitting device 1. In the current source circuit 31B, similarly to the current source circuit 31A, the magnitude of the input voltage Vop is changed in synchronization with the switching timing of the first switch 322a and the second switch 322b. Therefore, the value of the drive current Iout is set for each iPM laser 2. In the current source circuit 31B, the resistance value of the resistor section Rop may be variable as in the above-described embodiment, or may be fixed. According to the second modification example, since the input voltage Vop, which is an analog signal indicating a current instruction value for the current source circuit 31B, is input from an external control circuit, the number of wirings connecting the semiconductor light emitting device 1 and the external control circuit to each other can be reduced, making the wiring thinner. As a result, for example, workability in three-dimensional measurement is improved.

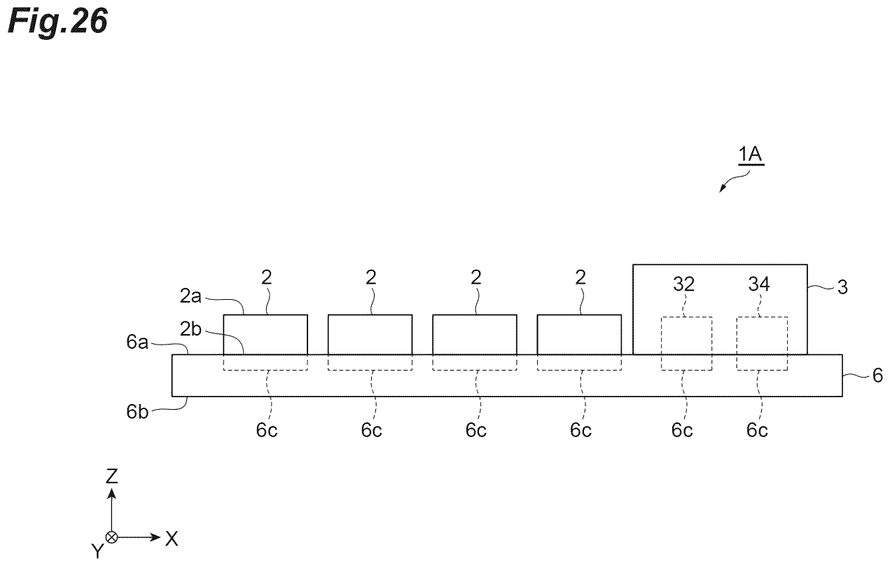

FIG. 26 is a side view of a semiconductor light emitting device 1A according to a third modification example. As shown in FIG. 26, the semiconductor light emitting device 1A includes a support substrate 6. The support substrate 6 has a third surface 6a and a fourth surface 6b on a side opposite to the third surface 6a. A plurality of iPM lasers 2 are not monolithic unlike in the above-described embodiment, but are present as individual chips, and are individually mounted on the third surface 6a with the second surface 2b facing the third surface 6a. The iPM lasers 2 adjacent to each other may be mounted at certain distances therebetween, or may be mounted without any spacing between them. In the example shown in FIG. 26, the plurality of iPM lasers 2 and the drive circuit 3 are provided on the common support substrate 6. Specifically, the plurality of iPM lasers 2 and the drive circuit 3 are arranged on the third surface 6a in a state of being aligned horizontally along the X-axis direction. The support substrate 6 includes a wiring thereinside, and a plurality of electrodes 6c are formed in line along the third surface 6a. Each iPM laser 2, each current mirror circuit 32 and each switch operating section 34 are electrically connected to the electrode 6c. That is, electrical connection between the plurality of iPM lasers 2 and the drive circuit 3 is made through the wiring of the support substrate 6, rather than by direct bump bonding as in the above-described embodiment. The drive circuit 3 may be arranged on the fourth surface 6b of the support substrate 6. That is, the plurality of iPM lasers 2 and the drive circuit 3 may be arranged on opposite sides with the support substrate 6 interposed therebetween. According to the configuration of the third modification example, since the plurality of iPM lasers 2 can be formed discretely on the support substrate 6, and the plurality of iPM lasers 2 formed discretely and the drive circuit 3 can be integrated on the support substrate 6, it is possible to make the device smaller as in the above-described embodiment.

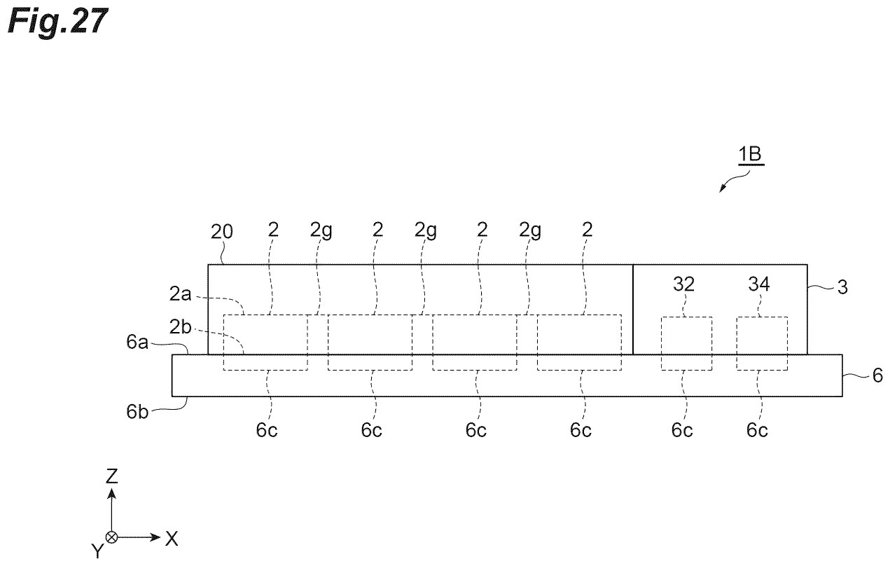

FIG. 27 is a side view of a semiconductor light emitting device 1B according to a fourth modification example. In this example, similarly to the above-described embodiment, a plurality of iPM lasers 2 are formed monolithically. The drive circuit 3 and the plurality of iPM lasers 2 formed monolithically are mounted on the common support substrate 6. According to this configuration, since the drive circuit 3 and the plurality of iPM lasers 2 formed monolithically can be integrated on the common support substrate 6, it is possible to make the device smaller as in the above-described embodiment.

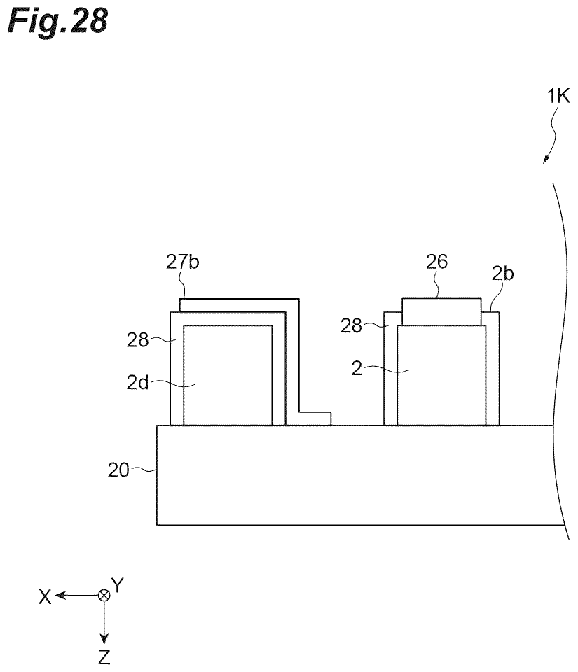

FIG. 28 is apart of a cross-sectional view of a semiconductor light emitting device 1K according to a fifth modification example. In the semiconductor light emitting device 1K, a semiconductor region 2d and a plurality of iPM lasers 2 are formed on a semiconductor substrate 20. The periphery of the semiconductor region 2d and the periphery of each iPM laser 2 are covered with an insulating film 28. A wiring electrode 27b is formed from the upper surface of the semiconductor region 2d to the side surface of the semiconductor region 2d through the insulating film 28. The wiring electrode 27b further continues from the side surface of the semiconductor region 2d and contacts the surface of the semiconductor substrate 20. The second electrode 26 is formed on the second surface 2b side of each iPM laser 2. The height in the Z-axis direction of the wiring electrode 27b formed on the upper surface of the semiconductor region 2d and the height of the second electrode 26 in the Z-axis direction are the same. Therefore, since both the N electrode (wiring electrode 27b) and the P electrode (second electrode 26) can be arranged on the common surface of the semiconductor substrate 20, a form suitable for surface mounting is obtained. In addition, by using the wiring electrode 27b, the wire bond required when the first electrode 27 is used is no longer necessary.

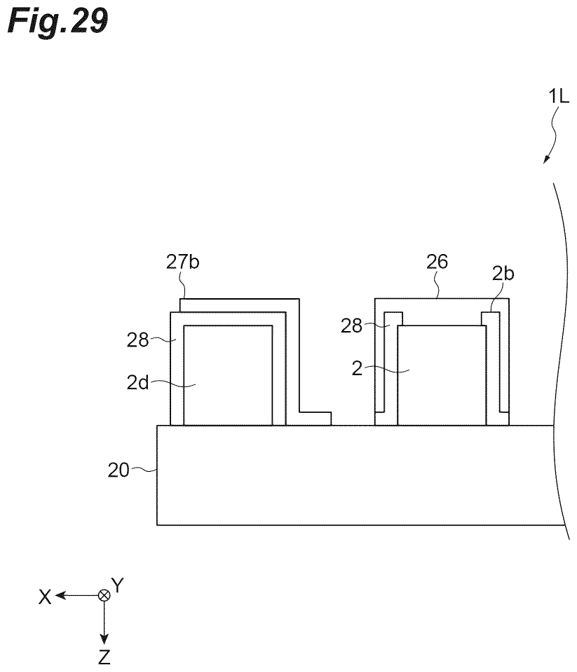

FIG. 29 is apart of a cross-sectional view of a semiconductor light emitting device 1L according to a sixth modification example. Only the differences from the semiconductor light emitting device 1K will be described. The side surface of each iPM laser 2 is covered with the second electrode 26 with the insulating film 28 interposed therebetween. The second electrode 26 is formed on the second surface 2b side of each iPM laser 2. That is, each iPM laser 2 is shielded by the second electrode 26 over its entire periphery. Therefore, it is possible to suppress interference between laser light generated in each iPM laser 2 and laser light generated in the adjacent iPM laser 2 and accordingly suppress laser mode disturbance, it is possible to realize stable laser oscillation. When laser light interference is actively utilized, it is preferable not to shield the outer periphery of the iPM laser 2 with an electrode unlike in the semiconductor light emitting device 1K.

### Second Embodiment

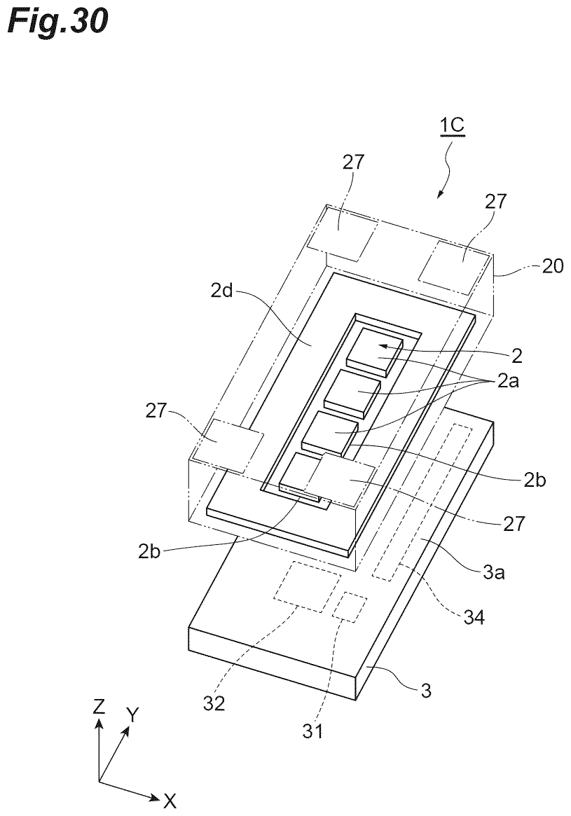

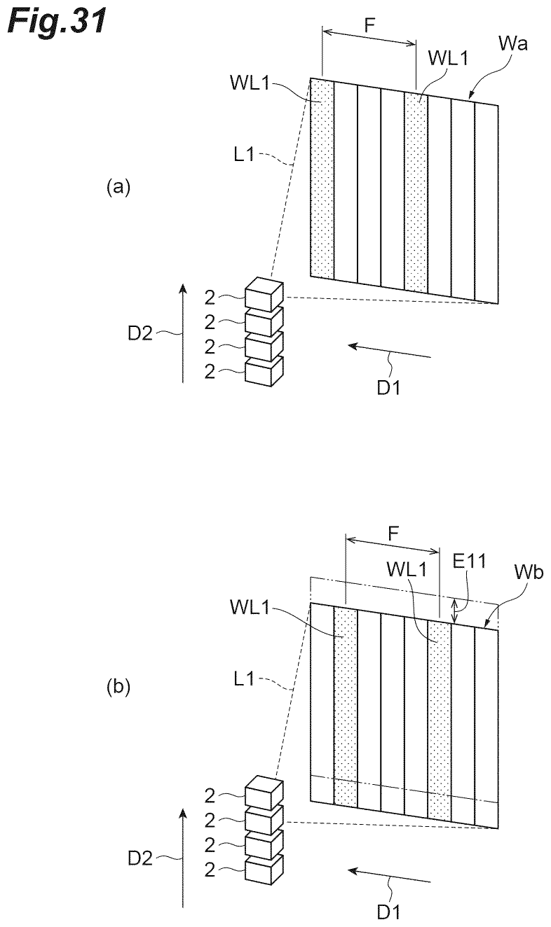

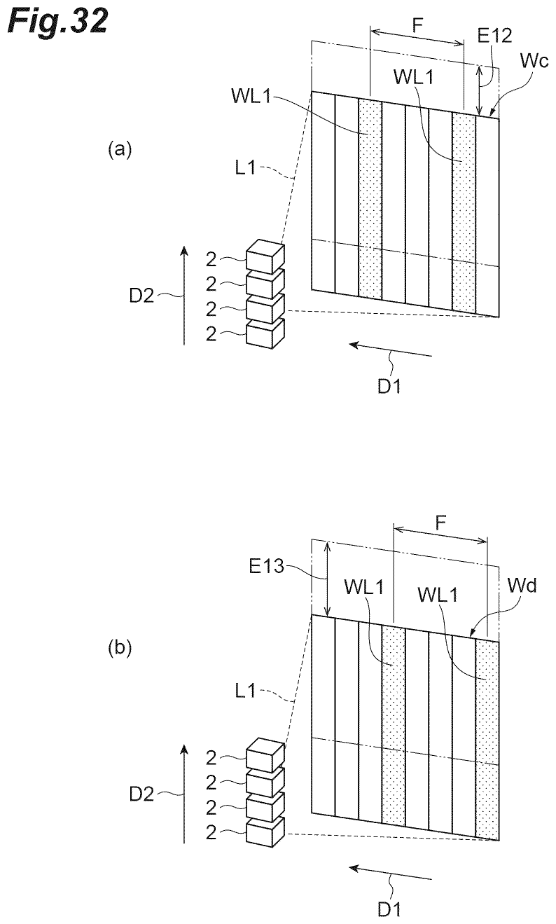

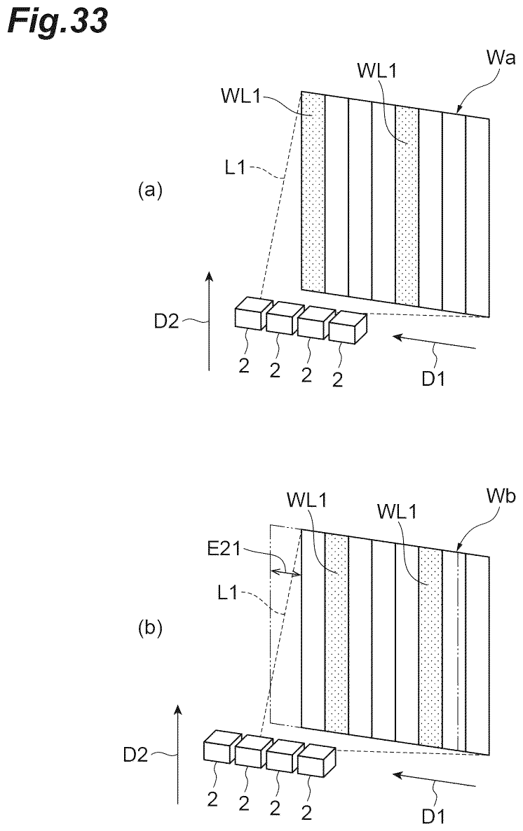

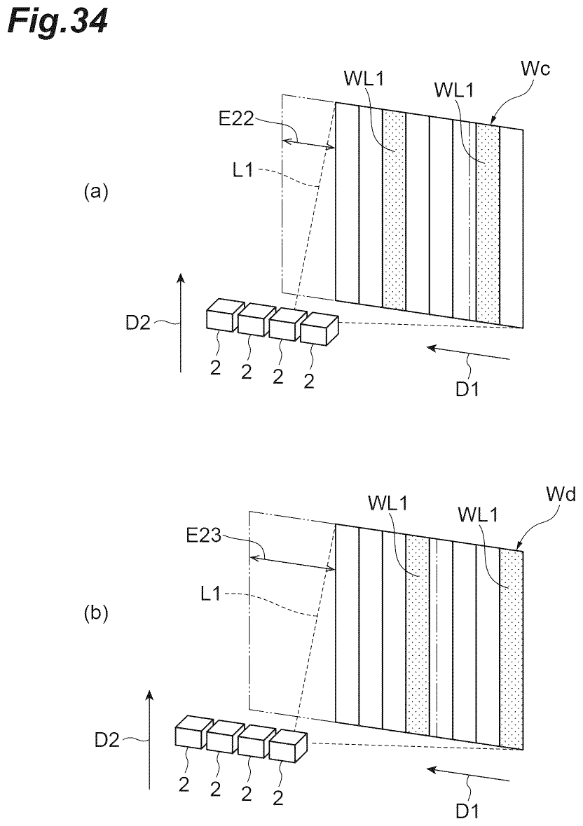

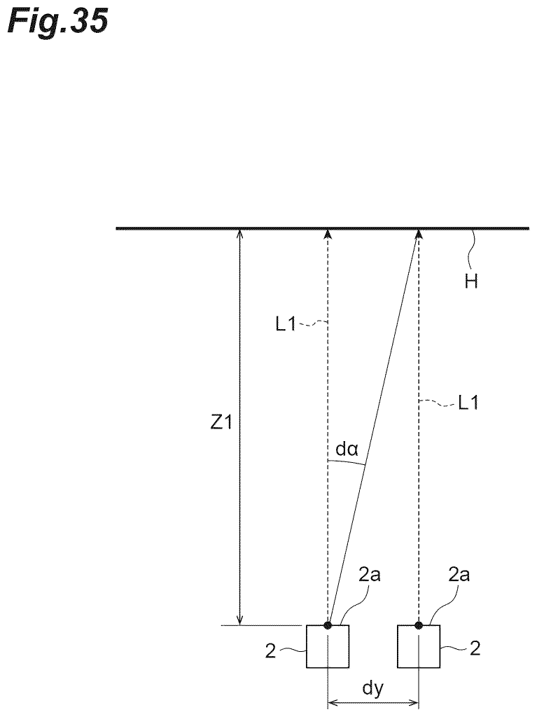

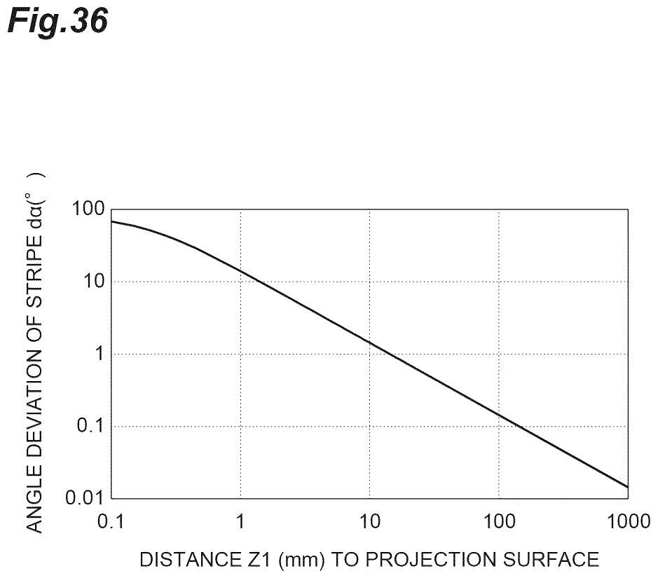

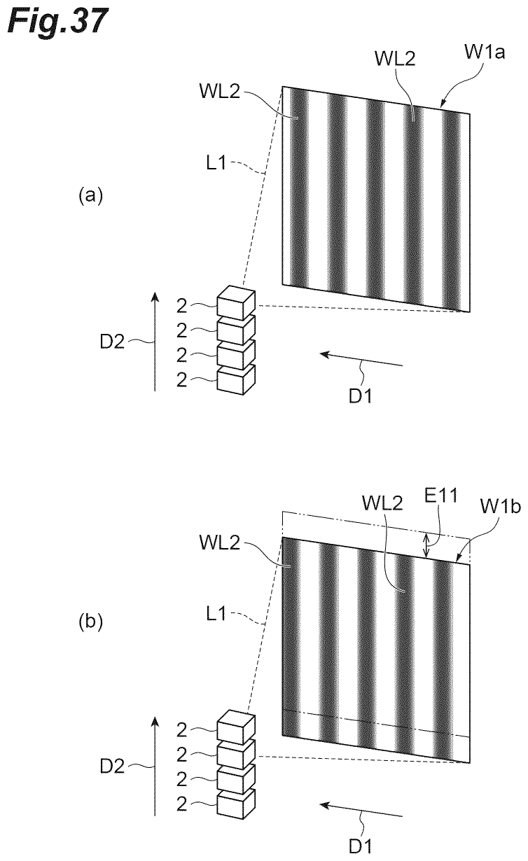

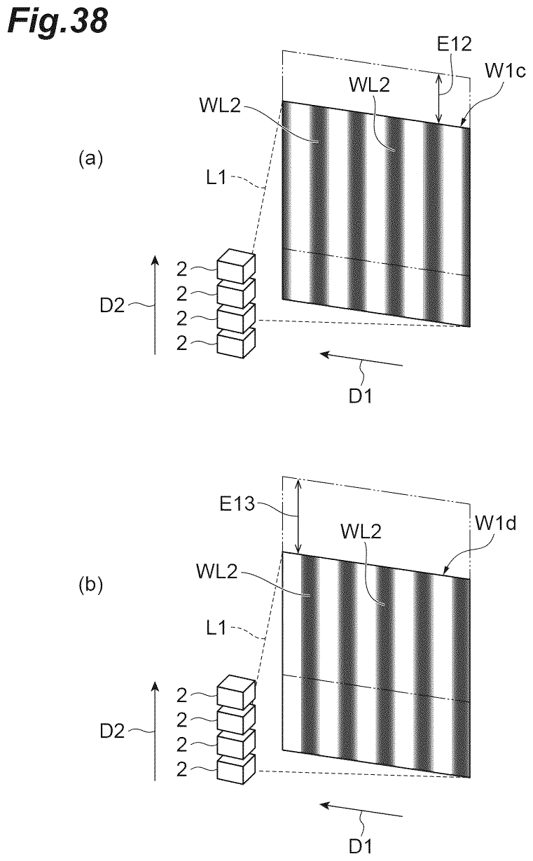

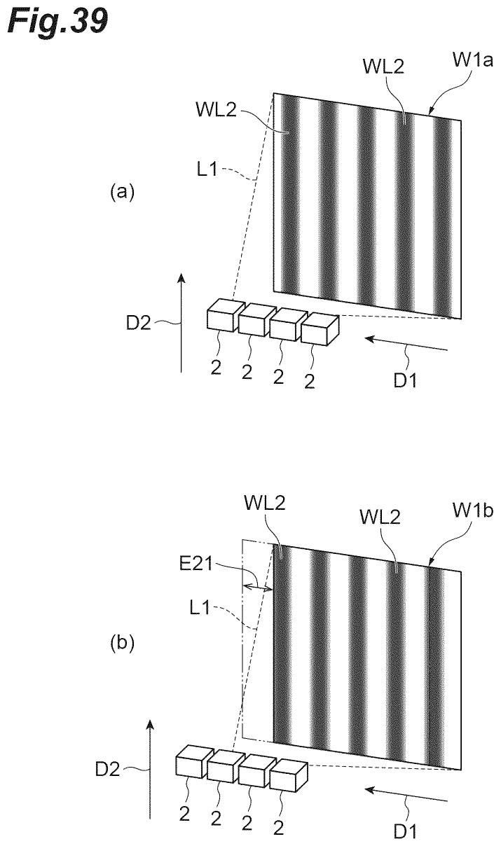

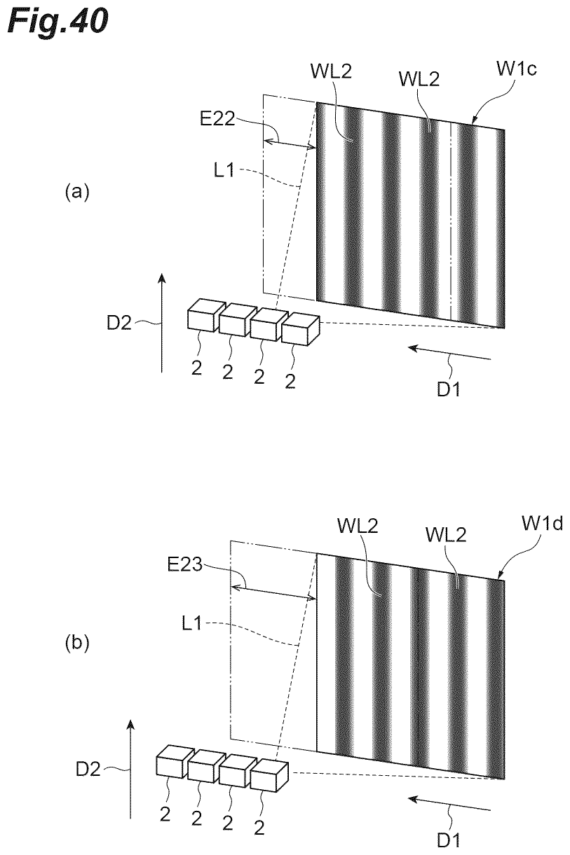

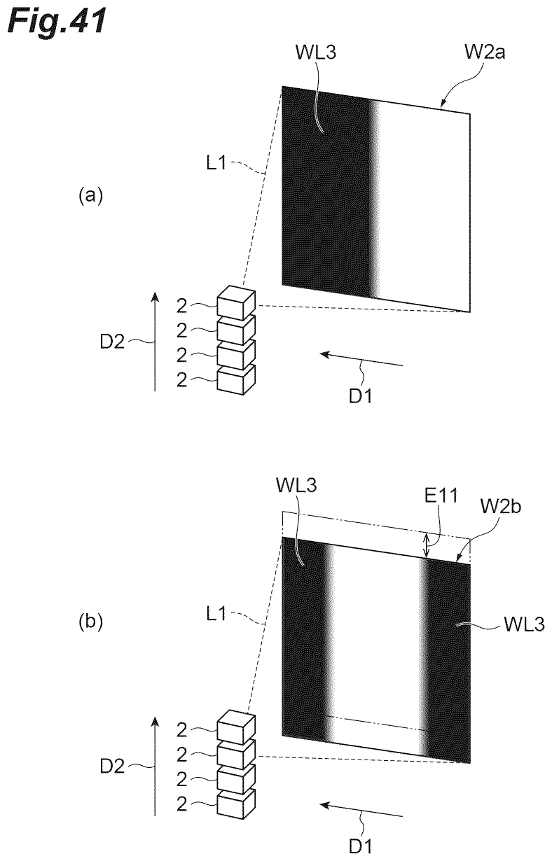

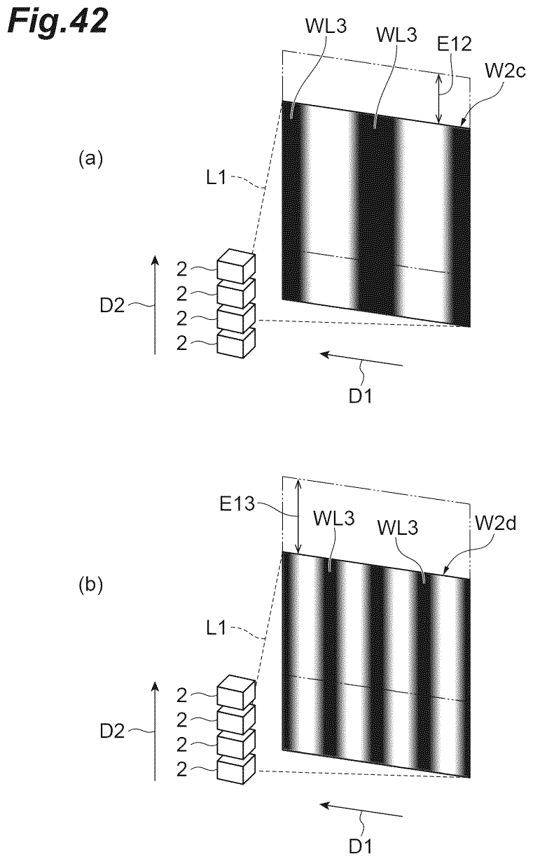

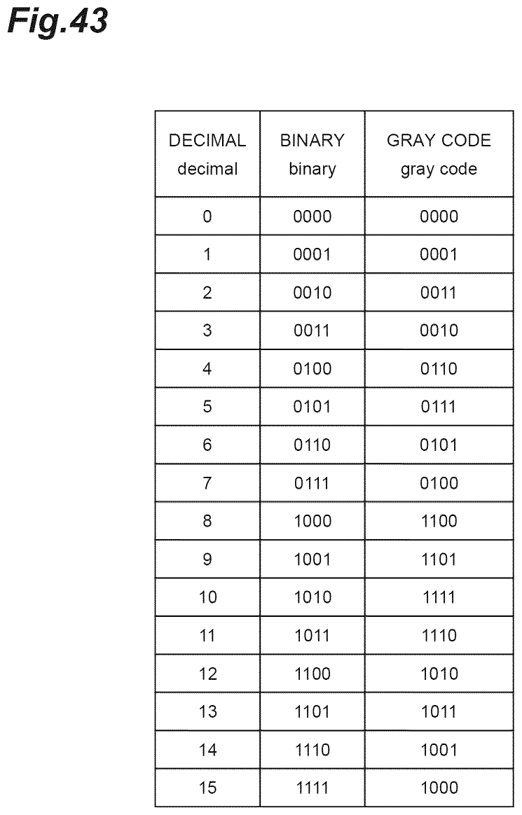

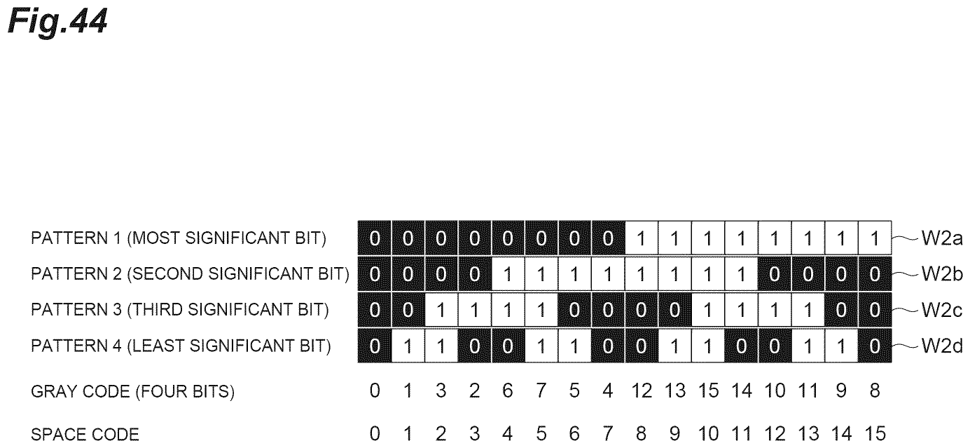

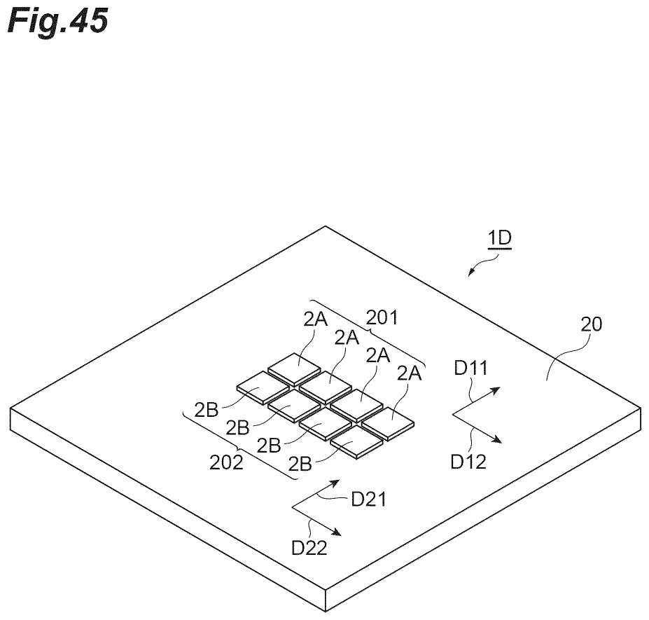

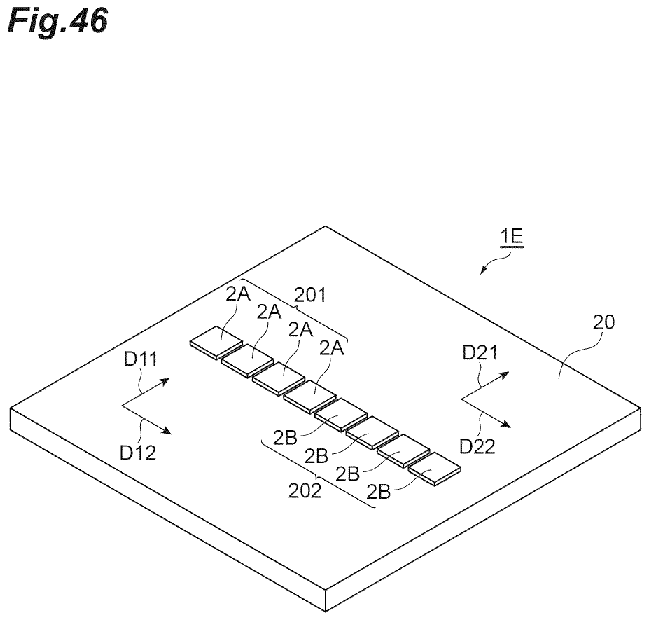

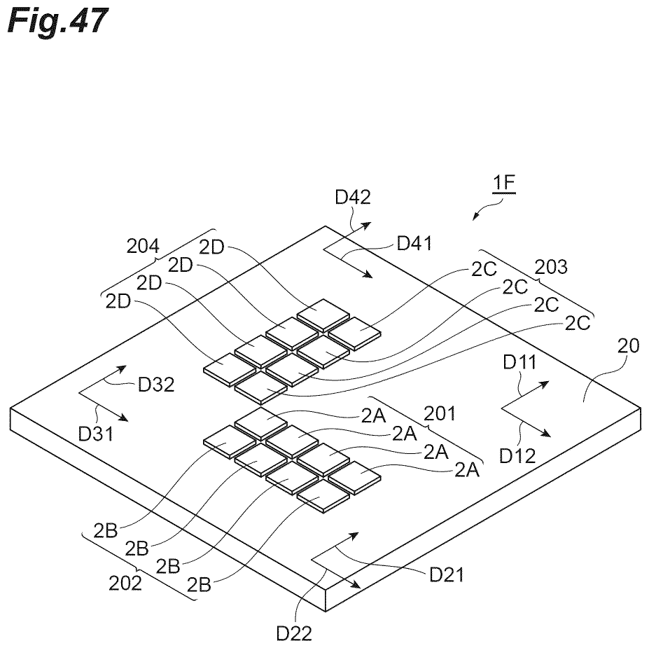

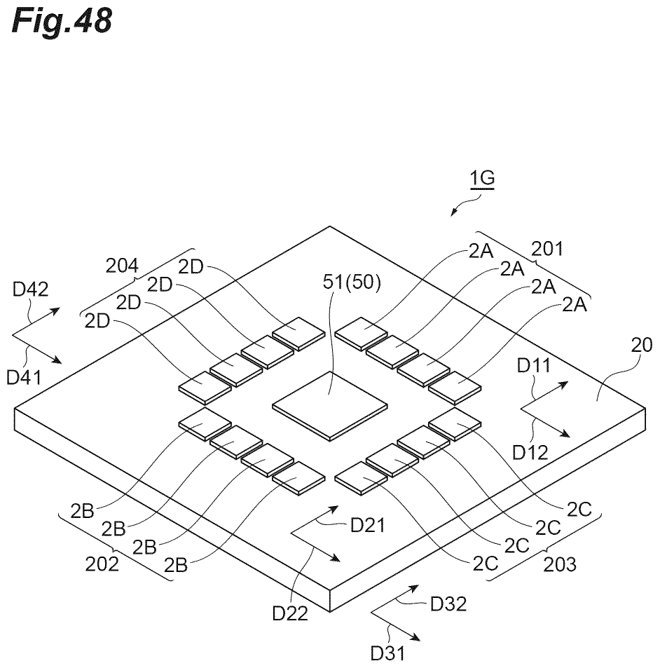

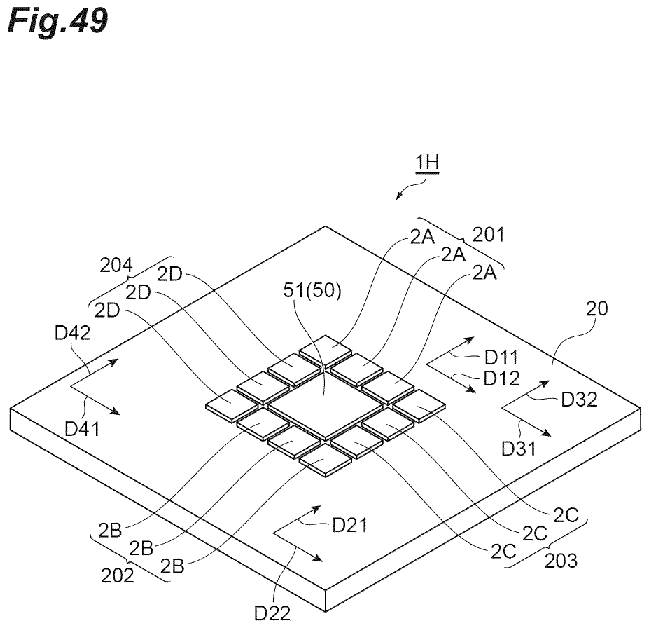

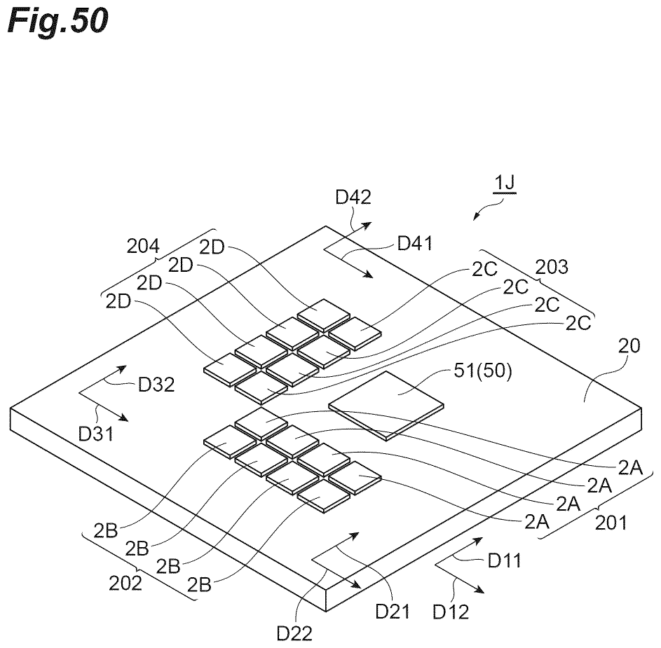

FIG. 30 is an exploded perspective view showing the configuration of a light source device 1C according to a second embodiment of the present disclosure. The three-dimensional measuring device 10 shown in FIG. 18 may include the light source device 1C of the present embodiment instead of the semiconductor light emitting device 1. That is, the light source device 1C according to the present embodiment is used for three-dimensional shape measurement using a phase shift method. As shown in FIG. 30, the light source device 1C includes a plurality of iPM lasers 2 (first light source), a drive circuit 3, a semiconductor substrate 20, a semiconductor region 2d, and a first electrode 27. In the present embodiment, the plurality of iPM lasers 2 are arranged one-dimensionally in a column with the Y-axis direction as a column direction. In the illustrated example, four iPM lasers 2 are arranged side by side along the Y-axis direction. As in the above-described embodiment, the plurality of iPM lasers 2 are monolithically formed on the semiconductor substrate 20. The plurality of iPM lasers 2 are arranged side by side in a direction crossing the optical axis direction of each iPM laser 2 so that their optical axis directions (in other words, the thickness direction of each iPM laser 2) are aligned. In the present embodiment, the optical axis direction of each iPM laser 2 matches the Z-axis direction, and the plurality of iPM lasers 2 are arranged side by side in the Y-axis direction perpendicular to the Z-axis direction. The other configurations of the plurality of iPM lasers 2 and configurations of the drive circuit 3, the semiconductor substrate 20, the semiconductor region 2d, and the first electrode 27 are the same as those in the semiconductor light emitting device 1 according to the embodiment previously described, and accordingly will not be described in detail.

FIGS. 31(a), 31(b), 32(a), and 32(b) are drawings schematically showing how light L1 including each of stripe elements Wa to Wd is projected from each of four iPM lasers 2 onto a common projection region. The stripe elements Wa to Wd are the first pattern in the present embodiment. In each of the stripe elements Wa to Wd, a plurality of bright lines WL1 (shown by halftone dots in the drawing) are periodically arranged along a direction D1 (first direction) crossing the extension direction of the bright line WL1. A distance F between the plurality of bright lines WL1 in the stripe elements Wa to Wd is equal in the stripe elements Wa to Wd (in other words, between the plurality of iPM lasers 2). In addition, the positions of the plurality of bright lines WL1 in the direction D1 with the position of the optical axis of each iPM laser 2 as a reference differ from each other between the plurality of iPM lasers 2. In the examples shown in FIGS. 31 and 32, the bright lines WL1 of the stripe elements Wa to Wd are shifted from each other by π/2 (rad), that is, ¼ period. When the number of iPM lasers 2 is n, the shift amount of the bright line WL1 between the plurality of iPM lasers 2 is 1/n of the distance (period) between the bright lines WL1. The plurality of iPM lasers 2 are aligned along a direction D2 (second direction) perpendicular to the direction D1. That is, the direction D2 matches the Y-axis direction shown in FIG. 30.

As shown in FIG. 31(a), first, the light L1 is projected from the iPM laser 2 (first iPM laser) located at one end in the direction D2. As a result, the stripe element Wa is projected onto the common projection region. Then, as shown in FIG. 31(b), the light L1 is projected from the iPM laser 2 (second iPM laser) located next to the first iPM laser in the direction D2. As a result, the stripe element Wb is projected onto the common projection region. At this time, a positional deviation E11 in the direction D2 occurs between the stripe elements Wa and Wb output from these iPM lasers 2 according to the arrangement pitch (optical axis distance) between the first iPM laser and the second iPM laser. The magnitude of the positional deviation E11 is equal to the optical axis distance between the first iPM laser and the second iPM laser. On the other hand, the position of the bright line WL1 of the stripe element Wb in the direction D1 is a predetermined position, that is, a position shifted by ¼ period from the bright line WL1 of the stripe element Wa, and no positional deviation from the predetermined position occurs. Then, as shown in FIG. 32(a), the light L1 is projected from the iPM laser 2 (third iPM laser) located next to the second iPM laser in the direction D2. As a result, the stripe element We is projected onto the common projection region. At this time, a positional deviation E12 in the direction D2 occurs between the stripe elements Wa and We according to the arrangement pitch (optical axis distance) between the first iPM laser and the third iPM laser. The magnitude of the positional deviation E12 is equal to the sum of the optical axis distances between the first iPM laser and the third iPM laser. On the other hand, the position of the bright line WL1 of the stripe element We in the direction D1 is a predetermined position, that is, a position shifted by ½ period from the bright line WL1 of the stripe element Wa, and no positional deviation from the predetermined position occurs. Then, as shown in FIG. 32(b), the light L1 is projected from the iPM laser 2 (fourth iPM laser) located next to the third iPM laser in the direction D2. As a result, the stripe element Wd is projected onto the common projection region. At this time, a positional deviation E13 in the direction D2 occurs between the stripe elements Wa and Wd according to the arrangement pitch (optical axis distance) between the first iPM laser and the fourth iPM laser. The magnitude of the positional deviation E13 is equal to the sum of the optical axis distances between the first iPM laser and the fourth iPM laser. On the other hand, the position of the bright line WL1 of the stripe element Wd in the direction D1 is a predetermined position, that is, a position shifted by ¾ period from the bright line WL1 of the stripe element Wa, and no positional deviation from the predetermined position occurs.

Here, as a comparative example of the present embodiment, a case where a plurality of iPM lasers 2 are arranged along the direction D1 will be described. FIGS. 33(a), 33(b), 34(a), and 34(b) are drawings schematically showing how the light L1 including the stripe elements Wa to Wd is projected onto a common projection region from each of the four iPM lasers 2 in such a comparative example. As shown in FIG. 33(a), first, the light L1 is projected from the iPM laser 2 (first iPM laser) located at one end in the direction D1. As a result, the stripe element Wa is projected onto the common projection region. Then, as shown in FIG. 33(b), the light L1 is projected from the iPM laser 2 (second iPM laser) located next to the first iPM laser in the direction D1. As a result, the stripe element Wb is projected onto the common projection region. At this time, a positional deviation E21 in the direction D1 occurs between the stripe elements Wa and Wb output from these iPM lasers 2 according to the arrangement pitch (optical axis distance) between the first iPM laser and the second iPM laser. The magnitude of the positional deviation E21 is equal to the optical axis distance between the first iPM laser and the second iPM laser. This positional deviation E21 causes a positional deviation from a predetermined position of the bright line WL1 of the stripe element Wb in the direction D1, that is, a position shifted by ¼ period from the bright line WL1 of the stripe element Wa, to occur in the bright line WL1 of the stripe element Wb. Then, as shown in FIG. 34(a), the light L1 is projected from the iPM laser 2 (third iPM laser) located next to the second iPM laser in the direction D1. As a result, the stripe element We is projected onto the common projection region. At this time, a positional deviation E22 in the direction D1 occurs between the stripe elements Wa and We according to the arrangement pitch (optical axis distance) between the first iPM laser and the third iPM laser. The magnitude of the positional deviation E22 is equal to the sum of the optical axis distances between the first iPM laser and the third iPM laser. This positional deviation E22 causes a positional deviation from a predetermined position of the bright line WL1 of the stripe element We in the direction D1, that is, a position shifted by ½ period from the bright line WL1 of the stripe element Wa, to occur in the bright line WL1 of the stripe element Wc. Then, as shown in FIG. 34(b), the light L1 is projected from the iPM laser 2 (fourth iPM laser) located next to the third iPM laser in the direction D1. As a result, the stripe element Wd is projected onto the common projection region. At this time, a positional deviation E23 in the direction D1 occurs between the stripe elements Wa and Wd according to the arrangement pitch (optical axis distance) between the first iPM laser and the fourth iPM laser. The magnitude of the positional deviation E23 is equal to the sum of the optical axis distances between the first iPM laser and the fourth iPM laser. This positional deviation E23 causes a positional deviation from a predetermined position of the bright line WL1 of the stripe element Wd in the direction D1, that is, a position shifted by ¾ period from the bright line WL1 of the stripe element Wa, to occur in the bright line WL1 of the stripe element Wd.

FIG. 35 is a drawing for explaining a problem caused by the positional deviation of the bright line WL1 in the above comparative example. In FIG. 35, two iPM lasers 2 adjacent to each other representing a plurality of iPM lasers 2 are shown. It is assumed that the alignment pitch between the two iPM lasers 2 adjacent to each other is dy, the distance from the first surface 2a of each of these iPM lasers 2 to the projection surface H is Z1, and the deviation of the central angle of the stripe element between the two iPM lasers 2 adjacent to each other is dα. At this time, the deviation dα of the central angle is geometrically expressed as the following Expression (35) using the arrangement pitch dy and the distance Z1.

$$\begin{matrix}[ Expression 35 ] & \\ d α = {tan}^{- 1} ( \frac{dy}{Z 1} ) & ( 35 )\end{matrix}$$

FIG. 36 is a graph showing the relationship between the distance Z1 and the central angle deviation dα when the arrangement pitch dy is set to 0.25 mm in Expression (35). In FIG. 36, the horizontal axis indicates the distance Z1 (mm), and the vertical axis indicates the central angle deviation dα (°). Representative values of the central angle deviation dα for the distance Z1 are listed below.

$$\begin{matrix}Z 1 = 1 mm \to d α = 14. ° \\ Z 1 = 1 mm \to d α = 2.86 ° \\ Z 1 = 5 mm \to d α = 1.43 ° \\ Z 1 = 10 mm \to d α = 0.286 ° \\ Z 1 = 50 mm \to d α = 0.143 ° \\ Z 1 = 100 mm \to d α = 0.0286 ° \\ Z 1 = 1 mm \to d α = 0.0143 °\end{matrix}$$

As is apparent from FIG. 36 and the above list, the smaller the distance Z1, the larger the central angle deviation dα. For example, when the distance Z1 is 50 mm, the central angle deviation dα is 0.286° near the center of the stripe element (near the optical axis). However, if the period of a typical stripe is 10, the deviation error is 28.6%. This value corresponds to the amount of shift of a stripe element at one time, for example, the amount of shift from the position of the stripe element Wa to the position of the stripe element Wb. Thus, as the central angle deviation dα increases, the error when forming the stripe pattern W1 increases, and the measurement error in the three-dimensional shape measurement increases. Depending on the application of the light source device 1C (for example, acquisition of a stereoscopic image of the oral cavity in dentistry), the distance Z1 must be reduced, and accordingly, it is desirable to reduce the above measurement error.

To address the above problem, when a plurality of iPM lasers 2 are arranged along the direction D2 perpendicular to the direction D1 as in the present embodiment (see FIGS. 31 and 32), the arrangement direction of the plurality of iPM lasers 2 is perpendicular to the arrangement direction of the bright lines WL1 of the stripe elements Wa to Wd. Therefore, even if the positional deviations E11 to E13 occur between the plurality of stripe elements Wa to Wd, the positional deviations E11 to E13 do not affect the formation of the stripe pattern W1. Therefore, compared to the comparative example described above, it is possible to reduce the measurement error in three-dimensional shape measurement.

In the light source device 1C according to the present embodiment, the distance F between the bright lines WL1 of the stripe elements Wa to Wd is equal between the plurality of iPM lasers 2, and the position of the bright line WL1 in the direction D1 with the optical axis of each iPM laser 2 as a reference differs between the plurality of iPM lasers 2. By projecting each of such stripe elements Wa to Wd from each of the plurality of iPM lasers 2 onto the common projection region, it is possible to suitably perform three-dimensional shape measurement using a phase shift method.

As in the present embodiment, the light source device 1C may include a plurality of iPM lasers 2 as a plurality of first light sources. In this case, a light source that outputs the light L1 including the stripe elements Wa to Wd can be made small, and accordingly, the light source device 1C can be made small. The first light source is not limited to the iPM laser 2. The first light source may be any other element (for example, an element obtained by combining a semiconductor laser and a diffraction grating element (DOE)) as long as it is possible to project the light L1 including the stripe elements Wa to Wd in which the plurality of bright lines WL1 are periodically arranged along the direction D1.

As in the present embodiment, the plurality of iPM lasers 2 may be formed monolithically each other. In this case, the assembly of the light source device 1C can be simplified by forming the plurality of iPM lasers 2 within a single element.

As in the present embodiment, the number of the plurality of iPM lasers 2 may be n, and the shift amount of the bright line WL1 between the plurality of iPM lasers 2 may be 1/n of the distance F between the bright lines WL1. In this case, three-dimensional shape measurement using a phase shift method can be suitably performed by forming the stripe pattern W1 shown in FIG. 19.

FIGS. 37(a), 37(b), 38(a), and 38(b) are drawings for explaining a modification example of the second embodiment, and schematically show how the light L1 including each of stripe patterns W1a to W1d is projected from each of four iPM lasers 2 onto a common projection region. The stripe patterns W1a to W1d are the first pattern in this modification example. In these drawings, the light intensity of the stripe patterns W1a to W1d is expressed by the shade of color, with a higher light intensity being expressed as darker and a lower light intensity being expressed as lighter. In each of the stripe patterns W1a to W1d, a plurality of bright lines WL2 are periodically arranged along the direction D1 crossing the extension direction of the bright line WL2. Each of the stripe patterns W1a to W1d is preferably a pattern in which the light intensity changes sinusoidally along the direction D1, for example, as shown in FIG. 19. However, each of the stripe patterns W1a to W1d does not need to be a sinusoidal wave pattern. Each of the stripe patterns W1a to W1d can be a top hat pattern. That is, in this modification example, a stripe pattern is projected from each iPM laser 2 onto the object to be measured while shifting the phase of the stripe pattern of each iPM laser 2 for each iPM laser 2, and imaging is performed for each projection of the stripe pattern from each iPM laser 2, thereby performing three-dimensional shape measurement using a phase shift method. Except for the pattern output from the iPM laser 2, the configuration of the light source device is the same as that in the second embodiment described above.

The distance between the plurality of bright lines WL2 of the stripe patterns W1a to W1d, that is, the period of the bright line WL2, is equal between the stripe patterns W1a to W1d (in other words, between the plurality of iPM lasers 2). The positions, that is, phases, of the plurality of bright lines WL2 in the direction D1 with the position of the optical axis of each iPM laser 2 as a reference are different between the plurality of iPM lasers 2. In the examples shown in FIGS. 37 and 38, the bright lines WL2 of the stripe patterns W1a to W1d are shifted from each other by π/2 (rad), that is, ¼ period. When the number of iPM lasers 2 is n, the shift amount of the bright line WL2 between the plurality of iPM lasers 2 is 1/n of the distance (period) between the bright lines WL2. The phase modulation layer 25A or 25B of each iPM laser 2 has a phase distribution for outputting the above-described stripe patterns W1a to W1d. The plurality of iPM lasers 2 are arranged along the direction D2 perpendicular to the direction D1 as in the second embodiment. That is, the direction D2 matches the Y-axis direction shown in FIG. 30.

As shown in FIG. 37(a), first, the light L1 is projected from the iPM laser 2 (first iPM laser) located at one end in the direction D2. As a result, the stripe pattern W1a is projected onto the common projection region. Then, as shown in FIG. 37(b), the light L1 is projected from the iPM laser 2 (second iPM laser) located next to the first iPM laser in the direction D2. As a result, the stripe pattern W1b is projected onto the common projection region. At this time, a positional deviation E11 in the direction D2 occurs between the stripe patterns W1a and W1b output from these iPM lasers 2 according to the arrangement pitch (optical axis distance) between the first iPM laser and the second iPM laser. On the other hand, the position of the bright line WL2 of the stripe pattern W1b in the direction D1 is a predetermined position, that is, a position shifted by ¼ period from the bright line WL2 of the stripe pattern W1a, and no positional deviation from the predetermined position occurs. Then, as shown in FIG. 38(a), the light L1 is projected from the iPM laser 2 (third iPM laser) located next to the second iPM laser in the direction D2. As a result, the stripe pattern W1c is projected onto the common projection region. At this time, a positional deviation E12 in the direction D2 occurs between the stripe patterns W1a and W1c according to the arrangement pitch (optical axis distance) between the first iPM laser and the third iPM laser. On the other hand, the position of the bright line WL2 of the stripe pattern W1c in the direction D1 is a predetermined position, that is, a position shifted by ½ period from the bright line WL2 of the stripe pattern W1a, and no positional deviation from the predetermined position occurs. Then, as shown in FIG. 38(b), the light L1 is projected from the iPM laser 2 (fourth iPM laser) located next to the third iPM laser in the direction D2. As a result, the stripe pattern W1d is projected onto the common projection region. At this time, a positional deviation E13 in the direction D2 occurs between the stripe patterns W1a and W1d according to the arrangement pitch (optical axis distance) between the first iPM laser and the fourth iPM laser. On the other hand, the position of the bright line WL2 of the stripe pattern W1d in the direction D1 is a predetermined position, that is, a position shifted by ¾ period from the bright line WL2 of the stripe pattern W1a, and no positional deviation from the predetermined position occurs.

Here, as a comparative example of this modification example, a case where a plurality of iPM lasers 2 are arranged along the direction D1 will be described. FIGS. 39(a), 39(b), 40(a), and 40(b) are drawings schematically showing how the light L1 including the stripe patterns W1a to W1d is projected onto a common projection region from each of the four iPM lasers 2 in such a comparative example. As shown in FIG. 39(a), first, the light L1 is projected from the iPM laser 2 (first iPM laser) located at one end in the direction D1. As a result, the stripe pattern W1a is projected onto the common projection region. Then, as shown in FIG. 39(b), the light L1 is projected from the iPM laser 2 (second iPM laser) located next to the first iPM laser in the direction D1. As a result, the stripe pattern W1b is projected onto the common projection region. At this time, a positional deviation E21 in the direction D1 occurs between the stripe patterns W1a and W1b output from these iPM lasers 2 according to the arrangement pitch (optical axis distance) between the first iPM laser and the second iPM laser. This positional deviation E21 causes a positional deviation from a predetermined position of the bright line WL2 of the stripe pattern W1b in the direction D1, that is, a position shifted by ¼ period from the bright line WL2 of the stripe pattern W1a, to occur in the bright line WL2 of the stripe pattern W1b. Then, as shown in FIG. 40(a), the light L1 is projected from the iPM laser 2 (third iPM laser) located next to the second iPM laser in the direction D1. As a result, the stripe pattern W1c is projected onto the common projection region. At this time, a positional deviation E22 in the direction D1 occurs between the stripe patterns W1a and W1c according to the arrangement pitch (optical axis distance) between the first iPM laser and the third iPM laser. This positional deviation E22 causes a positional deviation from a predetermined position of the bright line WL2 of the stripe pattern W1c in the direction D1, that is, a position shifted by ½ period from the bright line WL2 of the stripe pattern W1a, to occur in the bright line WL2 of the stripe pattern W1c. Then, as shown in FIG. 40(b), the light L1 is projected from the iPM laser 2 (fourth iPM laser) located next to the third iPM laser in the direction D1. As a result, the stripe pattern W1d is projected onto the common projection region. At this time, a positional deviation E23 in the direction D1 occurs between the stripe patterns W1a and W1d according to the arrangement pitch (optical axis distance) between the first iPM laser and the fourth iPM laser. This positional deviation E23 causes a positional deviation from a predetermined position of the bright line WL2 of the stripe pattern W1d in the direction D1, that is, a position shifted by ¾ period from the bright line WL2 of the stripe pattern W1a, to occur in the bright line WL2 of the stripe pattern W1d. In the comparative example, due to the positional deviation of the bright line WL2, the phase shift accuracy of the stripe patterns W1b to W1d decreases, resulting in a large measurement error.

To address the above problem, when a plurality of iPM lasers 2 are arranged along the direction D2 perpendicular to the direction D1 as in this modification example (see FIGS. 37 and 38), the arrangement direction of the plurality of iPM lasers 2 is perpendicular to the arrangement direction of the bright lines WL2 of the stripe patterns W1a to W1d. Therefore, even if the positional deviations E11 to E13 occur between the plurality of stripe patterns W1a to W1d, the positional deviations E11 to E13 do not affect the phase shift accuracy of the stripe patterns W1b to W1d. Therefore, compared to the comparative example described above, it is possible to reduce the measurement error in three-dimensional shape measurement.

In this modification example, the distance (period) between the bright lines WL2 of the stripe patterns W1a to W1d is equal between the plurality of iPM lasers 2, and the position (phase) of the bright line WL2 in the direction D1 with the optical axis of each iPM laser 2 as a reference differs between the plurality of iPM lasers 2. By projecting each of such stripe patterns W1a to W1d from each of the plurality of iPM lasers 2 onto the common projection region, it is possible to suitably perform three-dimensional shape measurement using a phase shift method.

FIGS. 41(a), 41(b), 42(a), and 42(b) are drawings for explaining other modification examples of the second embodiment, and schematically show how the light L1 including stripe patterns W2a to W2d is projected from each of four iPM lasers 2 onto a common projection region. The stripe patterns W2a to W2d are the first pattern in this modification example. In these drawings, the light intensity of the stripe patterns W2a to W2d is expressed by the shade of color, with a lower light intensity being expressed as lighter (whiter) and a higher light intensity being expressed as darker (blacker). In each of the stripe patterns W2a to W2d, a plurality of bright lines WL3 are arranged along the direction D1 intersecting the extension direction of the bright line WL3. Each of the stripe patterns W2a to W2d includes a gray code pattern. That is, the width and position of the bright line WL3 indicate a gray code. In this modification example, a stripe pattern is projected from each iPM laser 2 onto an object to be measured while changing the gray code included in the stripe pattern of each iPM laser 2 for each iPM laser 2, and imaging is performed each time a stripe pattern is projected from each iPM laser 2, thereby performing three-dimensional shape measurement. Except for the pattern output from the iPM laser 2, the configuration of the light source device is the same as that in the second embodiment.

The gray code is one of the way of expressing binary numbers. FIG. 43 is a chart showing conversion among decimal numbers, binary code that is another way of expressing binary numbers, and gray code. The gray code has a characteristic that only one bit changes when a number is increased or decreased by one. Since the change is only one bit, a malfunction is unlikely to occur. Therefore, the gray code is often used in digital circuits and the like. FIG. 44 is a drawing showing an example of a combination of stripe patterns including a 4-bit gray code. This drawing shows the brightness and darkness of each of a plurality of bits aligned along the direction D1. As an example, FIG. 44 shows stripe patterns W2a to W2d including four different gray codes. The conversion from binary code to gray code follows the following rules. First, it is assumed that the most significant bit 1 of the gray code is the same as the binary code. From then on, two adjacent bits are referenced in order from the high-order bit. If there are consecutive 1s or 0s, the corresponding bit of the gray code is set to 0, and if there are no consecutive 1s or 0s, the corresponding bit of the Gray code is set to 1. Alternatively, the conversion from binary code to gray code may follow the following rules. First, a target binary code is prepared. Then, the binary code is shifted one bit to the right to obtain a binary code with a leading 0. Then, the exclusive OR of that binary code and the original binary code is calculated. The result of this calculation is a gray code. In order to generate a gray code, for example, OpenCV can be used.

In the gray code, the Hamming distance between adjacent bits is 1. The Hamming distance refers to the number of different digits in corresponding positions when comparing two values having the same number of digits with each other. Therefore, in a gray code with a Hamming distance of 1, even if a bit error occurs when restoring a bit string, the error is within 1. In the binary code, an error in the position is large when an error occurs in the high-order bit. However, in the gray code, a code that is resistant to noise is obtained.

The stripe patterns W2a to W2d are striped patterns set to have different gray code values. By performing imaging with the imaging unit 50 while switching the four stripe patterns W2a to W2d in order, the three-dimensional shape of the object to be measured SA can be measured.

In order to avoid erroneous recognition due to the color of the surface of the object to be measured SA, a stripe pattern including another gray code in which each bit value of the gray code of the stripe patterns W2a to W2d shown in FIG. 44 is inverted may be used in combination. In this case, four more iPM lasers 2 for outputting a stripe pattern including a different gray code may be provided.

The plurality of iPM lasers 2 are arranged along the direction D2 perpendicular to the direction D1 as in the second embodiment. That is, the direction D2 matches the Y-axis direction shown in FIG. 30.

Using the stripe patterns W2a to W2d in FIG. 44 as an example, the operation of switching the four stripe patterns in order will be described. As shown in FIG. 41(a), first, the light L1 is projected from the iPM laser 2 (first iPM laser) located at one end in the direction D2. As a result, the stripe pattern W2a is projected onto the common projection region. Then, as shown in FIG. 41(b), the light L1 is projected from the iPM laser 2 (second iPM laser) located next to the first iPM laser in the direction D2. As a result, the stripe pattern W2b is projected onto the common projection region. At this time, a positional deviation E11 in the direction D2 occurs between the stripe patterns W2a and W2b output from these iPM lasers 2 according to the arrangement pitch (optical axis distance) between the first iPM laser and the second iPM laser. On the other hand, the position of the bright line WL3 of the stripe pattern W2b in the direction D1 does not deviate from the predetermined position.

Then, as shown in FIG. 42(a), the light L1 is projected from the iPM laser 2 (third iPM laser) located next to the second iPM laser in the direction D2. As a result, the stripe pattern W2c is projected onto the common projection region. At this time, a positional deviation E12 in the direction D2 occurs between the stripe patterns W2a and W2c according to the arrangement pitch (optical axis distance) between the first iPM laser and the third iPM laser. On the other hand, the position of the bright line WL3 of the stripe pattern W2c in the direction D1 does not deviate from the predetermined position. Then, as shown in FIG. 42(b), the light L1 is projected from the iPM laser 2 (fourth iPM laser) located next to the third iPM laser in the direction D2. As a result, the stripe pattern W2d is projected onto the common projection region. At this time, a positional deviation E13 in the direction D2 occurs between the stripe patterns W2a and W2d according to the arrangement pitch (optical axis distance) between the first iPM laser and the fourth iPM laser. On the other hand, the position of the bright line WL3 of the stripe pattern W2d in the direction D1 does not deviate from the predetermined position.

When the plurality of iPM lasers 2 are arranged along the direction D2 perpendicular to the direction D1 as in this modification example (see FIGS. 41 and 42), the arrangement direction of the plurality of iPM lasers 2 is perpendicular to the arrangement direction of the bright lines WL3 of the stripe patterns W2a to W2d. Therefore, even if the positional deviations E11 to E13 occur between the plurality of stripe patterns W2a to W2d, the positional deviations E11 to E13 do not affect the calculation of the three-dimensional shape. As a result, it is possible to reduce measurement errors in three-dimensional shape measurement.

### Third Embodiment

FIGS. 45 and 46 are perspective views showing the configurations of light source devices 1D and 1E according to a third embodiment of the present disclosure, respectively. The light source device 1D shown in FIG. 45 and the light source device 1E shown in FIG. 46 include light source groups 201 and 202. The light source group 201 includes a plurality of (four in the illustrated example) iPM lasers 2A (first light sources) arranged side by side in a direction crossing the optical axis direction so that each of their optical axis directions is aligned. The light source group 202 includes a plurality of (four in the illustrated example) iPM lasers 2B (second light sources) arranged side by side in a direction crossing the optical axis direction so that their optical axis directions are aligned. The plurality of iPM lasers 2A and the plurality of iPM lasers 2B are monolithically formed on the common semiconductor substrate 20. The internal structures of the iPM lasers 2A and 2B are the same as that of the iPM laser 2 in the first embodiment described above.

Each of the plurality of iPM lasers 2A projects light including each of the above-described stripe elements Wa to Wd (see FIGS. 31 and 32) or each of the stripe patterns W1a to W1d (see FIGS. 37 and 38) onto a common projection region. The stripe elements Wa to Wd or the stripe patterns W1a to W1d projected from the plurality of iPM lasers 2A are the first pattern in the present embodiment. Each of the plurality of iPM lasers 2B projects light including each of the stripe elements Wa to Wd or each of the stripe patterns W1a to W1d onto the common projection region. The stripe elements Wa to Wd or the stripe patterns W1a to W1d projected from the plurality of iPM lasers 2B are the second pattern in the present embodiment. The plurality of iPM lasers 2A are arranged along a direction D12 (corresponding to the above direction D2) perpendicular to an arrangement direction D11 (corresponding to the above direction D1) of the bright lines of the stripe elements Wa to Wd or the stripe patterns W1a to W1d, similarly to the plurality of iPM lasers 2 in the second embodiment or its modification example. The plurality of iPM lasers 2B are arranged along a direction D22 (fourth direction, corresponding to the above direction D2) perpendicular to an arrangement direction of the bright lines D21 (third direction, corresponding to the above direction D1) of the bright lines of the stripe elements Wa to Wd or the stripe patterns W1a to W1d. Although the directions D21 and D22 match the directions D11 and D12, respectively, in the illustrated example, the directions D21 and D22 may be different from the directions D11 and D12.

The period of the stripe pattern W1 (see FIG. 19) formed by the stripe elements Wa to Wd output from the light source group 202 or the period of the stripe patterns W1a to W1d is different from the period of the stripe pattern W1 formed by the stripe elements Wa to Wd output from the light source group 201 or the period of the stripe patterns W1a to W1d. In the light source device 1D shown in FIG. 45, the light source group 201 and the light source group 202 are arranged side by side in a direction crossing the respective arrangement directions D12 and D22. In the light source device 1E shown in FIG. 46, the light source group 201 and the light source group 202 are arranged side by side along the respective arrangement directions D12 and D22.

The distance (period) between the bright lines of the stripe elements Wa to Wd or the stripe patterns W1a to W1d is equal between the plurality of iPM lasers 2A. The position (phase) of the bright line in the direction D11 with the optical axis of each iPM laser 2A as a reference differs between the plurality of iPM lasers 2A. Similarly, the distance (period) between the bright lines of the stripe elements Wa to Wd or the stripe patterns W1a to W1d is equal between the plurality of iPM lasers 2B. The position (phase) of the bright line in the direction D21 with the optical axis of each iPM laser 2B as a reference differs between the plurality of iPM lasers 2B. By projecting such stripe elements Wa to Wd or stripe patterns W1a to W1d from the plurality of iPM lasers 2A or 2B onto the common projection region, it is possible to suitably perform three-dimensional shape measurement using a phase shift method.

In the light source devices 1D and 1E according to the present embodiment, it is possible to improve the measurement accuracy by performing three-dimensional shape measurement using a phase shift method at least twice using two light source groups, that is, the light source group 201 including a plurality of iPM lasers 2A and the light source group 202 including a plurality of iPM lasers 2B. In the light source devices 1D and 1E according to the present embodiment, the plurality of iPM lasers 2A are arranged along the direction D12 perpendicular to the arrangement direction D11 of the bright lines, and the plurality of iPM lasers 2B are arranged along the direction D22 perpendicular to the arrangement direction D21 of the bright lines. In this case, even if the positions of the iPM lasers 2A (or 2B) deviate from each other by the arrangement pitch, the direction of the deviation is perpendicular to the arrangement direction of the bright lines. Therefore, even if a positional deviation in the stripe elements Wa to Wd or the stripe patterns W1a to W1d occurs in the plurality of iPM lasers 2A (or 2B), the positional deviation does not affect the phase shift accuracy and the like. As a result, according to the light source devices 1D and 1E according to the present embodiment, it is possible to reduce measurement errors in three-dimensional shape measurement using a phase shift method.

As in the present embodiment, the distance (period) between the bright lines of the stripe patterns W1a to W1d or the stripe pattern W1 formed by the stripe elements Wa to Wd output from the light source group 202 may be different from the distance (period) between the bright lines of the stripe patterns W1a to W1d or the stripe pattern W1 formed by the stripe elements Wa to Wd output from the light source group 201. In this case, since three-dimensional shape measurement using a phase shift method can be performed using two types of stripe patterns with different distances between bright lines, it is possible to further improve the measurement accuracy.

### Modification Examples

FIG. 47 is a perspective view showing the configuration of a light source device 1F according to a modification example of the third embodiment. The light source device 1F shown in FIG. 47 further includes light source groups 203 and 204 in addition to the light source groups 201 and 202 in the third embodiment. The light source group 203 includes a plurality of (four in the illustrated example) iPM lasers 2C (second light sources) arranged side by side in a direction crossing the optical axis direction so that their optical axis directions are aligned. The light source group 204 includes a plurality of (four in the illustrated example) iPM lasers 2D (second light sources) arranged side by side in a direction crossing the optical axis direction so that their optical axis directions are aligned. The plurality of iPM lasers 2C and the plurality of iPM lasers 2D are monolithically formed on the common semiconductor substrate 20 together with the plurality of iPM lasers 2A and the plurality of iPM lasers 2B. The internal structures of the iPM lasers 2C and 2D are the same as that of the iPM laser 2 in the first embodiment described above.

Each of the plurality of iPM lasers 2C projects light including each of the above-described stripe elements Wa to Wd (see FIGS. 31 and 32) or each of the stripe patterns W1a to W1d (see FIGS. 37 and 38) onto the common projection region. The stripe elements Wa to Wd or the stripe patterns W1a to W1d projected from the plurality of iPM lasers 2C are the second pattern in this modification example. Each of the plurality of iPM lasers 2D projects light including each of the stripe elements Wa to Wd or each of the stripe patterns W1a to W1d onto the common projection region. The stripe elements Wa to Wd or the stripe patterns W1a to W1d projected from the plurality of iPM lasers 2D are the second pattern in this modification example. The plurality of iPM lasers 2C are arranged along a direction D32 (fourth direction, corresponding to the above direction D2) perpendicular to an arrangement direction D31 (third direction, corresponding to the above direction D1) of the bright lines of the stripe elements Wa to Wd or the stripe patterns W1a to W1d. The plurality of iPM lasers 2D are arranged along a direction D42 (fourth direction, corresponding to the above direction D2) perpendicular to an arrangement direction D41 (third direction, corresponding to the above direction D1) of the bright lines of the stripe elements Wa to Wd or the stripe patterns W1a to W1d. In the illustrated example, the directions D41 and D42 match the directions D31 and D32, respectively, but the directions D41 and D42 may be different from the directions D31 and D32. The directions D31 and D41 cross the directions D11 and D21. In the illustrated example, the directions D31 and D41 are perpendicular to the directions D11 and D21, but the directions D31 and D41 may be inclined with respect to the directions D11 and D21.

The period of the stripe patterns W1a to W1d or the period of the stripe pattern W1 (see FIG. 19) formed by the stripe elements Wa to Wd output from the light source group 203 may be different from the period of the stripe patterns W1a to W1d or the period of the stripe pattern W1 formed by the stripe elements Wa to Wd output from the light source group 204. In the light source device 1F shown in FIG. 47, the light source group 203 and the light source group 204 are arranged side by side in a direction crossing the respective arrangement directions D32 and D42, but the light source group 203 and the light source group 204 may be arranged side by side along the respective arrangement directions D32 and D42.

The distance (period) between the bright lines of the stripe elements Wa to Wd or the stripe patterns W1a to W1d is equal between the plurality of iPM lasers 2C. The position (phase) of the bright line in the direction D31 with the optical axis of each iPM laser 2C as a reference differs between the plurality of iPM lasers 2C. Similarly, the distance (period) between the bright lines of the stripe elements Wa to Wd or the stripe patterns W1a to W1d is equal between the plurality of iPM lasers 2D. The position (phase) of the bright line in the direction D41 with the optical axis of each iPM laser 2D as a reference differs between the plurality of iPM lasers 2D. By projecting such stripe elements Wa to Wd or stripe patterns W1a to W1d from the plurality of iPM lasers 2C or 2D onto the common projection region, it is possible to suitably perform three-dimensional shape measurement using a phase shift method.

In the light source device 1F according to this modification example, it is possible to improve the measurement accuracy by performing three-dimensional shape measurement using a phase shift method at least four times using four light source groups, that is, the light source group 201 including a plurality of iPM lasers 2A, the light source group 202 including a plurality of iPM lasers 2B, the light source group 203 including a plurality of iPM lasers 2C, and the light source group 204 including a plurality of iPM lasers 2D. In the light source device 1F according to this modification example, the plurality of iPM lasers 2C are arranged along the direction D32 perpendicular to the arrangement direction D31 of the bright lines, and the plurality of iPM lasers 2D are arranged along the direction D42 perpendicular to the arrangement direction D41 of the bright lines. In this case, even if the positions of the iPM lasers 2C (or 2D) deviate from each other by the arrangement pitch, the direction of the deviation is perpendicular to the arrangement direction of the bright lines. Therefore, even if a positional deviation in the stripe elements Wa to Wd or the stripe patterns W1a to W1d occurs in the plurality of iPM lasers 2C (or 2D), the positional deviation does not affect the phase shift accuracy and the like. As a result, according to the light source device 1F according to this modification example, it is possible to reduce measurement errors in three-dimensional shape measurement using a phase shift method.

As in this modification example, the distance (period) between the bright lines of the stripe patterns W1a to W1d or the stripe pattern W1 formed by the stripe elements Wa to Wd output from the light source group 204 may be different from the distance (period) between the bright lines of the stripe patterns W1a to W1d or the stripe pattern W1 formed by the stripe elements Wa to Wd output from the light source group 203. In this case, since three-dimensional shape measurement using a phase shift method can be performed using two types of stripe patterns with different distances between bright lines, it is possible to further improve the measurement accuracy.

As in this modification example, the arrangement direction D31 of the bright lines output from the plurality of iPM lasers 2C and the arrangement direction D41 of the bright lines output from the plurality of iPM lasers 2D may cross the arrangement direction D11 of the bright lines output from the plurality of iPM lasers 2A and the arrangement direction D21 of the bright lines output from the plurality of iPM lasers 2B. In this case, since three-dimensional shape measurement using a phase shift method can be performed using two or more types of stripe patterns with different directions of bright line arrangement, it is possible to further improve the measurement accuracy.

### Fourth Embodiment

FIG. 48 is a perspective view showing the configuration of a light receiving and emitting module 1G according to a fourth embodiment of the present disclosure. The light receiving and emitting module 1G shown in FIG. 48 includes an imaging element 51 in addition to the configuration of the light source device 1F shown in FIG. 47. The light receiving and emitting module 1G according to this modification example is different from the light source device 1F in that the light source groups 201 to 204 are arranged so as to surround the imaging element 51. Specifically, the light source groups 201 and 202 are arranged side by side in the directions D11 and D21, and the imaging element 51 is arranged therebetween. The light source groups 203 and 204 are arranged side by side in the directions D31 and D41, and the imaging element 51 is arranged therebetween. The configuration of each of the light source groups 201 to 204 is the same as that in the third embodiment and its modification example.

The imaging element 51 is provided on a substrate common to the iPM lasers 2A to 2D. In one example, the imaging element 51 is monolithically formed on the semiconductor substrate 20 together with the iPM lasers 2A to 2D. The imaging element 51 is provided instead of the imaging unit 50 shown in FIG. 18. The imaging element 51 has sensitivity to the light L1 emitted from the iPM lasers 2A to 2D. The imaging element 51 images the stripe elements Wa to Wd or the stripe patterns W1a to W1d in the object to be measured (projection region) irradiated with the light L1, generates image data indicating the imaging result, and outputs the image data to the measuring unit 60 (see FIG. 18).

According to the light receiving and emitting module 1G according to the present embodiment, it is possible to achieve the same function and effect as those of the light source device 1D by including the configuration of the light source device 1D. According to the light receiving and emitting module 1G according to the present embodiment, it is possible to achieve the same function and effect as those of the light source device 1F by including the configuration of the light source device 1F.

### Modification Examples

FIG. 49 is a perspective view showing the configuration of a light receiving and emitting module 1H according to a modification example of the fourth embodiment. The modification example is different from the fourth embodiment in that the number of iPM lasers included in the light source groups 201 to 204 is three and one of the plurality of iPM lasers included in each of the light source groups 201 to 204 is included in the arrangement of another adjacent light source group.

Specifically, one iPM laser 2A located at the first end in the arrangement direction of the three iPM lasers 2A forming the light source group 201 is located on the second end side of the three iPM lasers 2D forming the light source group 204, and is aligned in a line with these iPM lasers 2D. Similarly, one iPM laser 2D located at the first end in the arrangement direction of the three iPM lasers 2D forming the light source group 204 is located on the second end side of the three iPM lasers 2B forming the light source group 202, and is aligned in a line with these iPM lasers 2B. One iPM laser 2B located at the first end in the arrangement direction of the three iPM lasers 2B forming the light source group 202 is located on the second end side of the three iPM lasers 2C forming the light source group 203, and is aligned in a line with these iPM lasers 2C. One iPM laser 2C located at the first end in the arrangement direction of the three iPM lasers 2C forming the light source group 203 is located on the second end side of the three iPM lasers 2A forming the light source group 201, and is aligned in a line with these iPM lasers 2A.

According to the configuration of this modification example, the light source groups 201 to 204 can be densely arranged to contribute to miniaturization of the light receiving and emitting module.

FIG. 50 is a perspective view showing the configuration of a light receiving and emitting module 1J according to another modification example of the fourth embodiment. This modification example is different from the fourth embodiment in the arrangement of the light source groups 201 to 204. That is, in this modification example, the light source groups 201 to 204 do not surround the imaging element 51, but are arranged in the same manner as in the light source device 1F shown in FIG. 47. Then, the imaging element 51 is arranged away from the light source groups 201 to 204. Even with this configuration, the same effects as in the fourth embodiment can be obtained.

The problems to be solved by the second embodiment and its modification example, the third embodiment and its modification example, and the fourth embodiment and its modification example described above and the means for solving the problems will be described below.

### Problem to be Solved

For example, as disclosed in Patent Literature 1 and Non Patent Literature 3, a three-dimensional shape measurement method using a stripe pattern is known. In this measurement method, light including a stripe pattern in which a plurality of bright lines are arranged is projected onto the object to be measured, and imaging is performed while changing the phase of the stripe pattern and the like. Based on a plurality of images obtained in this manner, a three-dimensional shape is calculated using a predetermined calculation expression. For example, according to the phase shift method in which light including a stripe pattern with a plurality of bright lines periodically arranged is projected onto the object to be measured and imaging is performed while shifting the phase of the stripe pattern (that is, the position of the bright line in the arrangement direction), it is possible to measure the three-dimensional shape with extremely high accuracy, such as a few hundredths of the distance between the bright lines.

In such a measurement, it is conceivable to output, from a plurality of light sources, a plurality of stripe patterns having different phases or a plurality of stripe elements for forming these stripe patterns respectively. In this case, the plurality of light sources are arranged side by side in a direction crossing the optical axis. As such a light source, for example, an iPM laser is used. However, when a plurality of light sources are arranged side by side in a direction crossing the optical axis, the positions of the light sources in the same direction inevitably deviate from each other by the arrangement pitch between the light sources. If a positional deviation between a plurality of stripe patterns occurs due to a positional deviation between a plurality of light sources, the measurement error increases.

An object of the disclosure of the present embodiments is to provide a light source device, a light receiving and emitting module, and a three-dimensional shape measuring device that can reduce measurement errors in three-dimensional shape measurement using a stripe pattern.

### Solution to Problem

[1] Alight source device according to the present embodiment is a light source device used for three-dimensional shape measurement, and includes a plurality of first light sources arranged side by side in a direction crossing the optical axis direction so that their optical axis directions are aligned. The plurality of first light sources project light including a first pattern, in which a plurality of bright lines are arranged along a first direction crossing the extension direction of the bright lines, onto a common projection region, and the plurality of first light sources are arranged along a second direction perpendicular to the first direction.

In the light source device of [1] above, the plurality of first light sources are arranged along the second direction perpendicular to the first direction that is the arrangement direction of the bright lines of the first pattern. In this case, even if the positions of the first light sources deviate from each other by the arrangement pitch, the direction of the deviation is perpendicular to the arrangement direction of the bright lines of the first pattern. Therefore, even if a positional deviation in the first pattern occurs between the plurality of first light sources, the positional deviation does not affect the calculation of the three-dimensional shape. Therefore, according to the light source device of [1] above, it is possible to reduce measurement errors in three-dimensional shape measurement.
[2] In the light source device of [1] above, the plurality of first light sources may project light including the first pattern, in which a plurality of bright lines are arranged along the first direction crossing the extension direction of the bright lines, onto the common projection region, and the distance between the plurality of bright lines of the first pattern may be equal between the plurality of first light sources. By projecting the light including such a first pattern from the plurality of first light sources onto the common projection region, it is possible to suitably perform three-dimensional shape measurement using a phase shift method.
[3] The light source device of [1] or [2] above may include a plurality of iPM lasers as the plurality of first light sources. In this case, a light source that outputs the light including the first pattern can be made smaller, and accordingly, the light source device can be made smaller.
[4] In the light source device according to any one of [1] to [3] above, a plurality of iPM lasers may be formed monolithically. In this case, the assembly of the light source device can be simplified by forming the plurality of iPM lasers within a single element. In addition, errors of positional deviation can be suppressed compared to a case where individual elements are assembled and mounted.
[5] In the light source device according to any one of [1] to [4] above, the number of the plurality of first light sources may be n, and the amount of shift of the bright lines between the plurality of first light sources may be 1/n of the distance between the plurality of bright lines. In this case, it is possible to suitably perform three-dimensional shape measurement using a phase shift method.
[6] In the light source device according to any one of [1] to [5]above may further include a plurality of second light sources arranged side by side in a direction crossing the optical axis direction so that their optical axis directions are aligned. The plurality of second light sources project light including a second pattern, in which a plurality of bright lines are aligned along a third direction crossing the extension direction of the bright lines, onto a common projection region. The plurality of second light sources are aligned along a fourth direction perpendicular to the third direction. In the light source device of [6] above, the plurality of second light sources are arranged along the fourth direction perpendicular to the third direction that is the arrangement direction of the bright lines of the second pattern. In this case, even if the positions of the second light sources deviate from each other by the arrangement pitch, the direction of the deviation is perpendicular to the arrangement direction of the bright lines of the second pattern. Therefore, even if a positional deviation in the second pattern occurs between the plurality of second light sources, the positional deviation does not affect the calculation of the three-dimensional shape. Therefore, according to the light source device of [6] above, it is possible to reduce measurement errors in three-dimensional shape measurement.
[7] In the light source device of [6] above, the distance between the plurality of bright lines of the second pattern may be equal between the plurality of second light sources. The positions of the plurality of bright lines in the third direction with the optical axis of each second light source as a reference may differ between the plurality of second light sources. By projecting the light including such a second pattern from the plurality of second light sources onto the common projection region, it is possible to suitably perform three-dimensional shape measurement using a phase shift method. That is, it is possible to improve the measurement accuracy by performing three-dimensional shape measurement using the phase shift method at least twice using two light source groups, that is, a light source group including the plurality of first light sources and a light source group including a plurality of second light sources.
[8] In the light source device of [6] above, the distance between the plurality of bright lines of the second pattern may be different from the distance between the plurality of bright lines of the first pattern. In this case, since three-dimensional shape measurement using a phase shift method can be performed using two types of stripe patterns with different distances between bright lines, it is possible to further improve the measurement accuracy.
[9] In the light source device according to any one of [7] or [8] above, the third direction may cross the first direction. In this case, since three-dimensional shape measurement can be performed using two types of stripe patterns with different bright line arrangement directions, it is possible to further improve the measurement accuracy.
[10]A light receiving and emitting module according to one embodiment of the present disclosure is a light receiving and emitting module used for three-dimensional shape measurement, and includes any one of the light source devices described above and an imaging element that images a first pattern projected onto a common projection region and generates image data. The light source device and the imaging element are provided on a common substrate. According to this light receiving and emitting module, since any one of the light source devices described above is included, it is possible to make the optical device small and to reduce measurement errors in three-dimensional shape measurement.
[11] A three-dimensional shape measuring device according to one embodiment of the present disclosure includes the image data generating device described above and a data generating unit that generates three-dimensional shape data using image data output from the image data generating device. According to this image data generating device, since any one of the light source devices described above is included, it is possible to reduce measurement errors in three-dimensional shape measurement.

### REFERENCE SIGNS LIST

1, 1A: semiconductor light emitting device, 1C to 1F: light source device, 1G, 1H, 1J: light receiving and emitting module, 2, 2A to 2D: iPM laser, 2a: first surface, 2b: second surface, 3: drive circuit, 6: support substrate, 6a: third surface, 6b: fourth surface, 20: semiconductor substrate, 21: first cladding layer, 22: active layer, 23: second cladding layer, 25A, 25B: phase modulation layer, 25a: base layer, 25b: different refractive index region, 26: second electrode, 27: first electrode, 31, 31A, 31B: current source circuit, 32: current mirror circuit, 33: oscillation prevention circuit, 34: switch operating section, 34a: first shift register, 34b: second shift register, 50: imaging unit, 51: imaging element, 201 to 204: light source group, 311: operational amplifier, 312: NMOS-FET, 314a to 314d: third switch, 316a to 316d: partial circuit, 317: digital-to-analog converter, 318: serial-to-parallel converter, 322: switch section, 322a: first switch, 322b: second switch, 323: first current path, 324: second current path, 331: NMOS-FET, 332: first PMOS-FET, 333: second PMOS-FET, D: straight line, D1, D2, D11, D12, D21, D22, D31, D32, D41, D42: direction, G: centroid, Iout: drive current, L1: light, O(x, y): lattice point, r(x, y): distance, Rop: resistor section, Rop1 to Rop4: resistor, S4: serial signal, S6: parallel signal, Vop: input voltage, WL1, WL2: bright line, ϕ(x, y): angle.

1: A semiconductor light emitting device, comprising:
a plurality of iPM lasers each having a first surface and a second surface opposite to the first surface and outputting light from the first surface; and
a drive circuit that supplies a drive current to cause each of the plurality of iPM lasers to emit light,
wherein the drive circuit includes:
a common current source circuit for the plurality of iPM lasers;
a plurality of switch sections provided corresponding to the plurality of iPM lasers, respectively, for ON/OFF switching of the drive current; and
a switch operating section that individually operates each of the plurality of switch sections.

2: The semiconductor light emitting device according to claim 1,
wherein each of the plurality of switch sections includes a first switch and a second switch connected in series to the first switch, and
the switch operating section includes a first shift register to operate the first switch and a second shift register to operate the second switch.

3: The semiconductor light emitting device according to claim 1,
wherein the drive circuit further includes a plurality of current mirror circuits respectively corresponding to the plurality of iPM lasers,
each of the plurality of current mirror circuits has a first current path and a second current path through which current having a magnitude proportional to a magnitude of current flowing through the first current path flows,
the first current path is connected to the common current source circuit, and each of the plurality of switch sections is provided on the first current path, and
the second current path is connected to an iPM laser corresponding to the current mirror circuit to which the second current path belongs, among the plurality of iPM lasers.

4: The semiconductor light emitting device according to claim 1,
wherein the drive circuit further includes a plurality of oscillation prevention circuits respectively corresponding to the plurality of iPM lasers,
each of the plurality of oscillation prevention circuits includes:
an NMOS-FET including a source terminal connected to an anode terminal of each of the plurality of iPM lasers and a drain terminal connected to a first constant potential line;
a first PMOS-FET including a gate terminal connected to the source terminal of the NMOS-FET and a drain terminal connected to a second constant potential line having a lower potential than the first constant potential line; and
a second PMOS-FET that includes a drain terminal connected to a source terminal of the first PMOS-FET, a source terminal connected to a third constant potential line having a higher potential than the second constant potential line, and a gate terminal and supplies current to the first PMOS-FET according to an input voltage to the gate terminal, and
a potential between the first PMOS-FET and the second PMOS-FET is supplied to a gate terminal of the NMOS-FET.

5: The semiconductor light emitting device according to claim 1,
wherein a value of current generated by the common current source circuit is variable.

6: The semiconductor light emitting device according to claim 5,
wherein the common current source circuit further includes:
an operational amplifier having a pair of input terminals, an input voltage being supplied to one of the pair of input terminals;
a transistor having a control terminal connected to an output terminal of the operational amplifier; and
a resistor section having one end connected to a current terminal of the transistor and to another input terminal of the operational amplifier and another end connected to a fourth constant potential line,
a resistance value of the resistor section is variable, and
switching operations of the plurality of switch sections are synchronized with an operation of changing the resistance value of the resistor section.

7: The semiconductor light emitting device according to claim 6,
wherein the resistor section includes a plurality of partial circuits connected in parallel to each other between the one end and the other end of the resistor section,
each of the plurality of partial circuits includes a resistor and a third switch connected in series with each other between the one end and the other end of the resistor section, and
switching operations of the plurality of switch sections are synchronized with a switching operation of the third switch.

8: The semiconductor light emitting device according to claim 5,
wherein the common current source circuit further includes:
an operational amplifier having a pair of input terminals, an input voltage being supplied to one of the pair of input terminals;
a transistor having a control terminal connected to an output terminal of the operational amplifier; and
a resistor having one end connected to a current terminal of the transistor and an other input terminal of the operational amplifier and an other end connected to a fourth constant potential line, and
switching operations of the plurality of switch sections are synchronized with an operation of switching a value of the input voltage.

9: The semiconductor light emitting device according to claim 5,
wherein the drive circuit further includes:
a serial-to-parallel converter for converting a serial signal including digital data indicating an instruction value of current for the common current source circuit into a parallel signal; and
a digital-to-analog converter for converting the digital data converted into the parallel signal into an analog signal, and
the common current source circuit generates current having a magnitude corresponding to the instruction value based on the analog signal.

10: The semiconductor light emitting device according to claim 1,
wherein each of the plurality of iPM lasers includes:
an active layer that is a light emitting section;
a phase modulation layer optically coupled to the active layer;
a first cladding layer located on the first surface side of the active layer and the phase modulation layer;
a second cladding layer located on the second surface side of the active layer and the phase modulation layer;
a second electrode located on the second surface side of the second cladding layer; and
a first electrode located on the first surface side of the first cladding layer,
the phase modulation layer includes:
a base layer; and
a plurality of different refractive index regions that are provided in the base layer so as to be two-dimensionally distributed on a plane perpendicular to a normal direction of the first surface and have a refractive index different from a refractive index of the base layer,
in a state in which a virtual square lattice is set on the plane, the plurality of different refractive index regions are arranged so that a centroid of each of the plurality of different refractive index regions is away from a corresponding lattice point by a predetermined distance, and an angle of a line segment connecting the centroid of each of the plurality of different refractive index regions to the corresponding lattice point with respect to the virtual square lattice, which is an angle around each lattice point in the virtual square lattice, is set according to a phase distribution for forming an optical image, and
at least two angles among angles each being the angle in the plurality of different refractive index regions are different from each other.

11: The semiconductor light emitting device according to claim 1,
wherein each of the plurality of iPM lasers includes:
an active layer that is a light emitting section;
a phase modulation layer optically coupled to the active layer;
a first cladding layer located on the first surface side of the active layer and the phase modulation layer;
a second cladding layer located on the second surface side of the active layer and the phase modulation layer;
a second electrode located on the second surface side of the second cladding layer; and
a first electrode located on the first surface side of the first cladding layer,
the phase modulation layer includes:
a base layer; and
a plurality of different refractive index regions that are provided in the base layer so as to be two-dimensionally distributed on a plane perpendicular to a normal direction of the first surface and have a refractive index different from that of the base layer,
in a state in which a virtual square lattice is set on the plane, the plurality of different refractive index regions are arranged so that a centroid of each of the plurality of different refractive index regions is located on a straight line passing through a corresponding lattice point and inclined with respect to the virtual square lattice, and a distance along the straight line between the centroid of each of the plurality of different refractive index regions and the corresponding lattice point is set according to a phase distribution for forming an optical image, and
an inclination of the straight line is uniform in the plurality of different refractive index regions.

12: The semiconductor light emitting device according to claim 1,
wherein each of the plurality of iPM lasers is monolithically formed.

13: The semiconductor light emitting device according to claim 12,
wherein the plurality of iPM lasers and the drive circuit are provided on a common substrate.

14: The semiconductor light emitting device according to claim 1, further comprising:
a support substrate having a third surface and a fourth surface opposite to the third surface,
wherein the plurality of iPM lasers are individually mounted on the third surface so that the second surface faces the third surface.

15: The semiconductor light emitting device according to claim 14,
wherein the drive circuit is provided on the third surface or the fourth surface of the support substrate.

16: The semiconductor light emitting device according to claim 1,
wherein the drive circuit is connected to the plurality of iPM lasers by bump bonding.
